(19) United States
(12) Patent Application Publication
(10) Pub. No.: US 2023/0422548 A1
(43) Pub. Date: Dec. 28, 2023

(54) Light-Emitting Device, Display Apparatus, Display Module, And Electronic Device

(71) Applicant: Semiconductor Energy Laboratory Co., Ltd., Kanagawa-ken (JP)

(72) Inventors: Takeyoshi WATABE, Atsugi (JP); Takuya ISHIMOTO, Isehara (JP); Nobuharu OHSAWA, Zama (JP); Satoshi SEO, Sagamihara (JP)

(73) Assignee: Semiconductor Energy Laboratory Co., Ltd., Kanagawa-ken (JP)

(21) Appl. No.: 18/210,953

(22) Filed: Jun. 16, 2023

(30) Foreign Application Priority Data
Jun. 22, 2022 (JP) 2022-100505

(51) Int. Cl. H10K 50/856; H10K 50/858

(52) U.S. Cl. CPC H10K 50/856; H10K 50/858; H10K 2102/351

(57) ABSTRACT

A novel light-emitting device that is highly convenient, useful, or reliable is provided. The light-emitting device includes a first reflective film, first to fourth layers, and a first electrode. The first electrode overlaps with the first reflective film. The fourth layer is positioned between the first electrode and the first reflective film, and contains a first light-emitting material, which has an emission spectrum having a peak at a first wavelength. The third layer is positioned between the fourth layer and the first reflective film, and contains an organic compound having an ordinary refractive index of 1.45 to 1.75. The second layer is positioned between the third layer and the first reflective film, has a property of transmitting light with the first wavelength, includes a second electrode, and contains an element with an atomic number of 21 to 83 at 5 atomic % or higher. The first layer is positioned between the second layer and the first reflective film, has a property of transmitting light with the first wavelength, and contains an element with an atomic number of 1 to 20 at 95 atomic % or higher. The first reflective film reflects light with the first wavelength.

### BACKGROUND OF THE INVENTION

### 1. Field of the Invention

One embodiment of the present invention relates to a light-emitting device, a display apparatus, a display module, an electronic device, or a semiconductor device.

Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specific examples of the technical field of one embodiment of the present invention disclosed in this specification include a semiconductor device, a display apparatus, a light-emitting apparatus, a power storage device, a memory device, a method for driving any of them, and a method for manufacturing any of them.

### 2. Description of the Related Art

For example, a structure of an organic EL apparatus is known as an electro-optical apparatus including a first pixel (Patent Document 1). The first pixel includes a light-emitting pixel R, a light-emitting pixel G, and a light-emitting pixel B. The light-emitting pixels R, G, and B each include a reflective layer, a counter electrode, an optical length adjustment layer, and a functional layer. The counter electrode functions as a transflective layer, and the optical length adjustment layer and the functional layer of each light-emitting element are provided between the reflective layer and the counter electrode. The optical length adjustment layer of the light-emitting pixel R includes a third insulating layer and a fourth insulating layer. The optical length adjustment layer of the light-emitting pixel G includes the fourth insulating layer as a luminance adjustment layer. The optical length adjustment layer of the light-emitting pixel B does not include the third insulating layer.

### REFERENCE

[Patent Document 1] Japanese Published Patent Application No. 2019-135724

### SUMMARY OF THE INVENTION

An object of one embodiment of the present invention is to provide a novel light-emitting device that is highly convenient, useful, or reliable. Another object is to provide a novel display apparatus that is highly convenient, useful, or reliable. Another object is to provide a novel display module that is highly convenient, useful, or reliable. Another object is to provide a novel electronic device that is highly convenient, useful, or reliable. Another object is to provide a novel light-emitting device, a novel display apparatus, a novel display module, a novel electronic device, or a novel semiconductor device.

Note that the description of these objects does not preclude the existence of other objects. In one embodiment of the present invention, there is no need to achieve all these objects. Other objects will be apparent from and can be derived from the description of the specification, the drawings, the claims, and the like.
(1) One embodiment of the present invention is a light-emitting device including a first reflective film, a first layer, a second layer, a third layer, a fourth layer, and a first electrode.

The first electrode overlaps with the first reflective film. The fourth layer is positioned between the first electrode and the first reflective film. The fourth layer contains a first light-emitting material. The first light-emitting material has an emission spectrum having a peak at a first wavelength.

The third layer is positioned between the fourth layer and the first reflective film. The third layer contains an organic compound. The organic compound has an ordinary refractive index higher than or equal to 1.45 and lower than or equal to 1.75 at a wavelength in the range of 450 nm to 650 nm inclusive.

The second layer is positioned between the third layer and the first reflective film. The second layer has a property of transmitting light with the first wavelength. The second layer includes a second electrode. The second layer contains an element with an atomic number of 21 to 83 at 5 atomic % or higher.

The first layer is positioned between the second layer and the first reflective film. The first layer has a property of transmitting light with the first wavelength. The first layer contains an element with an atomic number of 1 to 20 at 95 atomic % or higher.

The first reflective film reflects light with the first wavelength.
(2) Another embodiment of the present invention is the light-emitting device in which the second layer has a higher ordinary refractive index than the third layer at the first wavelength, and a difference in ordinary refractive index between the second layer and the third layer at the first wavelength is larger than or equal to 0.2 and smaller than or equal to 1.5.
(3) Another embodiment of the present invention is the light-emitting device in which the first layer has a lower ordinary refractive index than the second layer at the first wavelength, and a difference in ordinary refractive index between the first layer and the second layer at the first wavelength is larger than or equal to 0.2 and smaller than or equal to 1.8.
(4) Another embodiment of the present invention is the light-emitting device in which the first layer has an ordinary refractive index higher than or equal to 1.20 and lower than or equal to 1.70 at the first wavelength, and the first layer has an insulating property.
(5) Another embodiment of the present invention is a light-emitting device including a first reflective film, a first layer, a second layer, a third layer, a fourth layer, and a first electrode.

The first electrode overlaps with the first reflective film. The fourth layer is positioned between the first electrode and the first reflective film. The fourth layer contains a first light-emitting material. The first light-emitting material has an emission spectrum having a peak at a first wavelength.

The third layer is positioned between the fourth layer and the first reflective film. The third layer contains an organic compound. The organic compound contains carbon atoms forming bonds by sp³ hybrid orbitals at higher than or equal to 23% and lower than or equal to 55% of the total carbon atoms in a molecule.

The second layer is positioned between the third layer and the first reflective film. The second layer has a property of transmitting light with the first wavelength. The second layer includes a second electrode. The second layer contains an element with an atomic number of 21 to 83 at 5 atomic % or higher.

The first layer is positioned between the second layer and the first reflective film. The first layer has a property of transmitting light with the first wavelength. The first layer contains an element with an atomic number of 1 to 20 at 95 atomic % or higher.

The first reflective film reflects light with the first wavelength.
(6) Another embodiment of the present invention is the light-emitting device in which the second layer contains a metal oxide, and the metal oxide contains indium, tin, zinc, gallium, or titanium.
(7) Another embodiment of the present invention is the light-emitting device in which the first layer contains silicon oxide or aluminum oxide.
(8) Another embodiment of the present invention is the light-emitting device in which the first reflective film has conductivity, and the first reflective film is electrically connected to the second electrode.
(9) Another embodiment of the present invention is the light-emitting device in which the first reflective film contains silver or aluminum.
(10) Another embodiment of the present invention is the light-emitting device in which the first electrode has a property of transmitting light with the first wavelength.
(11) Another embodiment of the present invention is the light-emitting device in which the first electrode contains silver, magnesium, aluminum, indium, tin, zinc, gallium, or titanium.
(12) Another embodiment of the present invention is a display apparatus including a first light-emitting device and a second light-emitting device.

The first light-emitting device has the above structure.

The second light-emitting device is adjacent to the first light-emitting device. The second light-emitting device includes a second reflective film, a fifth layer, a sixth layer, a seventh layer, an eighth layer, and a third electrode.

The third electrode overlaps with the second reflective film.

The eighth layer is positioned between the third electrode and the second reflective film. The eighth layer contains a second light-emitting material. The second light-emitting material has an emission spectrum having a peak at a second wavelength. The second wavelength is longer than the first wavelength.

The seventh layer is positioned between the eighth layer and the second reflective film. The seventh layer contains an organic compound. The organic compound has an ordinary refractive index higher than or equal to 1.45 and lower than or equal to 1.75 at a wavelength in the range of 450 nm to 650 nm inclusive.

The sixth layer contains the same material as the second layer. The sixth layer is positioned between the third electrode and the second reflective film. The sixth layer has a property of transmitting light with the second wavelength. The sixth layer includes a fourth electrode.

The fifth layer contains the same material as the first layer. The fifth layer is positioned between the sixth layer and the second reflective film. The fifth layer has a property of transmitting light with the second wavelength.

The second reflective film is adjacent to the first reflective film, and reflects light with the second wavelength.
(13) Another embodiment of the present invention is a display apparatus including a first light-emitting device and a second light-emitting device.

The first light-emitting device has the above structure.

The second light-emitting device is adjacent to the first light-emitting device. The second light-emitting device includes a second reflective film, a fifth layer, a sixth layer, a seventh layer, an eighth layer, and a third electrode.

The third electrode overlaps with the second reflective film.

The eighth layer is positioned between the third electrode and the second reflective film. The eighth layer contains a second light-emitting material. The second light-emitting material has an emission spectrum having a peak at a second wavelength. The second wavelength is longer than the first wavelength.

The seventh layer is positioned between the eighth layer and the second reflective film. The seventh layer contains an organic compound. The organic compound contains carbon atoms forming bonds by sp³ hybrid orbitals at higher than or equal to 23% and lower than or equal to 55% of the total carbon atoms in a molecule.

The sixth layer contains the same material as the second layer. The sixth layer is positioned between the third electrode and the second reflective film. The sixth layer has a property of transmitting light with the second wavelength. The sixth layer includes a fourth electrode.

The fifth layer contains the same material as the first layer. The fifth layer is positioned between the sixth layer and the second reflective film. The fifth layer has a property of transmitting light with the second wavelength.

The second reflective film is adjacent to the first reflective film, and reflects light with the second wavelength.
(14) Another embodiment of the present invention is the display apparatus in which the seventh layer is thicker than the third layer.
(15) Another embodiment of the present invention is the display apparatus in which a difference in thickness between the sixth layer and the second layer is larger than 0 and smaller than 5 nm.
(16) Another embodiment of the present invention is the display apparatus in which a difference in thickness between the fifth layer and the first layer is larger than 0 and smaller than 5 nm.
(17) Another embodiment of the present invention is a display module including the display apparatus and at least one of a connector and an integrated circuit.
(18) Another embodiment of the present invention is an electronic device including the display apparatus and at least one of a battery, a camera, a speaker, and a microphone.

Although the block diagram in drawings attached to this specification shows components classified based on their functions in independent blocks, it is difficult to classify actual components based on their functions completely, and one component can have a plurality of functions.

Note that the light-emitting apparatus in this specification includes, in its category, an image display device that uses a light-emitting device. The light-emitting apparatus may also include, in its category, a module in which a light-emitting device is provided with a connector such as an anisotropic conductive film or a tape carrier package (TCP), a module in which a printed wiring board is provided at the end of a TCP, and a module in which an integrated circuit (IC) is directly mounted on a light-emitting device by a chip on glass (COG) method. Furthermore, a lighting device or the like may include the light-emitting apparatus.

One embodiment of the present invention can provide a novel light-emitting device that is highly convenient, useful, or reliable. Another embodiment of the present invention can provide a novel display apparatus that is highly convenient, useful, or reliable. Another embodiment of the present invention can provide a novel display module that is highly convenient, useful, or reliable. Another embodiment of the present invention can provide a novel electronic device that is highly convenient, useful, or reliable. A novel light-emitting device can be provided. A novel display apparatus can be provided. A novel display module can be provided. A novel electronic device can be provided.

Note that the description of these effects does not preclude the existence of other effects. One embodiment of the present invention does not necessarily have all these effects. Other effects will be apparent from and can be derived from the description of the specification, the drawings, the claims, and the like.

### BRIEF DESCRIPTION OF THE DRAWINGS

In the accompanying drawings:

FIGS. 1A and 1B illustrate a structure of a light-emitting device of an embodiment;

FIGS. 2A and 2B illustrate a structure of a light-emitting device of an embodiment;

FIGS. 3A and 3B each illustrate a structure of a light-emitting device of an embodiment;

FIGS. 4A to 4C illustrate a structure of a display apparatus of an embodiment;

FIGS. 5A and 5B each illustrate a structure of a display apparatus of an embodiment;

FIGS. 6A to 6C illustrate a structure of a display apparatus of an embodiment;

FIG. 7 illustrates a structure of a display apparatus of an embodiment;

FIG. 8 illustrates a structure of a display module of an embodiment;

FIGS. 9A and 9B each illustrate a structure of a display apparatus of an embodiment;

FIG. 10 illustrates a structure of a display apparatus of an embodiment;

FIG. 11 illustrates a structure of a display apparatus of an embodiment;

FIG. 12 illustrates a structure of a display apparatus of an embodiment;

FIG. 13 illustrates a structure of a display apparatus of an embodiment;

FIG. 14 illustrates a structure of a display apparatus of an embodiment;

FIG. 15 illustrates a structure of a display module of an embodiment;

FIGS. 16A to 16C illustrate a structure of a display apparatus of an embodiment;

FIG. 17 illustrates a structure of a display apparatus of an embodiment;

FIG. 18 illustrates a structure of a display apparatus of an embodiment;

FIGS. 19A to 19D illustrate examples of electronic devices of an embodiment;

FIGS. 20A to 20F illustrate examples of electronic devices of an embodiment;

FIGS. 21A to 21G illustrate examples of electronic devices of an embodiment;

FIG. 22 illustrates structures of light-emitting devices of an example;

FIG. 23 illustrates structures of light-emitting devices of an example;

FIG. 24 is a graph showing emission spectra of light-emitting materials of an example;

FIG. 25 is a graph showing wavelength dependence of an ordinary refractive index n and an extinction coefficient k of a material of an example;

FIG. 26 is a graph showing wavelength dependence of an ordinary refractive index n and an extinction coefficient k of a material of an example;

FIG. 27 is a graph showing wavelength dependence of an ordinary refractive index n and an extinction coefficient k of a material of an example;

FIG. 28 is a graph showing wavelength dependence of an ordinary refractive index n and an extinction coefficient k of a material of an example;

FIG. 29 is a graph showing wavelength dependence of an ordinary refractive index n and an extinction coefficient k of a material of an example; and

FIG. 30 is a graph showing wavelength dependence of an ordinary refractive index n and an extinction coefficient k of a material of an example.

### DETAILED DESCRIPTION OF THE INVENTION

A light-emitting device of one embodiment of the present invention includes a first reflective film, a first layer, a second layer, a third layer, a fourth layer, and a first electrode. The first electrode overlaps with the first reflective film. The fourth layer is positioned between the first electrode and the first reflective film. The fourth layer contains a first light-emitting material. An emission spectrum of the first light-emitting material has a peak at a first wavelength. The third layer is positioned between the fourth layer and the first reflective film. The third layer contains an organic compound that has an ordinary refractive index higher than or equal to 1.45 and lower than or equal to 1.75 at a wavelength in the range of 450 nm to 650 nm inclusive. The second layer is positioned between the third layer and the first reflective film. The second layer has a property of transmitting light with the first wavelength. The second layer includes a second electrode. The second layer contains an element with an atomic number of 21 to 83 at 5 atomic % or higher. The first layer is positioned between the second layer and the first reflective film. The first layer has a property of transmitting light with the first wavelength. The first layer contains an element with an atomic number of 1 to 20 at 95 atomic % or higher. The first reflective film reflects light with the first wavelength.

Thus, the third layer has a lower ordinary refractive index than the second layer. The second layer has a higher ordinary refractive index than the first layer. Light emitted from the fourth layer to the first reflective film goes through a region having a low ordinary refractive index and then a region having a high ordinary refractive index. Part of the light can be reflected between the third layer and the second layer. The reflected light and light emitted from the fourth layer to the first electrode can interfere with each other to be intensified. The other part of the light goes through a region having a high ordinary refractive index and then a region having a low ordinary refractive index. Part thereof can be reflected between the second layer and the first layer. The reflected light and the light emitted from the fourth layer to the first electrode can interfere with each other to be intensified. The reflected light and the light reflected between the third layer and the second layer can interfere with each other to be intensified. The light reflected by the first reflective film and the light emitted from the fourth layer to the first electrode can interfere with each other to be intensified. The light emitted from the fourth layer can be extracted efficiently. As a result, a novel light-emitting device that is highly convenient, useful, or reliable can be provided.

Embodiments will be described in detail with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments. Note that in structures of the invention described below, the same portions or portions having similar functions are denoted by the same reference numerals in different drawings, and the description thereof is not repeated.

### Embodiment 1

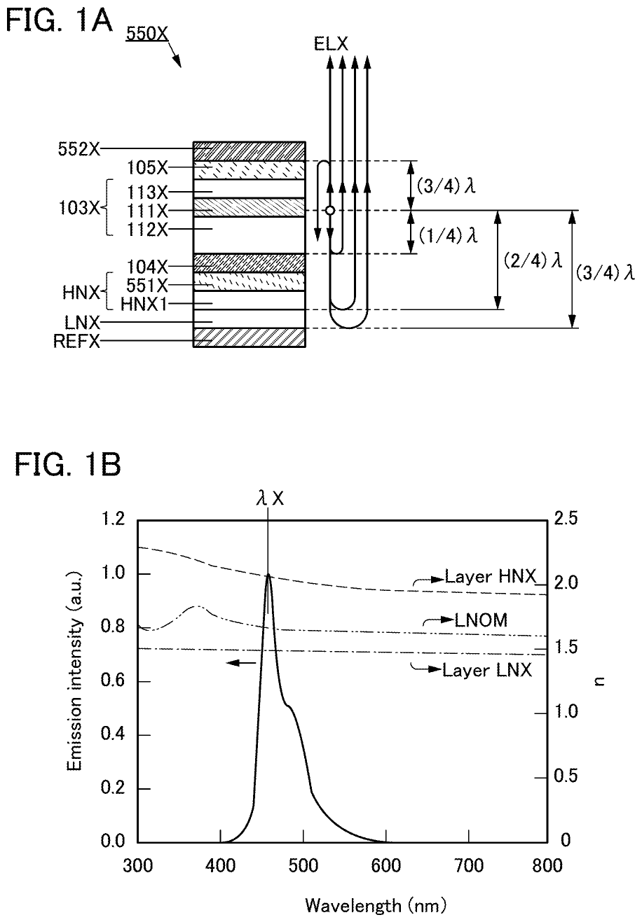

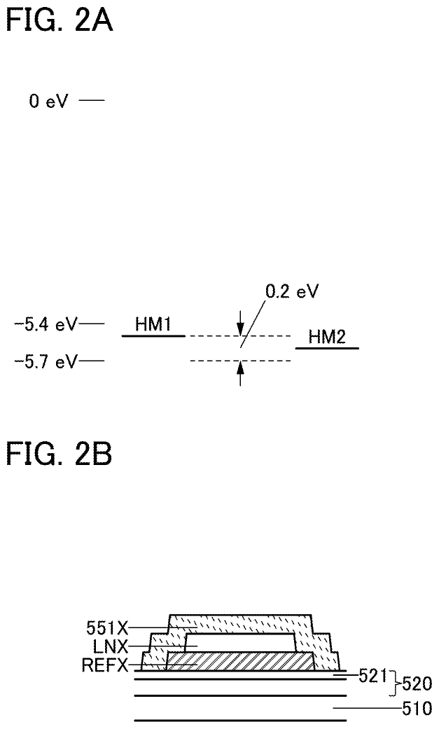

In this embodiment, a structure of a light-emitting device of one embodiment of the present invention is described with reference to FIGS. 1A and 1B and FIGS. 2A and 2B.

FIG. 1A is a cross-sectional view illustrating a structure of a light-emitting device of one embodiment of the present invention, and FIG. 1B is a graph showing an emission spectrum and wavelength dependence of ordinary refractive indices for describing the structure of the light-emitting device of one embodiment of the present invention.

FIG. 2A is an energy diagram showing the structure of the light-emitting device of one embodiment of the present invention. FIG. 2B is a cross-sectional view illustrating a structure of part of the light-emitting device of one embodiment of the present invention.

### Structure Example 1 of Light-Emitting Device 550X

A light-emitting device 550X described in this embodiment includes a reflective film REFX, a layer LNX, a layer HNX, a unit 103X, and an electrode 552X (see FIG. 1A). The layer HNX includes an electrode 551X, and the unit 103X includes a layer 113X, a layer 112X, and a layer 111X. The light-emitting device 550X includes a layer 104X and a layer 105X.

The electrode 552X overlaps with the reflective film REFX, and has a property of transmitting light with a wavelength XX.

### Structure Example of Unit 103X

The unit 103X has a single-layer structure or a stacked-layer structure. For example, the unit 103X includes the layer 111X, the layer 112X, and the layer 113X. The unit 103X has a function of emitting light ELX.

The layer 111X is positioned between the layer 113X and the layer 112X, the layer 113X is positioned between the electrode 552X and the layer 111X, and the layer 112X is positioned between the layer 111X and the electrode 551X.

For example, a layer selected from functional layers such as a light-emitting layer, a hole-transport layer, an electron-transport layer, and a carrier-blocking layer can be used for the unit 103X. A layer selected from functional layers such as a hole-injection layer, an electron-injection layer, an exciton-blocking layer, and a charge-generation layer can also be used for the unit 103X.

### Structure Example 1 of Layer 111X

The layer 111X is positioned between the electrode 552X and the reflective film REFX, and contains a light-emitting material EMX. The light-emitting material EMX has an emission spectrum having a peak at the wavelength XX. For example, a material emitting blue light can be used as the light-emitting material (see FIG. 1). Furthermore, a host material can be used for the layer 111X.

The layer 111X can be referred to as a light-emitting layer. The layer 111X is preferably provided in a region where holes and electrons are recombined. This allows efficient conversion of energy generated by recombination of carriers into light and emission of the light.

Furthermore, the layer 111X is preferably provided apart from a metal used for the electrode or the like. In that case, a quenching phenomenon caused by the metal used for the electrode or the like can be inhibited.

It is preferable that a distance from an electrode or the like having reflectivity to the layer 111X be adjusted and the layer 111X be placed in an appropriate position in accordance with an emission wavelength. With this structure, the amplitude can be increased by utilizing an interference phenomenon between light reflected by the electrode or the like and light emitted from the layer 111X. Light with a predetermined wavelength can be intensified and the spectrum of the light can be narrowed. In addition, bright light emission colors with high intensity can be obtained. In other words, the layer 111X is placed in an appropriate position, for example, between electrodes and the like, and thus a microcavity structure can be formed.

For example, a fluorescent substance, a phosphorescent substance, or a substance exhibiting thermally activated delayed fluorescence (TADF) (also referred to as a TADF material) can be used for the light-emitting material. Thus, energy generated by recombination of carriers can be released as the light ELX from the light-emitting material.

[Fluorescent substance]A fluorescent substance can be used for the layer 111X. For example, the following fluorescent substances can be used for the layer 111X. Note that fluorescent substances that can be used for the layer 111X are not limited to the following, and a variety of known fluorescent substances can be used.

Specifically, any of the following fluorescent substances can be used: 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis[N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N,N′-(pyrene-1,6-diyl)bis[(6,N-diphenylbenzo[b]naphtho[1,2-d]furan)-8-amine](abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), 3,10-bis[N-(dibenzofuran-3-yl)-N-phenylamino]naphtho[2,3-b;6,7-b′]bisbenzofuran (abbreviation: 3,10FrA2Nbf(IV)-02), and the like.

Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

Other examples of fluorescent substances include N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, 9,10-diphenyl-2-[N-phenyl-N-(9-phenyl-carbazol-3-yl)-amino]-anthracene (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracene-2-amine (abbreviation: 2YGABPhA), N,N,9-triphenylanthracene-9-amine (abbreviation: DPhAPhA), coumarin 545T, N,N′-diphenylquinacridone (abbreviation: DPQd), rubrene, and 5,12-bis(1,1′-biphenyl-4-yl)-6,11-diphenyltetracene (abbreviation: BPT).

Other examples of fluorescent substances include 2-(2-{2-[4-(dimethylamino)phenyl]ethenyl}-6-methyl-4H-pyran-4-ylidene)propanedinit rile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), and 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM).

### [Phosphorescent Substance]

A phosphorescent substance can be used for the layer 111X. For example, phosphorescent substances described below as examples can be used for the layer 111X. Note that phosphorescent substances that can be used for the layer 111X are not limited to the following, and a variety of known phosphorescent substances can be used for the layer 111X.

For example, any of the following can be used for the layer 111X: an organometallic iridium complex having a 4H-triazole skeleton, an organometallic iridium complex having a 1H-triazole skeleton, an organometallic iridium complex having an imidazole skeleton, an organometallic iridium complex having a phenylpyridine derivative with an electron-withdrawing group as a ligand, an organometallic iridium complex having a pyrimidine skeleton, an organometallic iridium complex having a pyrazine skeleton, an organometallic iridium complex having a pyridine skeleton, a rare earth metal complex, a platinum complex, and the like.

### [Phosphorescent Substance (Blue)]

As an organometallic iridium complex having a 4H-triazole skeleton or the like, tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), or the like can be used.

As an organometallic iridium complex having a 1H-triazole skeleton or the like, tris[3-methyl-1-(2-methylphenyl)-5-phenyl-1H-1,2,4-triazolato]iridium(III) (abbreviation: [Ir(Mptz1-mp)₃]), tris(1-methyl-5-phenyl-3-propyl-1H-1,2,4-triazolato)iridium(III) (abbreviation: [Ir(Prptz1-Me)₃]), or the like can be used.

As an organometallic iridium complex having an imidazole skeleton or the like, fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), or the like can be used.

As an organometallic iridium complex having a phenylpyridine derivative with an electron-withdrawing group as a ligand, or the like, bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C²}iridium(III) picolinate (abbreviation: Ir(CF₃ppy)₂(pic)), bis[2-(4′,6′-difluorophenyl)pyridinato-N,C^{2′}′]iridium(III) acetylacetonate (abbreviation: FIracac), or the like can be used.

These substances are compounds exhibiting blue phosphorescence and having an emission wavelength peak at 440 nm to 520 nm.

### [Phosphorescent Substance (Green)]

As an organometallic iridium complex having a pyrimidine skeleton or the like, tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis(4,6-diphenylpyrimidinato)iridium(III) (abbreviation: [Ir(dppm)₂(acac)]), or the like can be used.

As an organometallic iridium complex having a pyrazine skeleton or the like, (acetylacetonato)bis(3,5-dimethyl-2-phenylpyrazinato)iridium(III) (abbreviation: [Ir(mppr-Me)₂(acac)]), (acetylacetonato)bis(5-isopropyl-3-methyl-2-phenylpyrazinato)iridium(III) (abbreviation: [Ir(mppr-iPr)₂(acac)]), or the like can be used.

As an organometallic iridium complex having a pyridine skeleton or the like, tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyri dinyl-κN²)phenyl-κC]iridium(III) (abbreviation: [Ir(5mppy-d₃)₂(mbfpypy-d₃)]), [2-d₃-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy-d₃)]), or the like can be used.

Examples of a rare earth metal complex are tris(acetylacetonato) (monophenanthroline)terbium(III) (abbreviation: [Tb(acac)₃(Phen)]), and the like.

These are compounds that mainly exhibit green phosphorescence and have an emission wavelength peak at 500 nm to 600 nm. Note that an organometallic iridium complex having a pyrimidine skeleton has distinctively high reliability or emission efficiency.

### [Phosphorescent Substance (Red)]

As an organometallic iridium complex having a pyrimidine skeleton or the like, (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), bis[4,6-di(naphthalen-1-yl)pyrimidinato](dipivaloylmethanato)iridium(III) (abbreviation: [Ir(d1npm)₂(dpm)]), or the like can be used.

As an organometallic iridium complex having a pyrazine skeleton or the like, (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), (acetylacetonato)bis[2,3-bis(4-fluorophenyl)quinoxalinato]iridium(III) (abbreviation: [Ir(Fdpq)₂(acac)]), or the like can be used.

As an organometallic iridium complex having a pyridine skeleton or the like, tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), or the like can be used.

As a rare earth metal complex or the like, tris(1,3-diphenyl-1,3-propanedionato)(monophenanthroline)europium(III) (abbreviation: [Eu(DBM)₃(Phen)]), tris[1-(2-thenoyl)-3,3,3-trifluoroacetonato](monophenanthroline)europium(III) (abbreviation: [Eu(TTA)₃(Phen)]), or the like can be used.

As a platinum complex or the like, 2,3,7,8,12,13,17,18-octaethyl-21H,23H-porphyrin platinum(II) (abbreviation: PtOEP) or the like can be used.

These are compounds that exhibit red phosphorescence and have an emission peak at 600 nm to 700 nm. Furthermore, the organometallic iridium complexes having a pyrazine skeleton can provide red light emission with chromaticity favorably used for display apparatuses.

### [Substance Exhibiting Thermally Activated Delayed Fluorescence (TADF)]

A TADF material can be used for the layer 111X. When a TADF material is used as the light-emitting substance, the S1 level of a host material is preferably higher than that of the TADF material. In addition, the T1 level of the host material is preferably higher than that of the TADF material.

For example, any of the TADF materials enumerated below can be used as the light-emitting material. Note that without being limited thereto, a variety of known TADF materials can be used.

In the TADF material, the difference between the S1 level and the T1 level is small, and reverse intersystem crossing (upconversion) from the triplet excited state into the singlet excited state can be achieved by a small amount of thermal energy. Thus, the singlet excited state can be efficiently generated from the triplet excited state. In addition, the triplet excitation energy can be converted into luminescence.

An exciplex whose excited state is formed of two kinds of substances has an extremely small difference between the S1 level and the T1 level and functions as a TADF material capable of converting triplet excitation energy into singlet excitation energy.

A phosphorescent spectrum observed at a low temperature (e.g., 77 K to 10 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between the S1 level and the T1 level of the TADF material is preferably smaller than or equal to 0.3 eV, further preferably smaller than or equal to 0.2 eV.

Examples of the TADF material include a fullerene, a derivative thereof, an acridine, a derivative thereof, and an eosin derivative. Furthermore, porphyrin containing a metal such as magnesium (Mg), zinc (Zn), cadmium (Cd), tin (Sn), platinum (Pt), indium (In), or palladium (Pd) can be also used as the TADF material.

Specifically, the following materials whose structural formulae are shown below can be used: a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), an octaethylporphyrin-platinum chloride complex (PtCl₂OEP), and the like.

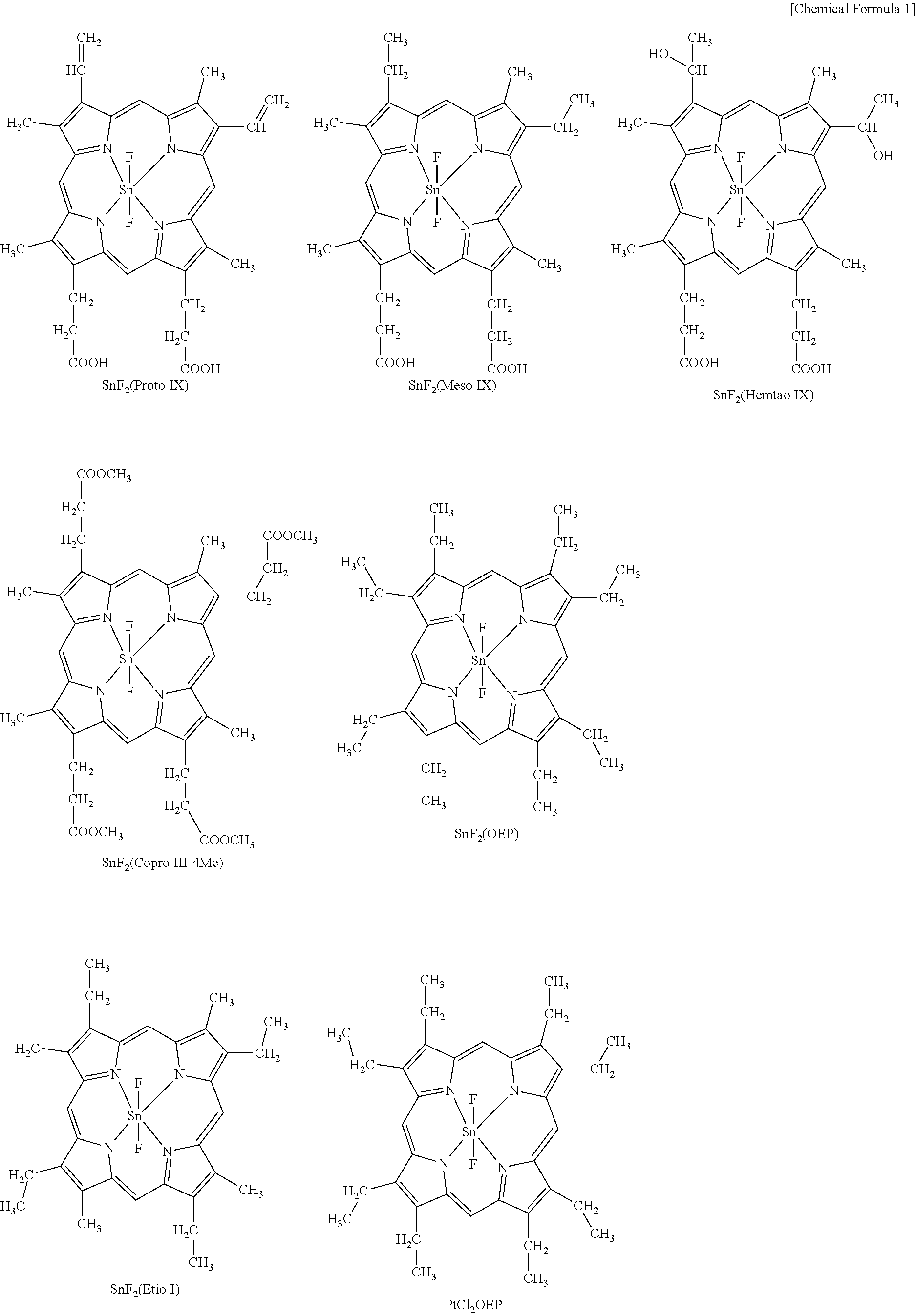

Furthermore, a heterocyclic compound including one or both of a π-electron rich heteroaromatic ring and a π-electron deficient heteroaromatic ring can be used, for example, as the TADF material.

Specifically, the following compounds whose structural formulae are shown below can be used: 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-tria zine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), and the like.

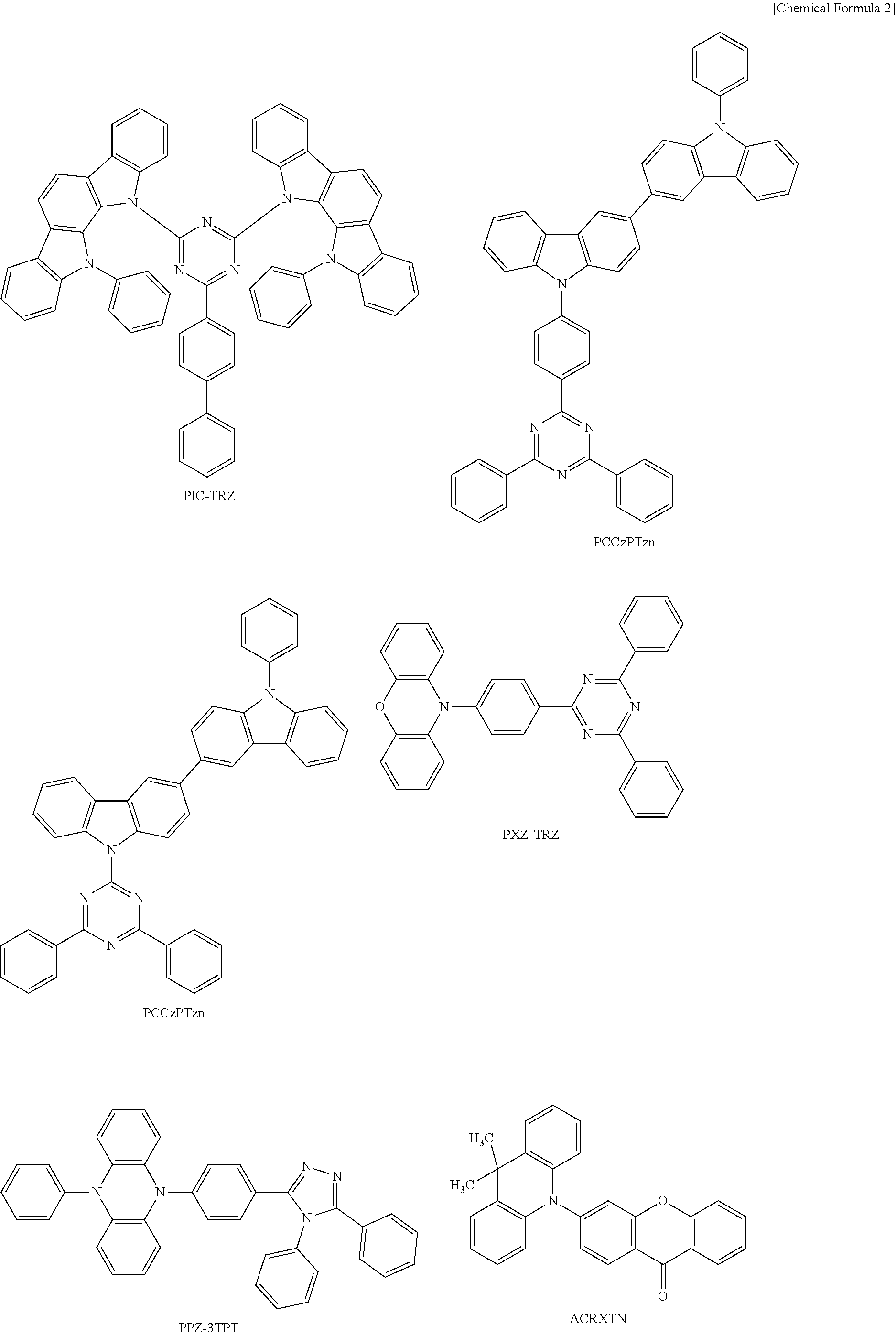

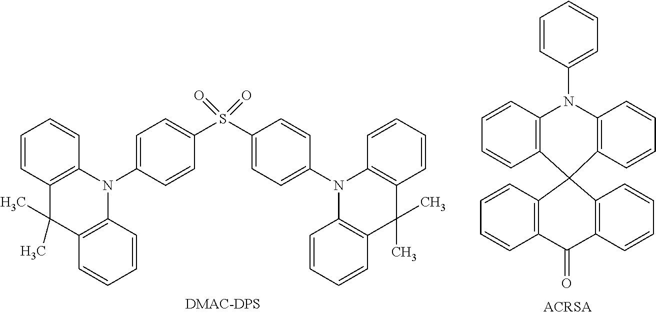 [SMILES: CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Such a heterocyclic compound is preferable because of having high electron-transport and hole-transport properties owing to a π-electron rich heteroaromatic ring and a π-electron deficient heteroaromatic ring. Among skeletons having the π-electron deficient heteroaromatic ring, in particular, a pyridine skeleton, a diazine skeleton (a pyrimidine skeleton, a pyrazine skeleton, and a pyridazine skeleton), and a triazine skeleton are preferred because of their high stability and reliability. In particular, a benzofuropyrimidine skeleton, a benzothienopyrimidine skeleton, a benzofuropyrazine skeleton, and a benzothienopyrazine skeleton are preferred because of their high electron-accepting properties and high reliability.

Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; therefore, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable.

Note that a substance in which the π-electron rich heteroaromatic ring is directly bonded to the π-electron deficient heteroaromatic ring is particularly preferred because the electron-donating property of the π-electron rich heteroaromatic ring and the electron-accepting property of the π-electron deficient heteroaromatic ring are both improved, the energy difference between the S1 level and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used.

As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane and boranthrene, an aromatic ring or a heteroaromatic ring having a nitrile group or a cyano group such as benzonitrile or cyanobenzene, a carbonyl skeleton such as benzophenone, a phosphine oxide skeleton, a sulfone skeleton, or the like can be used.

As described above, a π-electron deficient skeleton and a π-electron rich skeleton can be used instead of at least one of the π-electron deficient heteroaromatic ring and the π-electron rich heteroaromatic ring.

### Structure Example 2 of Layer 111X

A carrier-transport material can be used as the host material. For example, a hole-transport material, an electron-transport material, a substance exhibiting thermally activated delayed fluorescence (TADF), a material having an anthracene skeleton, or a mixed material can be used as the host material. A material having a wider bandgap than the light-emitting material contained in the layer 111X is preferably used as the host material. Thus, transfer of energy from excitons generated in the layer 111X to the host material can be inhibited.

### [Hole-Transport Material]

A material having a hole mobility of 1×10⁻⁶ cm²/Vs or higher can be suitably used as the hole-transport material.

As the hole-transport material, an amine compound or an organic compound having a π-electron rich heteroaromatic ring skeleton can be used, for example. Specifically, a compound having an aromatic amine skeleton, a compound having a carbazole skeleton, a compound having a thiophene skeleton, a compound having a furan skeleton, or the like can be used. The compound having an aromatic amine skeleton and the compound having a carbazole skeleton are particularly preferable because these compounds are highly reliable and have high hole-transport properties to contribute to a reduction in driving voltage.

The following are examples that can be used as a compound having an aromatic amine skeleton: 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF).

As a compound having a carbazole skeleton, for example, 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 3,3′-bis(9-phenyl-9H-carbazole) (abbreviation: PCCP) can be used.

As a compound having a thiophene skeleton, for example, 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV) can be used.

As a compound having a furan skeleton, for example, 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II) can be used.

### [Electron-Transport Material]

For example, a metal complex or an organic compound having a π-electron deficient heteroaromatic ring skeleton can be used as the electron-transport material.

As a metal complex, bis(10-hydroxybenzo[h]quinolinato)beryllium(II) (abbreviation: BeBq₂), bis(2-methyl-8-quinolinolato) (4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ) can be used, for example.

As an organic compound having a π-electron deficient heteroaromatic ring skeleton, a heterocyclic compound having a polyazole skeleton, a heterocyclic compound having a diazine skeleton, a heterocyclic compound having a pyridine skeleton, a heterocyclic compound having a triazine skeleton, or the like can be used, for example. In particular, the heterocyclic compound having a diazine skeleton or the heterocyclic compound having a pyridine skeleton has favorable reliability and thus is preferable. In addition, the heterocyclic compound having a diazine (pyrimidine or pyrazine) skeleton has a high electron-transport property to contribute to a reduction in driving voltage.

As a heterocyclic compound having a polyazole skeleton, 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), or 2-[3-(dibenzothiophen-4-yl)phenyl]-1-phenyl-1H-benzimidazole (abbreviation: mDBTBIm-II) can be used, for example.

As a heterocyclic compound having a diazine skeleton, 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), or 4,8-bis[3-(dibenzothiophen-4-yl)phenyl]benzo[h]quinazoline (abbreviation: 4,8mDBtP2Bqn) can be used, for example.

As a heterocyclic compound having a pyridine skeleton, 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB) can be used, for example.

As a heterocyclic compound having a triazine skeleton, 2-[3′-(9,9-dimethyl-9H-fluoren-2-yl)biphenyl-3-yl]-4,6-diphenyl-1,3,5-triazine (abbreviation: mFBPTzn), 2-[(1,1′-biphenyl)-4-yl]-4-phenyl-6-[9,9′-spirobi(9H-fluoren)-2-yl]-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), or 2-{3-[3-(benzo[b]naphtho[1,2-d]furan-6-yl)phenyl]phenyl}-4,6-diphenyl-1,3,5-triazine (abbreviation: mBnfBPTzn-02) can be used, for example.

### [Material Having Anthracene Skeleton]

An organic compound having an anthracene skeleton can be used as the host material. An organic compound having an anthracene skeleton is particularly preferable in the case where a fluorescent substance is used as the light-emitting substance. Thus, a light-emitting device with high emission efficiency and high durability can be obtained.

Among the organic compounds having an anthracene skeleton, an organic compound having a diphenylanthracene skeleton, in particular, a 9,10-diphenylanthracene skeleton, is chemically stable and thus is preferable. The host material preferably has a carbazole skeleton because the hole-injection and hole-transport properties are improved. In particular, the host material preferably has a dibenzocarbazole skeleton because the highest occupied molecular orbital (HOMO) level thereof is shallower than that of carbazole by approximately 0.1 eV so that holes enter the host material easily, the hole-transport property is improved, and the heat resistance is increased. Note that in terms of the hole-injection and hole-transport properties, instead of a carbazole skeleton, a benzofluorene skeleton or a dibenzofluorene skeleton may be used.

Thus, a substance having both a 9,10-diphenylanthracene skeleton and a carbazole skeleton, a substance having both a 9,10-diphenylanthracene skeleton and a benzocarbazole skeleton, or a substance having both a 9,10-diphenylanthracene skeleton and a dibenzocarbazole skeleton is preferable as the host material.

Examples of the substances that can be used include 6-[3-(9,10-diphenyl-2-anthryl)phenyl]benzo[b]naphtho[1,2-d]furan (abbreviation: 2mBnfPPA), 9-phenyl-10-[4′-(9-phenyl-9H-fluoren-9-yl)biphenyl-4-yl]anthracene (abbreviation: FLPPA), 9-(1-naphthyl)-10-[4-(2-naphthyl)phenyl]anthracene (abbreviation: αN-βNPAnth), 9-phenyl-3-[4-(10-phenyl-9-anthryl)phenyl]-9H-carbazole (abbreviation: PCzPA), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 3-[4-(1-naphthyl)-phenyl]-9-phenyl-9H-carbazole (abbreviation: PCPN), and the like.

In particular, CzPA, cgDBCzPA, 2mBnfPPA, and PCzPA have excellent characteristics.

### [Substance Exhibiting Thermally Activated Delayed Fluorescence (TADF)]

A TADF material can be used as the host material. When the TADF material is used as the host material, triplet excitation energy generated in the TADF material can be converted into singlet excitation energy by reverse intersystem crossing. Moreover, excitation energy can be transferred to the light-emitting substance. In other words, the TADF material functions as an energy donor, and the light-emitting substance functions as an energy acceptor. Thus, the emission efficiency of the light-emitting device can be increased.

This is very effective in the case where the light-emitting substance is a fluorescent substance. In that case, the S1 level of the TADF material is preferably higher than that of the fluorescent substance in order that high emission efficiency be achieved. Furthermore, the T1 level of the TADF material is preferably higher than the S1 level of the fluorescent substance. Therefore, the T1 level of the TADF material is preferably higher than that of the fluorescent substance.

It is also preferable to use a TADF material that emits light whose wavelength overlaps with the wavelength on a lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protecting group around a luminophore (a skeleton which causes light emission) of the fluorescent substance. As the protecting group, a substituent having no 7r bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protecting groups. The substituents having no π bond are poor in carrier-transport performance; therefore, the TADF material and the luminophore of the fluorescent substance can be made away from each other with little influence on carrier transportation or carrier recombination.

Here, the luminophore refers to an atomic group (skeleton) that causes light emission in a fluorescent substance. The luminophore is preferably a skeleton having a π bond, further preferably includes an aromatic ring, and still further preferably includes a condensed aromatic ring or a condensed heteroaromatic ring.

Examples of the condensed aromatic ring or the condensed heteroaromatic ring include a phenanthrene skeleton, a stilbene skeleton, an acridone skeleton, a phenoxazine skeleton, and a phenothiazine skeleton. In particular, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferred because of its high fluorescence quantum yield.

For example, the TADF material that can be used as the light-emitting material can be used as the host material.

### Structure Example 1 of Mixed Material

A material in which a plurality of kinds of substances are mixed can be used as the host material. For example, a material which includes an electron-transport material and a hole-transport material can be used as the mixed material. The weight ratio between the hole-transport material and the electron-transport material contained in the mixed material may be (the hole-transport material/the electron-transport material)=(1/19) or more and (19/1) or less. Thus, the carrier-transport property of the layer 111X can be easily adjusted and a recombination region can be easily controlled.

### Structure Example 2 of Mixed Material

In addition, a material mixed with a phosphorescent substance can be used as the host material. When a fluorescent substance is used as the light-emitting substance, a phosphorescent substance can be used as an energy donor for supplying excitation energy to the fluorescent substance.

### Structure Example 3 of Mixed Material

A mixed material containing a material to form an exciplex can be used as the host material. For example, a material in which an emission spectrum of a formed exciplex overlaps with a wavelength on the lowest-energy-side absorption band of the light-emitting substance can be used as the host material. This enables smooth energy transfer and improves emission efficiency. The driving voltage can be suppressed. With such a structure, light emission can be efficiently obtained by exciplex-triplet energy transfer (ExTET), which is energy transfer from the exciplex to the light-emitting substance (phosphorescent material).

A phosphorescent substance can be used as at least one of the materials forming an exciplex. Accordingly, reverse intersystem crossing can be used. Triplet excitation energy can be efficiently converted into singlet excitation energy.

Combination of an electron-transport material and a hole-transport material whose HOMO level is higher than or equal to that of the electron-transport material is preferable for forming an exciplex. The LUMO level of the hole-transport material is preferably higher than or equal to the LUMO level of the electron-transport material. Thus, an exciplex can be efficiently formed. Note that the LUMO levels and the HOMO levels of the materials can be derived from the electrochemical characteristics (the reduction potentials and the oxidation potentials). Specifically, the reduction potentials and the oxidation potentials can be measured by cyclic voltammetry (CV).

The formation of an exciplex can be confirmed by a phenomenon in which the emission spectrum of the mixed film in which the hole-transport material and the electron-transport material are mixed is shifted to the longer wavelength side than the emission spectra of each of the materials (or has another peak on the longer wavelength side) observed by comparison of the emission spectra of the hole-transport material, the electron-transport material, and the mixed film of these materials, for example. Alternatively, the formation of an exciplex can be confirmed by a difference in transient response, such as a phenomenon in which the transient PL lifetime of the mixed film has longer lifetime components or a larger proportion of delayed components than that of each of the materials, observed by comparison of transient photoluminescence (PL) of the hole-transport material, the electron-transport material, and the mixed film of these materials. The transient PL can be rephrased as transient electroluminescence (EL). That is, the formation of an exciplex can also be confirmed by a difference in transient response observed by comparison of the transient EL of the hole-transport material, the electron-transport material, and the mixed film of these materials.

### Structure Example of Layer 112X

The layer 112X is positioned between the layer 111X and the reflective film REFX (see FIG. 1A). A hole-transport material can be used for the layer 112X, for example. The layer 112X can be referred to as a hole-transport layer. A material having a wider bandgap than the light-emitting material contained in the layer 111X is preferably used for the layer 112X. In that case, transfer of energy from excitons generated in the layer 111X to the layer 112X can be inhibited.

The layer 112X contains an organic compound LNOM. The organic compound LNOM has a hole-transport property.

Note that the distance between the layer 111X and the layer HNX is preferably greater than 0 nm and less than or equal to 85 nm. For example, in the case where the electrode 551X forms the surface of the layer HNX close to the layer 111X, the distance between the layer 111X and the electrode 551X is preferably greater than 0 nm and less than or equal to 85 nm.

### [Organic Compound LNOM]

For example, the organic compound LNOM having a hole-transport property and an ordinary refractive index higher than or equal to 1.40 and lower than or equal to 1.75 in the blue emission range (455 nm to 465 nm inclusive) can be used for the layer 112X. Alternatively, the organic compound LNOM having a hole-transport property and an ordinary refractive index higher than or equal to 1.40 and lower than or equal to 1.70 with respect to light with a wavelength of 633 nm, which is usually used for measurement of refractive indices, can be used for the layer 112X. Note that in this specification, an ordinary refractive index with respect to light with a wavelength UL corresponds to a value obtained in such a manner that a sample in which a target layer is formed over a S1 wafer is fabricated and is measured with a spectroscopic ellipsometer. A refractive index of a sample that does not have a birefringence index is also referred to an ordinary refractive index for convenience.

Note that a value obtained by dividing the product of the ordinary refractive index of the organic compound LNOM at the wavelength kX and the distance between the layer 111X and the electrode 551X by the wavelength kX is preferably greater than 0 and less than or equal to 0.3. Part of light emitted from the layer 111X to the electrode 551X is reflected by the electrode 551X having a higher refractive index than the layer 112X and the phase of the light is inverted owing to the reflection. In other words, the phase is shifted by an amount corresponding to half the wavelength XX. Moreover, the light emitted from the layer 111X to the electrode 551X travels back and forth between the layer 111X and the electrode 551X until the light is reflected by the electrode 551X to return to the layer 111X. The value obtained by dividing the product of the ordinary refractive index of the organic compound LNOM at the wavelength λX and the distance by the wavelength λX is set to greater than 0 and less than or equal to 0.3, whereby the light emitted from the layer 111X to the electrode 551X and the light emitted from the layer 111X to the electrode 552X are intensified with each other, increasing the light extraction efficiency.

The organic compound LNOM contains carbon atoms forming bonds by sp³ hybrid orbitals at higher than or equal to 23% and lower than or equal to 55% of the total carbon atoms in the molecule.

For example, a monoamine compound including a first aromatic group, a second aromatic group, and a third aromatic group which are bonded to the same nitrogen atom can be used for the layer 112X.

In the monoamine compound, the proportion of carbon atoms forming bonds by the sp³ hybrid orbitals to the total number of carbon atoms in the molecule is preferably higher than or equal to 23% and lower than or equal to 55%. In addition, it is preferable that the integral value of signals at lower than 4 ppm exceed the integral value of signals at 4 ppm or higher in the results of ¹H-NMR measurement conducted on the monoamine compound.

The monoamine compound preferably has at least one fluorene skeleton. One or more of the first aromatic group, the second aromatic group, and the third aromatic group are preferably a fluorene skeleton.

Examples of the above-described organic compound having a hole-transport property include organic compounds having structures represented by General formulae (Gₕ₁1) to (Gₕ₁4) shown below.

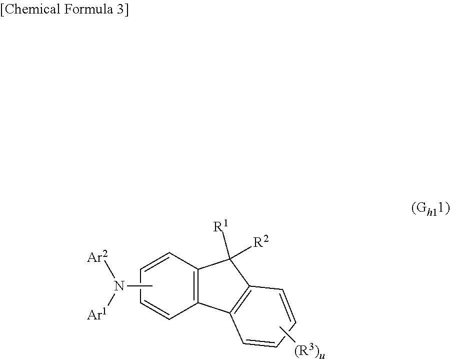

In General Formula (Gₕ₁1), each of Ar¹ and Ar² independently represents a substituent with a benzene ring or a substituent in which two or three benzene rings are bonded to each other. Note that one or both of Ar¹ and Ar² have one or more hydrocarbon groups each having 1 to 12 carbon atoms forming bonds only by the sp³ hybrid orbitals. The total number of carbon atoms contained in all of the hydrocarbon groups bonded to Ar¹ and Ar² is 8 or more and the total number of carbon atoms contained in all of the hydrocarbon groups bonded to Ar¹ or Ar² is 6 or more. Note that in the case where a plurality of straight-chain alkyl groups each having one or two carbon atoms are bonded to Ar¹ or Ar² as the hydrocarbon groups, the straight-chain alkyl groups may be bonded to each other to form a ring. As the hydrocarbon group having 1 to 12 carbon atoms forming bonds only by the sp³ hybrid orbitals, an alkyl group having 3 to 8 carbon atoms or a cycloalkyl group having 6 to 12 carbon atoms is preferable. Specifically, it is possible to use a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a heptyl group, an octyl group, a nonyl group, a decyl group, a cyclohexyl group, a 4-methylcyclohexyl group, a cycloheptyl group, a cyclooctyl group, a cyclononyl group, a cyclodecyl group, a decahydronaphthyl group, a cycloundecyl group, a cyclododecyl group, or the like. It is particularly preferable to use a t-butyl group, a cyclohexyl group, or a cyclododecyl group.

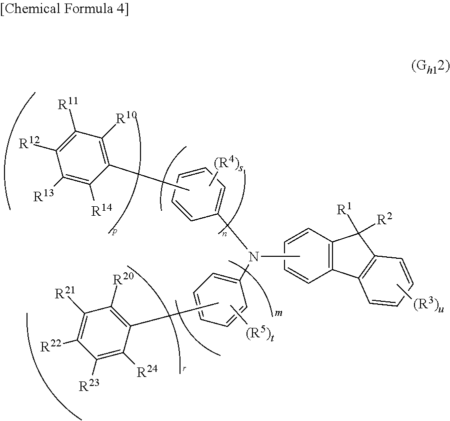

In General Formula (Gₕ₁2), each of m and r independently represents 1 or 2 and m+r is 2 or 3. Furthermore, each t independently represents an integer of 0 to 4 and is preferably 0. Each of R⁴ and R⁵ independently represents hydrogen or a hydrocarbon group having 1 to 3 carbon atoms. When m is 2, the kind and number of substituents and the position of bonds included in one phenylene group may be the same as or different from those of the other phenylene group; and when r is 2, the kind and number of substituents and the position of bonds included in one phenyl group may be the same as or different from those of the other phenyl group. In the case where t is an integer of 2 to 4, R⁵s may be the same or different from each other; and adjacent groups (adjacent R⁵s) may be bonded to each other to form a ring.

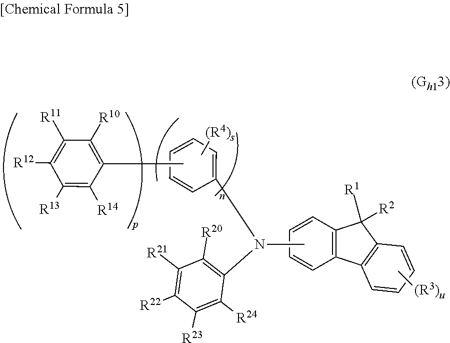

In General Formulae (Gₕ₁2) and (Gₕ₁3), each of n and p independently represents 1 or 2 and n+p is 2 or 3. In addition, each s independently represents an integer of 0 to 4 and is preferably 0. In the case where s is an integer of 2 to 4, R⁴s may be the same or different from each other. R⁴ represents hydrogen or a hydrocarbon group having 1 to 3 carbon atoms. When n is 2, the kind and number of substituents and the position of bonds in one phenylene group may be the same as or different from those of the other phenylene group; and when p is 2, the kind and number of substituents and the position of bonds in one phenyl group may be the same as or different from those of the other phenyl group. In the case where s is an integer of 2 to 4, R⁴s may be the same or different from each other. Examples of the hydrocarbon group having 1 to 3 carbon atoms include a methyl group, an ethyl group, a propyl group, and an isopropyl group.

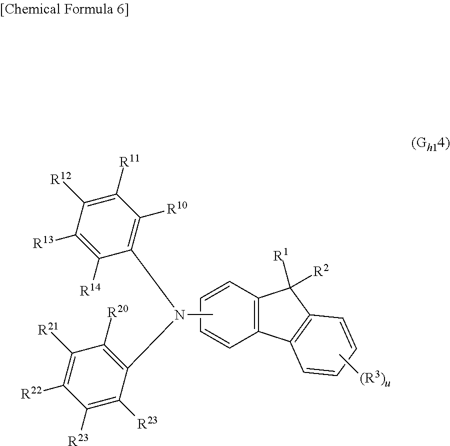

In General Formulae (Gₕ₁2) to (Gₕ₁4), each of R¹⁰ to R¹⁴ and R²⁰ to R²⁴ independently represents hydrogen or a hydrocarbon group having 1 to 12 carbon atoms each forming bonds only by the sp³ hybrid orbitals. Note that at least three of R¹⁰ to R¹⁴ and at least three of R²⁰ to R²⁴ are preferably hydrogen. As the hydrocarbon group having 1 to 12 carbon atoms each forming bonds only by the sp³ hybrid orbitals, a tert-butyl group or a cyclohexyl group is preferable. The total number of carbon atoms contained in R¹⁰ to R¹⁴ and R²⁰ to R²⁴ is 8 or more and the total number of carbon atoms contained in either R¹⁰ to R¹⁴ or R²⁰ to R²⁴ is 6 or more. Note that adjacent groups of R¹⁰ to R¹⁴ and R²⁰ to R²⁴ may be bonded to each other to form a ring.

As the hydrocarbon group having 1 to 12 carbon atoms each forming bonds only by the sp³ hybrid orbitals, an alkyl group having 3 to 8 carbon atoms or a cycloalkyl group having 6 to 12 carbon atoms is preferable. Specifically, it is possible to use a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a heptyl group, an octyl group, a cyclohexyl group, a 4-methylcyclohexyl group, a cycloheptyl group, a cyclooctyl group, a cyclononyl group, a cyclodecyl group, a decahydronaphthyl group, a cycloundecyl group, a cyclododecyl group, or the like. It is particularly preferable to use a t-butyl group, a cyclohexyl group, or a cyclododecyl group.

In General Formulae (Gₕ₁1) to (Gₕ₁4), each u independently represents an integer of 0 to 4 and is preferably 0. In the case where u is an integer of 2 to 4, R³s may be the same or different from each other. In addition, each of R¹, R², and R³ independently represents an alkyl group having 1 to 4 carbon atoms and R¹ and R² may be bonded to each other to form a ring. Examples of the hydrocarbon group having 1 to 4 carbon atoms include a methyl group, an ethyl group, a propyl group, and a butyl group.

An arylamine compound that includes at least one aromatic group having first to third benzene rings and at least three alkyl groups can also be suitably used as the organic compound LNOM. Note that the first to third benzene rings are bonded in this order and the first benzene ring is directly bonded to nitrogen of amine.

The first benzene ring may further include a substituted or unsubstituted phenyl group and preferably includes an unsubstituted phenyl group. Furthermore, the second benzene ring or the third benzene ring may include a phenyl group substituted by an alkyl group.

Note that hydrogen is not directly bonded to carbon atoms at 1- and 3-positions in two or more of, preferably all of the first to third benzene rings, and the carbon atoms are bonded to any of the first to third benzene rings, the phenyl group substituted by the alkyl group, the at least three alkyl groups, and the nitrogen of the amine.

It is preferable that the arylamine compound further include a second aromatic group. It is preferable that the second aromatic group have an unsubstituted monocyclic ring or a substituted or unsubstituted condensed ring composed of three or less rings; in particular, it is further preferable that the second aromatic group be a substituted or unsubstituted condensed ring composed of three or less rings and the condensed ring be a group having a condensed ring having 6 to 13 carbon atoms forming the ring. It is still further preferable that the second aromatic group have a benzene ring, a naphthalene ring, a fluorene ring, or an acenaphthylene ring. It is particularly preferable that the second aromatic group have a fluorene ring. Note that a dimethylfluorenyl group is preferable as the second aromatic group.

It is preferable that the arylamine compound further include a third aromatic group. The third aromatic group is a group having 1 to 3 substituted or unsubstituted benzene rings.

It is preferable that the at least three alkyl groups and the alkyl group substituted for the phenyl group be each a chain alkyl group having 2 to 5 carbon atoms. In particular, the alkyl group is preferably a chain alkyl group having a branch formed of 3 to 5 carbon atoms, and is further preferably a t-butyl group.

Examples of the above-described organic compound LNOM having a hole-transport property include organic compounds having structures represented by General Formulae (Gₕ₂1) to (Gₕ₂3) shown below.

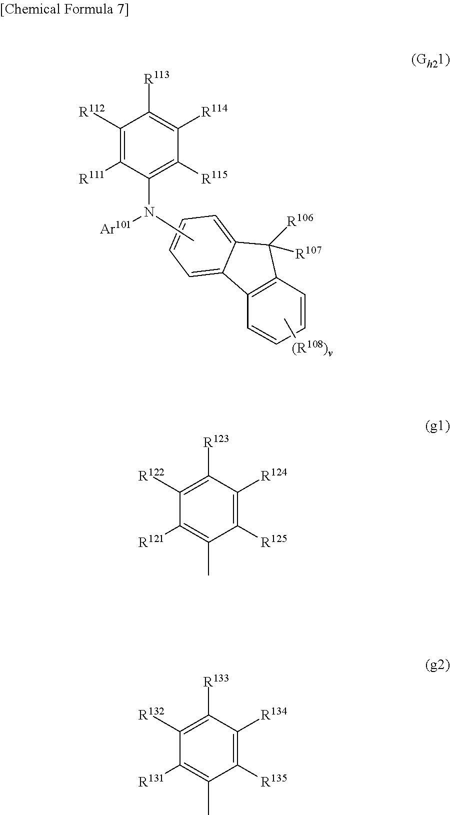

Note that in General Formula (Gₕ₂1), Ar¹⁰¹ represents a substituted or unsubstituted benzene ring or a substituent in which two or three substituted or unsubstituted benzene rings are bonded to one another.

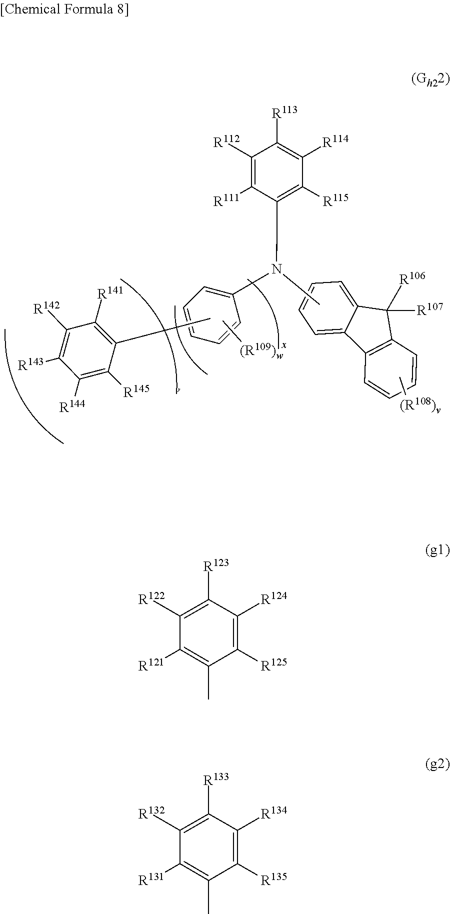

Note that in General Formula (Gₕ₂2), each of x and y independently represents 1 or 2 and x+y is 2 or 3. Furthermore, R¹⁰⁹ represents an alkyl group having 1 to 4 carbon atoms, and w represents an integer of 0 to 4. Each of R¹⁴¹ to R¹⁴⁵ independently represents any one of hydrogen, an alkyl group having 1 to 6 carbon atoms, and a cycloalkyl group having 5 to 12 carbon atoms. When w is 2 or more, R¹⁰⁹s may be the same or different from each other. When x is 2, the kind and number of substituents and the position of bonds included in one phenylene group may be the same as or different from those of the other phenylene group. When y is 2, the kind and number of substituents included in one phenyl group including R¹⁴¹ to R¹⁴⁵ may be the same as or different from those of the other phenyl group including R¹⁴¹ to R¹⁴⁵.

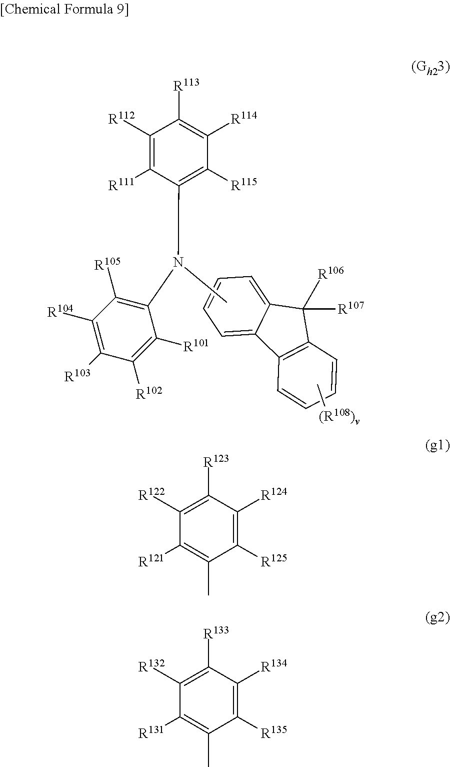

In General Formula (Gₕ₂3), each of R¹⁰¹ to R¹⁰⁵ independently represents any one of hydrogen, an alkyl group having 1 to 6 carbon atoms, a cycloalkyl group having 6 to 12 carbon atoms, and a substituted or unsubstituted phenyl group.

In General Formulae (Gₕ₂1) to (Gₕ₂3), each of R¹⁰⁶, R¹⁰⁷, and R¹⁰⁸ independently represents an alkyl group having 1 to 4 carbon atoms, and v represents an integer of 0 to 4. When v is 2 or more, R¹⁰⁸s may be the same or different from each other. One of R¹¹¹ to R¹¹⁵ represents a substituent represented by General Formula (g1), and each of the others independently represents any one of hydrogen, an alkyl group having 1 to 6 carbon atoms, and a substituted or unsubstituted phenyl group. In General Formula (g1), one of R¹²¹ to R¹²⁵ represents a substituent represented by General Formula (g2), and each of the others independently represents any one of hydrogen, an alkyl group having 1 to 6 carbon atoms, and a phenyl group substituted by an alkyl group having 1 to 6 carbon atoms. In General Formula (g2), each of R¹³¹ to R¹³⁵ independently represents any one of hydrogen, an alkyl group having 1 to 6 carbon atoms, and a phenyl group substituted by an alkyl group having 1 to 6 carbon atoms. Note that at least three of R¹¹¹ to R¹¹⁵, R¹²¹ to R¹²⁵, and R¹³¹ to R¹³⁵ are each an alkyl group having 1 to 6 carbon atoms; the number of substituted or unsubstituted phenyl groups in R¹¹¹ to R¹¹⁵ is one or less; and the number of phenyl groups substituted by an alkyl group having 1 to 6 carbon atoms in R¹²¹ to R¹²⁵ and R¹³¹ to R¹³⁵ is one or less. In at least two combinations of the three combinations R¹¹² and R¹¹⁴, R¹²² and R¹²⁴, and R¹³² and R¹³⁴, at least one R represents any of the substituents other than hydrogen.

In the case where the substituted or unsubstituted benzene ring or the substituted or unsubstituted phenyl group has a substituent in any of General Formulae (Gₕ₂1) to (Gₕ₂3), the substituent can be an alkyl group having 1 to 6 carbon atoms or a cycloalkyl group having 5 to 12 carbon atoms. The alkyl group having 1 to 4 carbon atoms is preferably a methyl group, an ethyl group, a propyl group, an isopropyl group, a butyl group, a sec-butyl group, an isobutyl group, or a tert-butyl group. The alkyl group having 1 to 6 carbon atoms is preferably a chain alkyl group having 2 or more carbon atoms; in terms of ensuring the carrier-transport property, a chain alkyl group having 5 or less carbon atoms is preferable. A chain alkyl group having a branch formed of 3 or more carbon atoms is significantly effective in lowering the refractive index. That is, the alkyl group having 1 to 6 carbon atoms is preferably a chain alkyl group having 2 to 5 carbon atoms, and further preferably a chain alkyl group having a branch formed of 3 to 5 carbon atoms. As the alkyl group having 1 to 6 carbon atoms, a methyl group, an ethyl group, a propyl group, an isopropyl group, a butyl group a sec-butyl group, an isobutyl group, a tert-butyl group, or a pentyl group is preferable. In particular, a tert-butyl group is preferred. Note that as the cycloalkyl group having 5 to 12 carbon atoms, a cyclohexyl group, a 4-methylcyclohexyl group, a cycloheptyl group, a cyclooctyl group, a cyclononyl group, a cyclodecyl group, a decahydronaphthyl group, a cycloundecyl group, a cyclododecyl group, or the like can be used. In terms of lowering the refractive index, a cycloalkyl group having 6 or more carbon atoms is preferred, and in particular, a cyclohexyl group or a cyclododecyl group is preferred.

The above-described organic compounds having a favorable hole-transport property each have an ordinary refractive index higher than or equal to 1.40 and lower than or equal to 1.75 in the blue emission range (455 nm to 465 nm inclusive) or an ordinary refractive index higher than or equal to 1.40 and lower than or equal to 1.70 with respect to light with a wavelength of 633 nm, which is usually used for measurement of refractive indices. The organic compounds can have both a high glass transition temperature (Tg) and favorable reliability. Such organic compounds also have a sufficient hole-transport property.

Preferable examples of such a material include N,N-bis(4-cyclohexylphenyl)-9,9-dimethyl-9H-fluoren-2-amine (abbreviation: dchPAF), N-[(4′-cyclohexyl)biphenyl-4-yl]-N-(4-cyclohexylphenyl)-9,9-dimethyl-9H-fluoren-2-amine (abbreviation: chBichPAF), N,N-bis(4-cyclohexylphenyl)-N-(spiro[cyclohexane-1,9′-[9H]fluoren]-2′-yl)amine (abbreviation: dchPASchF), N-[(4′-cyclohexyl)biphenyl-4-yl]-N-(4-cyclohexylphenyl)-N-(spiro[cyclohexane-1,9′-[9H]fluoren]-2′-yl)amine (abbreviation: chBichPASchF), N-(4-cyclohexylphenyl)bis(spiro[cyclohexane-1,9′-[9H]fluoren]-2′-yl)amine (abbreviation: SchFB1chP), N-[(3′,5′-ditertiarybutyl)-1,1′-biphenyl-4-yl]-N-(4-cyclohexylphenyl)-9,9-dimethyl-9H-fluoren-2-amine (abbreviation: mmtBuBichPAF), N,N-bis(3′,5′-ditertiarybutyl-1,1′-biphenyl-4-yl)-9,9-dimethyl-9H-fluoren-2-amine (abbreviation: dmmtBuBiAF), N-(3,5-ditertiarybutylphenyl)-N-(3′,5′-ditertiarybutyl-1,1′-biphenyl-4-yl)-9,9-dimethyl-9H-fluoren-2-amine (abbreviation: mmtBuBimmtBuPAF), N,N-bis(4-cyclohexylphenyl)-9,9-dipropyl-9H-fluoren-2-amine (abbreviation: dchPAPrF), N-[(3′,5′-dicyclohexyl)-1,1′-biphenyl-4-yl]-N-(4-cyclohexylphenyl)-9,9-dimethyl-9H-fluoren-2-amine (abbreviation: mmchBichPAF), N-(3,3″,5,5″-tetra-t-butyl-1,1′:3,1″-terphenyl-5′-yl)-N-(4-cyclohexylphenyl)-9,9-dimeth yl-9H-fluoren-2-amine (abbreviation: mmtBumTPchPAF), N-(4-cyclododecylphenyl)-N-(4-cyclohexylphenyl)-9,9-dimethyl-9H-fluoren-2-amine (abbreviation: CdoPchPAF), N-(3,3″,5,5″-tetra-t-butyl-1,1′: 3,1″-terphenyl-5′-yl)-N-phenyl-9,9-dimethyl-9H-fluoren-2-amine (abbreviation: mmtBumTPFA), N-(1,1′-biphenyl-4-yl)-N-(3,3″,5,5″-tetra-t-butyl-1,1′: 3,1″-terphenyl-5′-yl)-9,9-dimethyl-9H-fluoren-2-amine (abbreviation: mmtBumTPFBi), N-(1,1′-biphenyl-2-yl)-N-(3,3″,5,5″-tetra-t-butyl-1,1′: 3,1″-terphenyl-5′-yl)-9,9-dimethyl-9H-fluoren-2-amine (abbreviation: mmtBumTPoFBi), N-[(3,3′,5′-tri-t-butyl)-1,1′-biphenyl-5-yl]-N-(4-cyclohexylphenyl)-9,9-dimethyl-9H-fluo ren-2-amine (abbreviation: mmtBumBichPAF), N-(1,1′-biphenyl-2-yl)-N-[(3,3′,5′-tri-t-butyl)-1,1′-biphenyl-5-yl]-9,9-dimethyl-9H-fluoren-2-amine (abbreviation: mmtBumBioFBi), N-(4-tert-butylphenyl)-N-(3,3″,5,5″-tetra-t-butyl-1,1′: 3,1″-terphenyl-5′-yl)-9,9-dimethyl-9H-fluoren-2-amine (abbreviation: mmtBumTPtBuPAF), N-(3,3″,5′,5″-tetra-tert-butyl-1,1′: 3,1″-terphenyl-5-yl)-N-phenyl-9,9-dimethyl-9H-fluoren-2-amine (abbreviation: mmtBumTPFA-02), N-(1,1′-biphenyl-4-yl)-N-(3,3″,5′,5″-tetra-tert-butyl-1,1′: 3,1″-terphenyl-5-yl)-9,9-dimeth yl-9H-fluoren-2-amine (abbreviation: mmtBumTPFBi-02), N-(1,1′-biphenyl-2-yl)-N-(3,3″,5′,5″-tetra-tert-butyl-1,1′: 3,1″-terphenyl-5-yl)-9,9-dimeth yl-9H-fluoren-2-amine (abbreviation: mmtBumTPoFBi-02), N-(4-cyclohexylphenyl)-N-(3,3″,5′,5″-tetra-tert-butyl-1,1′: 3′,1″-terphenyl-5-yl)-9,9-dimethyl-9H-fluoren-2-amine (abbreviation: mmtBumTPchPAF-02), N-(1,1′-biphenyl-2-yl)-N-(3″,5′,5″-tri-tert-butyl-1,1′: 3,1″-terphenyl-5-yl)-9,9-dimethyl-9H-fluoren-2-amine (abbreviation: mmtBumTPoFBi-03), N-(4-cyclohexylphenyl)-N-(3″,5′,5″-tri-tert-butyl-1,1′: 3′,1″-terphenyl-5-yl)-9,9-dimethyl-9H-fluoren-2-amine (abbreviation: mmtBumTPchPAF-03), N-(1,1′-biphenyl-2-yl)-N-(3″,5′,5″-tri-tert-butyl-1,1′: 3,1″-terphenyl-4-yl)-9,9-dimethyl-9H-fluoren-2-amine (abbreviation: mmtBumTPoFBi-04), N-(4-cyclohexylphenyl)-N-(3″,5′,5″-tri-tert-butyl-1,1′: 3′,1″-terphenyl-4-yl)-9,9-dimethyl-9H-fluoren-2-amine (abbreviation: mmtBumTPchPAF-04), N-(1,1′-biphenyl-2-yl)-N-(3,3″,5″-tri-tert-butyl-1,1′: 4′,1″-terphenyl-5-yl)-9,9-dimethyl-9H-fluoren-2-amine (abbreviation: mmtBumTPoFBi-05), N-(4-cyclohexylphenyl)-N-(3,3″,5″-tri-tert-butyl-1,1′: 4′,1″-terphenyl-5-yl)-9,9-dimethyl-9H-fluoren-2-amine (abbreviation: mmtBumTPchPAF-05), and N-(3′,5′-ditertiarybutyl-1,1′-biphenyl-4-yl)-N-(1,1′-biphenyl-2-yl)-9,9-dimethyl-9H-fluoren-2-amine (abbreviation: mmtBuBioFBi).

Alternatively, 1,1-bis-[4-bis(4-methyl-phenyl)-amino-phenyl]-cyclohexane (abbreviation: TAPC) or the like can be used.

### Structure Example of Layer 113X

An electron-transport material, a material having an anthracene skeleton, and a mixed material can be used for the layer 113X, for example. The layer 113X can be referred to as an electron-transport layer. A material having a wider bandgap than the light-emitting material contained in the layer 111X is preferably used for the layer 113X. In that case, energy transfer from excitons generated in the layer 111X to the layer 113X can be inhibited.

### [Electron-Transport Material]

For example, a material having an electron mobility higher than or equal to 1×10⁻⁷ cm²/Vs and lower than or equal to 5×10⁻⁵ cm²/Vs when the square root of the electric field strength [V/cm] is 600 can be suitably used as the electron-transport material. In this case, the electron-transport property in the electron-transport layer can be suppressed. The amount of electrons injected into the light-emitting layer can be controlled. The light-emitting layer can be prevented from having excess electrons.

A metal complex or an organic compound having a π-electron deficient heteroaromatic ring skeleton can be used as the electron-transport material. For example, an electron-transport material capable of being used as a host material can be used for the layer 113X.

### [Material Having Anthracene Skeleton]

An organic compound having an anthracene skeleton can be used for the layer 113X. In particular, an organic compound having both an anthracene skeleton and a heterocyclic skeleton can be suitably used.

For example, an organic compound having both an anthracene skeleton and a nitrogen-containing five-membered ring skeleton can be used for the layer 113X. Alternatively, an organic compound having both an anthracene skeleton and a nitrogen-containing five-membered ring skeleton where two heteroatoms are included in a ring can be used for the layer 113X. Specifically, it is preferable to use, as the heterocyclic skeleton, a pyrazole ring, an imidazole ring, an oxazole ring, a thiazole ring, or the like.

For example, an organic compound having both an anthracene skeleton and a nitrogen-containing six-membered ring skeleton can be used for the layer 113X. Alternatively, an organic compound having both an anthracene skeleton and a nitrogen-containing six-membered ring skeleton where two heteroatoms are included in a ring can be used for the layer 113X. Specifically, it is preferable to use, as the heterocyclic skeleton, a pyrazine ring, a pyrimidine ring, a pyridazine ring, or the like.

### Structure Example of Mixed Material

A material in which a plurality of kinds of substances are mixed can be used for the layer 113X. Specifically, a mixed material which contains an alkali metal, an alkali metal compound, or an alkali metal complex and an electron-transport substance can be used for the layer 113X. Note that the electron-transport material preferably has a HOMO level of −6.0 eV or higher.

The mixed material can be suitably used for the layer 113X in combination with a structure using a composite material, which is separately described, for the layer 104X. For example, a composite material of an electron-accepting substance and a hole-transport material can be used for the layer 104X. Specifically, a composite material of an electron-accepting substance and a substance having a relatively deep HOMO level HM1, which is higher than or equal to −5.7 eV and lower than or equal to −5.4 eV, can be used for the layer 104X (see FIG. 2A). Using the mixed material for the layer 113X in combination with the structure using such a composite material for the layer 104X leads to an increase in the reliability of the light-emitting device.

Furthermore, a structure using a hole-transport material for the layer 112X is preferably combined with the structure using the mixed material for the layer 113X and the composite material for the layer 104X. For example, a substance having a HOMO level HM2, which differs by −0.2 eV to 0 eV from the relatively deep HOMO level HM1, can be used for the layer 112X (see FIG. 2A). This leads to an increase in the reliability of the light-emitting device. Note that in this specification and the like, the structure of the above-described light-emitting device may be referred to as a Recombination-Site Tailoring Injection structure (ReSTI structure).

The concentration of the alkali metal, the alkali metal compound, or the alkali metal complex preferably changes in the thickness direction of the layer 113X (including the case where the concentration is 0).

For example, a metal complex having an 8-hydroxyquinolinato structure can be used. A methyl-substituted product of the metal complex having an 8-hydroxyquinolinato structure (e.g., a 2-methyl-substituted product or a 5-methyl-substituted product) or the like can also be used.

As the metal complex having an 8-hydroxyquinolinato structure, 8-hydroxyquinolinato-lithium (abbreviation: Liq), 8-hydroxyquinolinato-sodium (abbreviation: Naq), or the like can be used. In particular, a complex of a monovalent metal ion, especially a complex of lithium is preferable, and Liq is further preferable.

### Structure Example 1 of Layer HNX

The layer HNX is positioned between the layer 112X and the reflective film REFX (see FIG. 1A). The layer HNX has a property of transmitting light with the wavelength λX. The layer HNX includes the electrode 551X.

Note that the thickness of the layer HNX is preferably larger than 0 nm and smaller than or equal to 80 nm.

For example, the layer HNX can have a structure in which a plurality of films are stacked. Specifically, a film in which a layer HNX1 and the electrode 551X are stacked can be used as the layer HNX. Alternatively, a film containing an inorganic compound, a film containing an organic compound, or a stacked film of an inorganic compound and an organic compound can be used as the layer HNX.

Note that an element having a larger principal quantum number tends to have larger polarizability. Furthermore, an element in which an electron travels an orbital more distant from its atomic nucleus tends to have larger polarizability. Moreover, the refractive index increases depending on the polarizability. Thus, the refractive index of the layer HNX can be increased when an element with a larger atomic number or an element in the later period is used for the layer HNX. For example, a material containing an element with an atomic number of 21 to 83 at 5 atomic % or higher can be used for the layer HNX.

### Structure Example 2 of Layer HNX

For example, a material having a higher ordinary refractive index than the layer 112X at the wavelength λX can be used for the layer HNX (see FIG. 1). The difference in ordinary refractive index between the layer HNX and the layer 112X is larger than or equal to 0.2 and smaller than or equal to 1.5. Specifically, a material having an ordinary refractive index higher than or equal to 1.9 and lower than or equal to 3.0 at the wavelength λX can be suitably used for the layer HNX.

Note that a value obtained by dividing the product of the ordinary refractive index of the layer HNX at the wavelength λX and the thickness of the layer HNX by the wavelength λX is preferably greater than or equal to 0.05 and less than or equal to 0.375, further preferably 0.25. Part of light emitted from the layer 111X to the layer HNX is reflected by the layer HNX having a higher refractive index than the layer 112X and the phase of the light is inverted owing to the reflection. In other words, the phase is shifted by an amount corresponding to half the wavelength λX. Moreover, the other part of the light emitted from the layer 111X to the layer HNX is reflected by the layer LNX having a lower refractive index than the layer HNX and travels back and forth in the layer HNX in the thickness direction. The value obtained by dividing the product of the ordinary refractive index of the layer HNX at the wavelength λX and the thickness thereof by the wavelength λX is set to greater than or equal to 0.05 and less than or equal to 0.375, whereby the light reflected by a surface of the layer HNX close to the layer 111X and the light reflected by a surface of the layer HNX close to the layer LNX are intensified with each other, increasing the light extraction efficiency.

Specifically, an oxide containing indium, tin, zinc, gallium, or titanium can be used for the layer HNX, for example.

A material having both a light-transmitting property and conductivity can be used for the electrode 551X. Note that a structure example that can be employed for the electrode 551X is described in detail in Embodiment 2.

### Structure Example 1 of Layer LNX

The layer LNX is positioned between the layer HNX and the reflective film REFX. The layer LNX has a property of transmitting light with the wavelength λX.

Note that the thickness of the layer LNX is preferably larger than 0 nm and smaller than or equal to 90 nm.

For example, a film containing an inorganic compound, a film containing an organic compound, or a stacked film of an inorganic compound and an organic compound can be used as the layer LNX.

For example, a material containing an element with an atomic number of 1 to 20 at 95 atomic % or higher can be used for the layer LNX.

### Structure Example 2 of Layer LNX

The layer LNX has a lower ordinary refractive index than the layer HNX at the wavelength λX. The difference in ordinary refractive index at the wavelength λX between the layer LNX and the layer HNX is larger than or equal to 0.2 and smaller than or equal to 1.8.

The layer LNX has an insulating property and an ordinary refractive index higher than or equal to 1.20 and lower than or equal to 1.70 at the wavelength λX.

Note that a value obtained by dividing the product of the ordinary refractive index of the layer LNX at the wavelength λX and the thickness of the layer LNX by the wavelength λX is preferably greater than 0 and less than or equal to 0.3. Part of light emitted from the layer 111X to the layer HNX is reflected by the layer LNX having a lower refractive index than the layer HNX. The other part of the light emitted from the layer 111X to the layer HNX transmits the layer LNX and is reflected by the reflective film REFX, and the phase of the light is inverted owing to the reflection. In other words, the phase is shifted by an amount corresponding to half the wavelength λX. The light travels back and forth in the layer LNX in the thickness direction. The value obtained by dividing the product of the ordinary refractive index of the layer LNX at the wavelength λX and the thickness of the layer LNX by the wavelength λX is set to greater than 0 and less than or equal to 0.3, whereby the light reflected by a surface of the layer LNX close to the layer 111X and the light reflected by a surface of the layer LNX close to the reflective film REFX are intensified with each other, increasing the light extraction efficiency.

Specifically, silicon oxide, aluminum oxide, lithium fluoride, sodium fluoride, potassium fluoride, magnesium fluoride, calcium fluoride, or the like can be used for the layer LNX.

### Structure Example 1 of Reflective Film REFX

The reflective film REFX reflects light with the wavelength λX. A film that efficiently reflects light can be used for the reflective film REFX, for example. Specifically, an alloy containing silver, copper, and the like, an alloy containing silver, palladium, and the like, or a metal film of silver, magnesium, titanium, aluminum, or the like can be used for the reflective film REFX.

Thus, the layer 112X has a lower ordinary refractive index than the layer HNX. The layer HNX has a higher ordinary refractive index than the layer LNX. Light emitted from the layer 111X to the reflective film REFX goes through the region having a low ordinary refractive index and then the region having a high ordinary refractive index. Part of the light can be reflected between the layer 112X and the layer HNX. The reflected light and light emitted from the layer 111X to the electrode 552X can interfere with each other to be intensified. The other part of the light goes through the region having a high ordinary refractive index and then the region having a low ordinary refractive index. Part thereof can be reflected between the layer HNX and the layer LNX. The reflected light and the light emitted from the layer 111X to the electrode 552X can interfere with each other to be intensified. The reflected light and the light reflected between the layer 112X and the layer HNX can interfere with each other to be intensified. The light reflected by the reflective film REFX and the light emitted from the layer 111X to the electrode 552X can also interfere with each other to be intensified. Thus, the light emitted from the layer 111X can be extracted efficiently. As a result, a novel light-emitting device that is highly convenient, useful, or reliable can be provided.

### Structure Example 2 of Reflective Film REFX

The reflective film REFX has conductivity and is electrically connected to the electrode 551X (see FIG. 2B).

Thus, a wiring can be used as the reflective film REFX, for example. Furthermore, the structure of the light-emitting device can be simplified. As a result, a novel light-emitting device that is highly convenient, useful, or reliable can be provided.

This embodiment can be combined with any of the other embodiments and example in this specification as appropriate.

### Embodiment 2

In this embodiment, a structure of the light-emitting device 550X of one embodiment of the present invention is described with reference to FIG. 1A.

### Structure Example of Light-Emitting Device 550X

The light-emitting device 550X described in this embodiment includes the reflective film REFX, the layer LNX, the layer HNX, the layer 104X, the unit 103X, and the electrode 552X (see FIG. 1A). The layer HNX includes the electrode 551X. Note that the layer 104X is positioned between the electrode 551X and the unit 103X. For example, the reflective film REFX, the layer LNX, the layer HNX, and the unit 103X can have the structures described in Embodiment 1.

### Structure Example of Electrode 551X

For example, a conductive material can be used for the electrode 551X. Specifically, a film having a property of transmitting visible light can be used for the electrode 551X. For example, a single layer or a stack using a metal film, an alloy film, a conductive oxide film, or the like that is thin enough to transmit light can be used for the electrode 551X.

In particular, a material having a work function higher than or equal to 4.0 eV can be suitably used for the electrode 551X.

For example, a conductive oxide containing indium can be used. Specifically, indium oxide, indium oxide-tin oxide (abbreviation: ITO), indium oxide-tin oxide containing silicon or silicon oxide (abbreviation: ITSO), indium oxide-zinc oxide, indium oxide containing tungsten oxide and zinc oxide (abbreviation: IWZO), or the like can be used.

For another example, a conductive oxide containing zinc can be used. Specifically, zinc oxide, zinc oxide to which gallium is added, zinc oxide to which aluminum is added, or the like can be used.

Furthermore, for example, gold (Au), platinum (Pt), nickel (Ni), tungsten (W), chromium (Cr), molybdenum (Mo), iron (Fe), cobalt (Co), copper (Cu), palladium (Pd), or a nitride of a metal material (e.g., titanium nitride) can be used. Graphene can also be used.

### Structure Example 1 of Layer 104X

A hole-injection material can be used for the layer 104X, for example. The layer 104X can be referred to as a hole-injection layer.

For example, a material having a hole mobility lower than or equal to 1×10⁻³ cm²/Vs when the square root of the electric field strength [V/cm] is 600 can be used for the layer 104X. A film having an electrical resistivity greater than or equal to 1×10⁴ Ω·cm and less than or equal to 1×10⁷ Ω·cm can be used as the layer 104X. The electrical resistivity of the layer 104X is preferably greater than or equal to 5×10⁴ Ω·cm and less than or equal to 1×10⁷ Ω·cm, further preferably greater than or equal to 1×10⁵ Ω·cm and less than or equal to 1×10⁷ Ω·cm.

### Structure Example 2 of Layer 104X

Specifically, an electron-accepting substance can be used for the layer 104X. Alternatively, a composite material containing a plurality of kinds of substances can be used for the layer 104X. This can facilitate the injection of holes from the electrode 551X, for example. Alternatively, the driving voltage of the light-emitting device 550X can be reduced.

### [Electron-Accepting Substance]

An organic compound or an inorganic compound can be used as the electron-accepting substance. The electron-accepting substance can extract electrons from an adjacent hole-transport layer or a hole-transport material by the application of an electric field.

For example, a compound having an electron-withdrawing group (a halogen group or a cyano group) can be used as the electron-accepting substance. Note that an electron-accepting organic compound is easily evaporated, which facilitates film deposition. Thus, the productivity of the light-emitting device 550X can be increased.

Specifically, 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), 2-(7-dicyanomethylene-1,3,4,5,6,8,9,10-octafluoro-7H-pyren-2-ylidene)malononitrile, or the like can be used.

A compound in which electron-withdrawing groups are bonded to a condensed aromatic ring having a plurality of heteroatoms, such as HAT-CN, is particularly preferable because it is thermally stable.

A [3]radialene derivative having an electron-withdrawing group (in particular, a cyano group or a halogen group such as a fluoro group) has a very high electron-accepting property and thus is preferred.

Specifically, α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], α,α′,α″-1,2,3-cyclopropanetriylidenetris[2,3,4,5,6-pentafluorobenzeneacetonitrile], or the like can be used.

For the electron-accepting substance, a transition metal oxide such as a molybdenum oxide, a vanadium oxide, a ruthenium oxide, a tungsten oxide, or a manganese oxide can be used.

It is possible to use any of the following materials: phthalocyanine-based compounds such as phthalocyanine (abbreviation: H₂Pc); phthalocyanine-based complex compounds such as copper phthalocyanine (abbreviation: CuPc); and compounds having an aromatic amine skeleton such as 4,4′-bis[N-(4-diphenylaminophenyl)-N-phenylamino]biphenyl (abbreviation: DPAB) and N,N′-bis[4-bis(3-methylphenyl)aminophenyl]-N,N′-diphenyl-4,4′-diaminobiphenyl (abbreviation: DNTPD).

In addition, high molecular compounds such as poly(3,4-ethylenedioxythiophene)/poly(styrenesulfonic acid) (abbreviation: PEDOT/PSS), and the like can be used.

### Structure Example 1 of Composite Material

For example, a composite material containing an electron-accepting substance and a hole-transport material can be used for the layer 104X. Accordingly, not only a material having a high work function but also a material having a low work function can also be used for the electrode 551X. Alternatively, a material used for the electrode 551X can be selected from a wide range of materials regardless of its work function.

For the hole-transport material in the composite material, for example, a compound having an aromatic amine skeleton, a carbazole derivative, an aromatic hydrocarbon, an aromatic hydrocarbon having a vinyl group, or a high molecular compound (such as an oligomer, a dendrimer, or a polymer) can be used. A material having a hole mobility of 1×10⁻⁶ cm²/Vs or higher can be suitably used as the hole-transport material in the composite material. For example, the hole-transport material that can be used for the layer 112X, such as the organic compound LNOM, can be used for the composite material. Furthermore, the hole-transport material that can be used as the host material in the layer 111X can be used for the composite material.

A substance having a relatively deep HOMO level can be suitably used as the hole-transport material in the composite material. Specifically, the HOMO level is preferably higher than or equal to −5.7 eV and lower than or equal to −5.4 eV. Accordingly, hole injection to the unit 103X can be facilitated. Hole injection to the layer 112X can be facilitated. The reliability of the light-emitting device 550X can be increased.

As the compound having an aromatic amine skeleton, for example, N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis[4-bis(3-methylphenyl)aminophenyl]-N,N′-diphenyl-4,4′-diaminobiphenyl (abbreviation: DNTPD), or 1,3,5-tris[N-(4-diphenylaminophenyl)-N-phenylamino]benzene (abbreviation: DPA3B) can be used.

As the carbazole derivative, for example, 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthracenyl)phenyl]-9H-carbazole (abbreviation: CzPA), or 1,4-bis[4-(N-carbazolyl)phenyl]-2,3,5,6-tetraphenylbenzene can be used.

As the aromatic hydrocarbon, for example, 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, pentacene, or coronene can be used.

As the aromatic hydrocarbon having a vinyl group, for example, 4,4′-bis(2,2-diphenylvinyl)biphenyl (abbreviation: DPVBi) or 9,10-bis[4-(2,2-diphenylvinyl)phenyl]anthracene (abbreviation: DPVPA) can be used.

As the high molecular compound, for example, poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), or poly[N,N′-bis(4-butylphenyl)-N,N′-bis(phenyl)benzidine] (abbreviation: Poly-TPD) can be used.

Furthermore, a substance having any of a carbazole skeleton, a dibenzofuran skeleton, a dibenzothiophene skeleton, and an anthracene skeleton can be suitably used as the hole-transport material in the composite material, for example. Moreover, a substance including any of the following can be used as the hole-transport material in the composite material: an aromatic amine having a substituent that includes a dibenzofuran ring or a dibenzothiophene ring, an aromatic monoamine that includes a naphthalene ring, and an aromatic monoamine in which a 9-fluorenyl group is bonded to nitrogen of amine through an arylene group. With the use of a substance including an N,N-bis(4-biphenyl)amino group, the reliability of the light-emitting device 550X can be increased.

Specific examples of the above-described substances include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N′-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N′-bis(biphenyl-4-yl)-9,9′-spirobi[9H-fluoren]-2-amine (abbreviation: BBASF), N,N′-bis(biphenyl-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi[9H-fluoren]-4-ami ne (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), N,N′-bis(9,9-dimethyl-9H-fluoren-2-yl)-9,9′-spirobi-9H-fluoren-4-amine, N,N′-bis(9,9-dimethyl-9H-fluoren-2-yl)-9,9′-spirobi-9H-fluoren-3-amine, N,N′-bis(9,9-dimethyl-9H-fluoren-2-yl)-9,9′-spirobi-9H-fluoren-2-amine, and N,N′-bis(9,9-dimethyl-9H-fluoren-2-yl)-9,9′-spirobi-9H-fluoren-1-amine.

### Structure Example 2 of Composite Material

For example, a composite material including an electron-accepting substance, a hole-transport material, and a fluoride of an alkali metal or a fluoride of an alkaline earth metal can be used as the hole-injection material. In particular, a composite material in which the proportion of fluorine atoms is higher than or equal to 20% can be suitably used. Thus, the refractive index of the layer 104X can be reduced. A layer with a low refractive index can be formed inside the light-emitting device 550X. The external quantum efficiency of the light-emitting device 550X can be improved.

This embodiment can be combined with any of the other embodiments and example in this specification as appropriate.

### Embodiment 3

In this embodiment, a structure of the light-emitting device 550X of one embodiment of the present invention which can be used for a display apparatus is described with reference to FIG. 1A.

### Structure Example of Light-Emitting Device 550X

The light-emitting device 550X described in this embodiment includes the reflective film REFX, the layer LNX, the layer HNX, the layer 104X, the unit 103X, and the electrode 552X (see FIG. 1A). The layer HNX includes the electrode 551X. Note that the layer 105X is positioned between the electrode 552X and the unit 103X. For example, the reflective film REFX, the layer LNX, the layer HNX, and the unit 103X can have the structures described in Embodiment 1.

### Structure Example of Electrode 552X

For example, a conductive material can be used for the electrode 552X. Specifically, a single layer or a stack using a metal, an alloy, or a material containing a conductive compound can be used for the electrode 552X.

For example, silver, magnesium, aluminum, indium, tin, zinc, gallium, or titanium can be used for the electrode 552X. Furthermore, the material that can be used for the electrode 551X described in Embodiment 2 can be used for the electrode 552X. In particular, a material having a lower work function than the electrode 551X can be suitably used for the electrode 552X. Specifically, a material having a work function lower than or equal to 3.8 eV is preferably used.

For example, an element belonging to Group 1 of the periodic table, an element belonging to Group 2 of the periodic table, a rare earth metal, or an alloy containing any of these elements can be used for the electrode 552X.

Specifically, an element such as lithium (Li) or cesium (Cs), an element such as magnesium (Mg), calcium (Ca), or strontium (Sr), an element such as europium (Eu) or ytterbium (Yb), or an alloy containing any of these elements such as an alloy of magnesium and silver or an alloy of aluminum and lithium can be used for the electrode 552X.

### Structure Example of Layer 105X

An electron-injection material can be used for the layer 105X, for example. The layer 105X can be referred to as an electron-injection layer.

Specifically, an electron-donating substance can be used for the layer 105X. Alternatively, a material in which an electron-donating substance and an electron-transport material are combined can be used for the layer 105X. Alternatively, electrode can be used for the layer 105X. This can facilitate the injection of electrons from the electrode 552X, for example. Alternatively, not only a material having a low work function but also a material having a high work function can also be used for the electrode 552X. Alternatively, a material used for the electrode 552X can be selected from a wide range of materials regardless of its work function. Specifically, aluminum (Al), silver (Ag), indium oxide-tin oxide (abbreviation: ITO), indium oxide-tin oxide containing silicon or silicon oxide, or the like can be used for the electrode 552X. The driving voltage of the light-emitting device 550X can be reduced.

### [Electron-Donating Substance]

For example, an alkali metal, an alkaline earth metal, a rare earth metal, or a compound thereof (an oxide, a halide, a carbonate, or the like) can be used as the electron-donating substance. Alternatively, an organic compound such as tetrathianaphthacene (abbreviation: TTN), nickelocene, or decamethylnickelocene can be used as the electron-donating substance.

As an alkali metal compound (including an oxide, a halide, and a carbonate), lithium oxide, lithium fluoride (LiF), cesium fluoride (CsF), lithium carbonate, cesium carbonate, 8-hydroxyquinolinato-lithium (abbreviation: Liq), or the like can be used.

As an alkaline earth metal compound (including an oxide, a halide, and a carbonate), calcium fluoride (CaF₂) or the like can be used.

### Structure Example 1 of Composite Material

A material composed of two or more kinds of substances can be used as the electron-injection material. For example, an electron-donating substance and an electron-transport material can be used for the composite material.

### [Electron-Transport Material]

A material having an electron mobility higher than or equal to 1×10⁻⁷ cm²/Vs and lower than or equal to 5×10⁻⁵ cm²/Vs when the square root of the electric field strength [V/cm] is 600 can be suitably used as the electron-transport material. In this case, the amount of electrons injected into the light-emitting layer can be controlled. The light-emitting layer can be prevented from having excess electrons.

A metal complex or an organic compound having a π-electron deficient heteroaromatic ring skeleton can be used as the electron-transport material. For example, an electron-transport material that can be used for the layer 113X can be used for the layer 111X.

### Structure Example 2 of Composite Material

A material including a fluoride of an alkali metal in a microcrystalline state and an electron-transport material can be used for the composite material. Alternatively, a material including a fluoride of an alkaline earth metal in a microcrystalline state and an electron-transport material can be used for the composite material. In particular, a composite material including a fluoride of an alkali metal or a fluoride of an alkaline earth metal at 50 wt % or higher can be suitably used. Alternatively, a composite material including an organic compound having a bipyridine skeleton can be suitably used. Thus, the refractive index of the layer 105X can be reduced. The external quantum efficiency of the light-emitting device 550X can be improved.

### Structure Example 3 of Composite Material

For example, a composite material of a first organic compound including an unshared electron pair and a first metal can be used for the layer 105X. The sum of the number of electrons of the first organic compound and the number of electrons of the first metal is preferably an odd number. The molar ratio of the first metal to 1 mol of the first organic compound is preferably greater than or equal to 0.1 and less than or equal to 10, further preferably greater than or equal to 0.2 and less than or equal to 2, still further preferably greater than or equal to 0.2 and less than or equal to 0.8.

Accordingly, the first organic compound including an unshared electron pair interacts with the first metal and thus can form a singly occupied molecular orbital (SOMO). Furthermore, in the case where electrons are injected from the electrode 552X into the layer 105X, a barrier therebetween can be reduced.

The layer 105X can adopt a composite material that allows the spin density measured by an electron spin resonance (ESR) method to be preferably greater than or equal to 1×10¹⁶ spins/cm³, further preferably greater than or equal to 5×10¹⁶ spins/cm³, still further preferably greater than or equal to 1×10¹⁷ spins/cm³.

### [Organic Compound Including Unshared Electron Pair]

For example, an electron-transport material can be used for the organic compound including an unshared electron pair. For example, a compound having an electron deficient heteroaromatic ring can be used. Specifically, a compound with at least one of a pyridine ring, a diazine ring (a pyrimidine ring, a pyrazine ring, and a pyridazine ring), and a triazine ring can be used. Accordingly, the driving voltage of the light-emitting device 550X can be reduced.

Note that the lowest unoccupied molecular orbital (LUMO) level of the organic compound including an unshared electron pair is preferably higher than or equal to −3.6 eV and lower than or equal to −2.3 eV. In general, the HOMO level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), 2,2′-(1,3-phenylene)bis(9-phenyl-1,10-phenanthroline) (abbreviation: mPPhen2P), or the like can be used as the organic compound including an unshared electron pair. Note that NBPhen has a higher glass transition temperature (Tg) than BPhen and thus has high heat resistance.

Alternatively, for example, copper phthalocyanine can be used as the organic compound including an unshared electron pair. The number of electrons of the copper phthalocyanine is an odd number.

### [First Metal]

When the number of electrons of the first organic compound including an unshared electron pair is an even number, for example, a composite material of the first organic compound and the metal that belongs to an odd-numbered group in the periodic table can be used for the layer 105X.

For example, manganese (Mn), which is a metal belonging to Group 7, cobalt 581(Co), which is a metal belonging to Group 9, copper (Cu), silver (Ag), and gold (Au), which are metals belonging to Group 11, aluminum (Al) and indium (In), which are metals belonging to Group 13 are odd-numbered groups in the periodic table. Note that elements belonging to Group 11 have a lower melting point than elements belonging to Group 7 or Group 9 and thus are suitable for vacuum evaporation. In particular, Ag is preferable because of its low melting point. By using a metal having a low reactivity with water or oxygen as the first metal, the moisture resistance of the light-emitting device 550X can be improved.

The use of Ag for the electrode 552X and the layer 105X can increase the adhesion between the layer 105X and the electrode 552X.

When the number of electrons of the first organic compound including an unshared electron pair is an odd number, a composite material of the first organic compound and the first metal that belongs to an even-numbered group in the periodic table can be used for the layer 105X. For example, iron (Fe), which is a metal belonging to Group 8, is an element belonging to an even-numbered group in the periodic table.

### [Electride]

For example, a substance obtained by adding electrons at high concentration to an oxide where calcium and aluminum are mixed can be used, for example, as the electron-injection material.

This embodiment can be combined with any of the other embodiments and example in this specification as appropriate.

### Embodiment 4

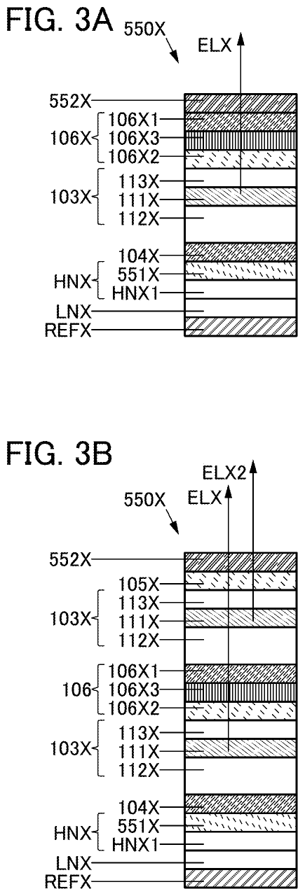

In this embodiment, a structure of a light-emitting device of one embodiment of the present invention which can be used for a display apparatus is described with reference to FIG. 3A.

FIG. 3A is a cross-sectional view illustrating a structure of a light-emitting device of one embodiment of the present invention which can be used for a display apparatus.

### Structure Example of Light-Emitting Device 550X

The light-emitting device 550X described in this embodiment includes the reflective film REFX, the layer LNX, the layer HNX, the layer 104X, the unit 103X, an intermediate layer 106X, and the electrode 552X (see FIG. 3A). The intermediate layer 106X includes a region positioned between the electrode 552X and the unit 103X.

### Structure Example 1 of Intermediate Layer 106X

The intermediate layer 106X has a function of supplying electrons to the anode side and supplying holes to the cathode side when voltage is applied. The intermediate layer 106X can be referred to as a charge-generation layer.

For example, a hole-injection material that can be used for the layer 104X described in Embodiment 2 can be used for the intermediate layer 106X. Specifically, the composite material can be used for the intermediate layer 106X.

Alternatively, for example, a stacked film in which a film including the composite material and a film including a hole-transport material are stacked can be used for the intermediate layer 106X. Note that the film including a hole-transport material is positioned between the film including the composite material and the cathode.

### Structure Example 2 of Intermediate Layer 106X

A stacked film in which a layer 106X1 and a layer 106X2 are stacked can be used for the intermediate layer 106X. The layer 106X1 includes a region positioned between the unit 103X and the electrode 552X and the layer 106X2 includes a region positioned between the unit 103X and the layer 106X1.

### Structure Example of Layer 106X1

For example, a hole-injection material that can be used for the layer 104X described in Embodiment 2 can be used for the layer 106X1. Specifically, the composite material can be used for the layer 106X1. A film having an electrical resistivity greater than or equal to 1×10⁴ Ω·cm and less than or equal to 1×10⁷ Ω·cm can be used as the layer 106X1. The electrical resistivity of the layer 106X1 is preferably greater than or equal to 5×10⁴ Ω·cm and less than or equal to 1×10⁷ Ω·cm, further preferably greater than or equal to 1×10⁵ Ω·cm and less than or equal to 1×10⁷ Ω·cm.

### Structure Example of Layer 106X2

For example, a material that can be used for the layer 105X described in Embodiment 3 can be used for the layer 106X2.

### Structure Example 3 of Intermediate Layer 106X

A stacked film in which the layer 106X1, the layer 106X2, and a layer 106X3 are stacked can be used for the intermediate layer 106X. The layer 106X3 includes a region positioned between the layer 106X1 and the layer 106X2.

### Structure Example of Layer 106X3

For example, an electron-transport material can be used for the layer 106X3. The layer 106X3 can be referred to as an electron-relay layer. With the layer 106X3, a layer that is on the anode side and in contact with the layer 106X3 can be distanced from a layer that is on the cathode side and in contact with the layer 106X3. Interaction between the layer that is on the anode side and in contact with the layer 106X3 and the layer that is on the cathode side and in contact with the layer 106X3 can be reduced. Electrons can be smoothly supplied to the layer that is on the anode side and in contact with the layer 106X3.

A substance whose LUMO level is positioned between the LUMO level of an electron-accepting substance contained in the layer 106X1 and the LUMO level of the substance contained in the layer 106X2 can be suitably used for the layer 106X3.

For example, a material having a LUMO level in a range higher than or equal to −5.0 eV, preferably higher than or equal to −5.0 eV and lower than or equal to −3.0 eV, can be used for the layer 106X3.

Specifically, a phthalocyanine-based material can be used for the layer 106X3. For example, copper phthalocyanine (abbreviation: CuPc) or a metal complex having a metal-oxygen bond and an aromatic ligand can be used for the layer 106X3.

This embodiment can be combined with any of the other embodiments and example in this specification as appropriate.

### Embodiment 5

In this embodiment, a structure of the light-emitting device 550X of one embodiment of the present invention which can be used for a display apparatus is described with reference to FIG. 3B.

FIG. 3B is a cross-sectional view illustrating a structure of a light-emitting device which is different from that in FIG. 3A.

### Structure Example of Light-Emitting Device 550X

The light-emitting device 550X described in this embodiment includes the reflective film REFX, the layer LNX, the layer HNX, the layer 104X, the unit 103X, the intermediate layer 106X, a unit 103X2, the layer 105X, and the electrode 552X (see FIG. 3B). The unit 103X2 includes a region positioned between the layer 105X and the intermediate layer 106X.

The unit 103X2 is positioned between the electrode 552X and the intermediate layer 106X. The unit 103X2 has a function of emitting light ELX2.

In other words, the light-emitting device 550X includes the stacked units between the electrode 551X and the electrode 552X. The number of stacked units is not limited to two and may be three or more. A structure including the stacked units positioned between the electrode 551X and the electrode 552X and the intermediate layer 106X positioned between the units is referred to as a stacked light-emitting device or a tandem light-emitting device in some cases.

This structure enables high luminance emission while the current density is kept low. Reliability can be improved. The driving voltage can be reduced in comparison with that of the light-emitting device with the same luminance. The power consumption can be reduced.

### Structure Example 1 of Unit 103X2

The unit 103X2 includes a layer 111X2, a layer 112X2, and a layer 113X2. The layer 111X2 is positioned between the layer 112X2 and the layer 113X2.

The structure that can be employed for the unit 103X can be employed for the unit 103X2. For example, the same structure as the unit 103X can be employed for the unit 103X2.

### Structure Example 2 of Unit 103X2

The structure that is different from the structure of the unit 103X can be employed for the unit 103X2. For example, the unit 103X2 can have a structure emitting light whose hue is different from that of light emitted from the unit 103X.

Specifically, a stack including the unit 103X emitting red light and green light and the unit 103X2 emitting blue light can be employed. With this structure, a light-emitting device emitting light of a desired color can be provided. A light-emitting device emitting white light can be provided, for example.

### Structure Example of Intermediate Layer 106X

The intermediate layer 106X has a function of supplying electrons to one of the unit 103X and the unit 103X2 and supplying holes to the other. For example, the intermediate layer 106X described in Embodiment 4 can be used.

### <Fabrication Method of Light-Emitting Device 550X>

For example, each of the layer HNX, the electrode 552X, the unit 103X, the intermediate layer 106X, and the unit 103X2 can be formed by a dry process, a wet process, an evaporation method, a droplet discharging method, a coating method, a printing method, or the like. A formation method may differ between components of the device.

Specifically, the light-emitting device 550X can be manufactured with a vacuum evaporation machine, an ink-jet machine, a coating machine such as a spin coater, a gravure printing machine, an offset printing machine, a screen printing machine, or the like.

For example, the electrode can be formed by a wet process or a sol-gel method using a paste of a metal material. In addition, an indium oxide-zinc oxide film can be formed by a sputtering method using a target obtained by adding zinc oxide to indium oxide at a concentration higher than or equal to 1 wt % and lower than or equal to 20 wt %. Furthermore, an indium oxide film containing tungsten oxide and zinc oxide (IWZO) can be formed by a sputtering method using a target containing, with respect to indium oxide, tungsten oxide at a concentration higher than or equal to 0.5 wt % and lower than or equal to 5 wt % and zinc oxide at a concentration higher than or equal to 0.1 wt % and lower than or equal to 1 wt %.

This embodiment can be combined with any of the other embodiments and example in this specification as appropriate.

### Embodiment 6

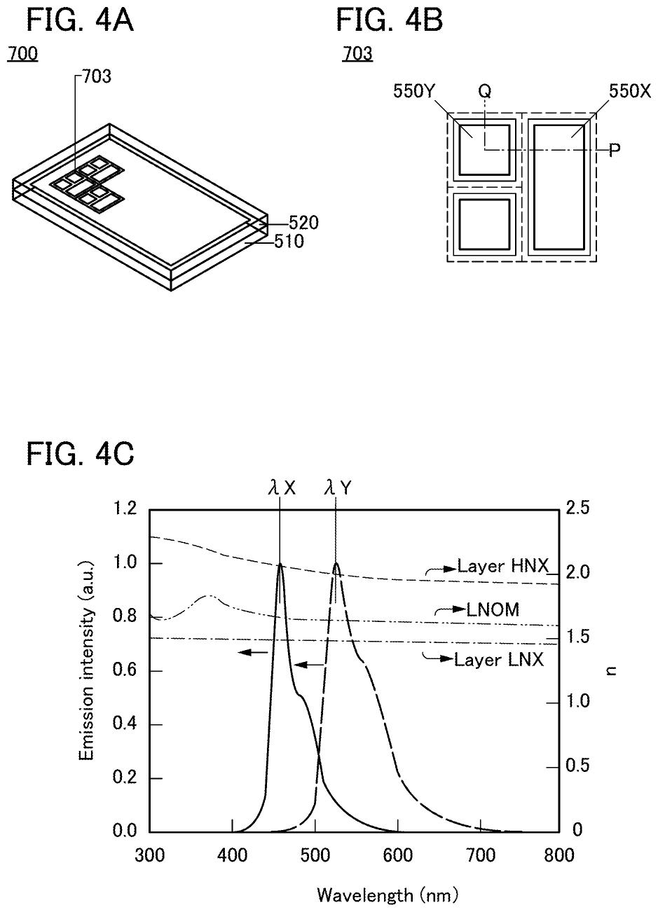

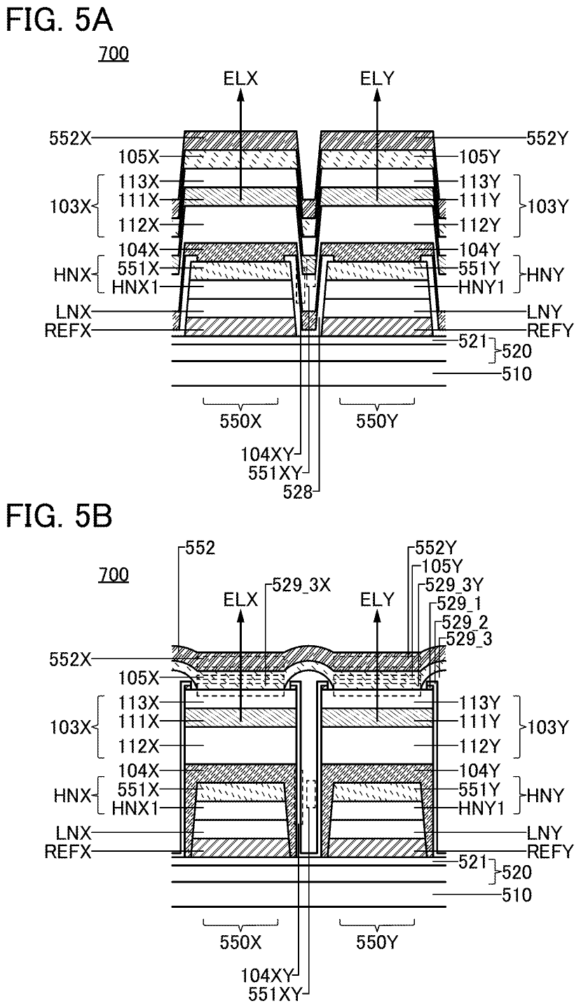

In this embodiment, structures of a display apparatus 700 of one embodiment of the present invention are described with reference to FIGS. 4A to 4C and FIGS. 5A and 5B.

FIG. 4A is a perspective view illustrating the display apparatus 700 of one embodiment of the present invention, and FIG. 4B is a front view illustrating part of the structure in FIG. 4A. FIG. 4C is a graph showing emission spectra and wavelength dependence of the ordinary refractive indices of materials used for the display apparatus 700 of one embodiment of the present invention.

FIG. 5A is a cross-sectional view illustrating a structure of the display apparatus 700 of one embodiment of the present invention taken along a cutting line P-Q in FIG. 4B, and FIG. 5B is a cross-sectional view illustrating a structure of the display apparatus 700 of one embodiment of the present invention, which is different from the structure in FIG. 5A.

### Structure Example 1 of Display Apparatus 700

The display apparatus 700 described in this embodiment includes a pixel set 703 (see FIG. 4A). The pixel set 703 includes the light-emitting device 550X and a light-emitting device 550Y (see FIG. 4B). The light-emitting device 550Y is adjacent to the light-emitting device 550X.

The display apparatus 700 includes a substrate 510 and a functional layer 520 (see FIG. 4A and FIG. 5A). The functional layer 520 includes an insulating film 521, and the light-emitting devices 550X and 550Y are formed over the insulating film 521. The functional layer 520 is positioned between the substrate 510 and the light-emitting device 550X.

### Structure Example of Light-Emitting Device 550X

The light-emitting device 550X includes the reflective film REFX, the layer LNX, the layer HNX, the unit 103X, and the electrode 552X. The layer HNX includes the electrode 551X, and the unit 103X includes the layer 113X, the layer 112X, and the layer 111X. The light-emitting device 550X includes the layer 104X and the layer 105X.

For example, the light-emitting device described in any one of Embodiments 1 to 5 can be used as the light-emitting device 550X.

### Structure Example of Light-Emitting Device 550Y

The light-emitting device 550Y includes a reflective film REFY, a layer LNY, a layer HNY, a unit 103Y, and an electrode 552Y. The layer HNY includes an electrode 551Y, and the unit 103Y includes a layer 113Y, a layer 112Y, and a layer 111Y. The light-emitting device 550Y includes a layer 104Y and a layer 105Y.

Note that the description of the structure of the light-emitting device 550X can be referred to for the light-emitting device 550Y. Specifically, the description of the light-emitting device 550X can be used for the description of the light-emitting device 550Y by replacing “X” in the reference numerals of the components of the light-emitting device 550X with “Y”.

The electrode 552Y overlaps with the reflective film REFY, and has a property of transmitting light with a wavelength λY.

### Structure Example of Layer 111Y

The layer 111Y is positioned between the electrode 552Y and the reflective film REFY, and contains a light-emitting material EMY. The light-emitting material EMY has an emission spectrum having a peak at the wavelength kY (see FIG. 4C). For example, the wavelength kY is longer than the wavelength λX.

### Structure Example of Layer 112Y

The layer 112Y is positioned between the layer 111Y and the reflective film REFY. The layer 112Y contains the organic compound LNOM. The organic compound LNOM contains carbon atoms forming bonds by the sp³ hybrid orbitals in the proportion of higher than or equal to 23% and lower than or equal to 55% to the total number of carbon atoms in a molecule.

### Structure Example of Layer HNY

The layer HNY is positioned between the layer 112Y and the reflective film REFY. The layer HNY has a property of transmitting light with the wavelength λY. The layer HNY includes the electrode 551Y. The electrode 551Y is adjacent to the electrode 551X and a space 551XY is positioned between the electrode 551Y and the electrode 551X.

Note that the material that can be used for the layer HNX can be used for the layer HNY. For example, a material containing an element with an atomic number of 21 to 83 at 5 atomic % or higher can be used for the layer HNY. Specifically, an oxide containing indium, tin, zinc, gallium, or titanium can be used for the layer HNY, for example. Note that the difference in thickness between the layer HNY and the layer HNX can be larger than 0 and smaller than 5 nm. Thus, the layer HNX and the layer HNY can be formed in the same step. In addition, the manufacturing process can be simplified.

### Structure Example of Layer LNY

The layer LNY is positioned between the layer HNY and the reflective film REFY. The layer LNY has a property of transmitting light with the wavelength λY. Note that the material that can be used for the layer LNX can be used for the layer LNY. For example, a material containing an element with an atomic number of 1 to 20 at 95 atomic % or higher can be used for the layer LNY. For example, the layer 112Y can be thicker than the layer 112X. In this manner, the thickness of the layer 112Y can be optimized for the wavelength λY which is longer than the wavelength λX. For example, the difference in thickness between the layer LNY and the layer LNX can be larger than 0 and smaller than 5 nm. Thus, the layer LNX and the layer LNY can be formed in the same step. In addition, the manufacturing process can be simplified.

The reflective film REFY is adjacent to the reflective film REFX and reflects light with the wavelength λY. For example, the material that can be used for the reflective film REFX can be used for the reflective film REFY.

Thus, the layer 112Y has a lower ordinary refractive index than the layer HNY. The layer HNY has a higher ordinary refractive index than the layer LNY. Light emitted from the layer 111Y to the reflective film REFY goes through the region having a low ordinary refractive index and then the region having a high ordinary refractive index. Part of the light can be reflected between the layer 112Y and the layer HNY. The reflected light and light emitted from the layer 111Y to the electrode 552Y can interfere with each other to be intensified. The other part of the light goes through the region having a high ordinary refractive index and then the region having a low ordinary refractive index. Part thereof can be reflected between the layer HNY and the layer LNY. The reflected light and the light emitted from the layer 111Y to the electrode 552Y can interfere with each other to be intensified. The reflected light and the light reflected between the layer 112Y and the layer HNY can interfere with each other to be intensified. The light reflected by the reflective film REFY and the light emitted from the layer 111Y to the electrode 552Y can also interfere with each other to be intensified. Thus, the light emitted from the layer 111Y can be extracted efficiently. As a result, a novel display apparatus that is highly convenient, useful, or reliable can be provided.

Note that part of a structure that can be employed as the structure of the light-emitting device 550X can be employed as the structure of the light-emitting device 550Y. For example, part of a conductive film that can be used for the electrode 552X can be used for the electrode 552Y. A structure that can be employed for the electrode 551X can be employed for the electrode 551Y. A structure that can be used for the layer 104X and a structure that can be used for the layer 105X can be respectively employed for the layer 104Y and the layer 105Y. Thus, common structures can be formed in one step in some cases. In addition, the manufacturing process can be simplified.

Moreover, the light-emitting device 550Y can have a structure emitting light whose hue is the same as that of light emitted from the light-emitting device 550X.

For example, both the light-emitting device 550X and the light-emitting device 550Y may emit white light. A coloring layer is provided to overlap with the light-emitting device 550X, whereby light of a predetermined hue can be extracted from white light. Another coloring layer is provided to overlap with the light-emitting device 550Y, whereby light of another predetermined hue can be extracted from white light.

For example, both the light-emitting device 550X and the light-emitting device 550Y may emit blue light. A color conversion layer is provided to overlap with the light-emitting device 550X, whereby blue light can be converted into light of a predetermined hue. Another coloring layer is provided to overlap with the light-emitting device 550Y, whereby blue light can be converted into light of another predetermined hue. Blue light can be converted into green light or red light, for example.

Moreover, the light-emitting device 550Y can have a structure emitting light whose hue is different from that of light emitted from the light-emitting device 550X. For example, the hue of light ELY emitted from the unit 103Y can be differentiated from that of the light ELX.

### Structure Example 2 of Display Apparatus 700

The display apparatus 700 described in this embodiment includes an insulating film 528 (see FIG. 5A).

### Structure Example of Insulating Film 528

The insulating film 528 has openings; one opening overlaps with the electrode 551X and the other opening overlaps with the electrode 551Y. The insulating film 528 overlaps with the space 551XY.

### Structure Example of Space 551XY

The space 551XY positioned between the electrode 551X and the electrode 551Y has a groove-like shape, for example. Thus, a step is formed along the groove. A deposited film is partly split or thinned between the space 551XY and the electrode 551X.

When an anisotropic deposition method such as a thermal evaporation method is employed, a split or thinned portion is formed along the step in a region 104XY positioned between the layer 104X and the layer 104Y.

Thus, current flowing through the region 104XY can be suppressed, for example. Moreover, current flowing between the layer 104X and the layer 104Y can be suppressed. Furthermore, a phenomenon in which the light-emitting device 550Y that is adjacent to the light-emitting device 550X unintentionally emits light in accordance with the operation of the light-emitting device 550X can be suppressed.

### Structure Example 3 of Display Apparatus 700

The display apparatus 700 described in this embodiment includes the light-emitting device 550X and the light-emitting device 550Y (see FIG. 5B). The light-emitting device 550Y is adjacent to the light-emitting device 550X.

The display apparatus 700 is different from the display apparatus 700 described with reference to FIG. 5A in that part or the whole of the structure of the light-emitting device 550X or the light-emitting device 550Y is removed from a portion overlapping with the space 551XY and a film 529_1, a film 5292, and a film 529_3 are provided instead of the insulating film 528. Different parts will be described in detail below, and the above description is referred to for parts having the same structure as the above.

In this specification and the like, a device formed using a metal mask or a fine metal mask (FMM) may be referred to as a device having a metal mask (MM) structure. In this specification and the like, a device formed without using a metal mask or an FMM is sometimes referred to as a device having a metal maskless (MML) structure.

### Structure Example of Film 529_1

The film 529_1 has openings; one opening overlaps with the electrode 551X and another opening overlaps with the electrode 551Y (see FIG. 5B). The film 529_1 has an opening overlapping with the space 551XY. For example, a film containing a metal, a metal oxide, an organic material, or an inorganic insulating material can be used as the film 529_1. Specifically, a light-blocking metal film can be used. This can block light emitted in the processing process to inhibit the characteristics of the light-emitting device from being degraded by the light.

### Structure Example of Insulating Film 529_2

The insulating film 529_2 has openings; one opening overlaps with the electrode 551X and the other opening overlaps with the electrode 551Y. The film 529_2 overlaps with the space 551XY.

The film 529_2 includes a region in contact with the layer 104X and the unit 103X.

The film 529_2 includes a region in contact with the layer 104Y and the unit 103Y.

The film 5292 includes a region in contact with the insulating film 521. The film 529_2 can be formed by an atomic layer deposition (ALD) method, for example. Thus, a film with favorable coverage can be formed. Specifically, a metal oxide film or the like can be used as the film 529_2. Aluminum oxide can be used, for example.

### Structure Example of Film 529_3

The film 529_3 has openings; an opening 529_3X overlaps with the electrode 551X and an opening 529_3Y overlaps with the electrode 551Y. A groove formed in a region overlapping with the space 551XY is filled with the film 529_3. The film 529_3 can be formed using a photosensitive resin, for example. Specifically, an acrylic resin or the like can be used.

Thus, the layer 104X can be electrically isolated from the layer 104Y, for example. In addition, current flowing through the region 104XY can be suppressed, for example. A phenomenon in which the light-emitting device 550Y that is adjacent to the light-emitting device 550X unintentionally emits light in accordance with the operation of the light-emitting device 550X can be suppressed. A step formed between a top surface of the unit 103X and a top surface of the unit 103Y can be reduced. Occurrence of a phenomenon in which a split or thinned portion due to the step is formed between the electrode 552X and the electrode 552Y can be suppressed. A continuous conductive film can be used for the electrode 552X and the electrode 552Y.

Note that part or the whole of the structure that can be employed for the light-emitting device 550X or the light-emitting device 550Y can be removed from a portion overlapping with the space 551XY by using a photolithography technique, for example.

Specifically, in a first step, a first film to be the unit 103Y later is formed over the space 551XY.

In a second step, a second film to be the film 529_1 later is formed over the first film.

In a third step, an opening overlapping with the space 551XY is formed in the second film by a photolithography method.

In a fourth step, part of the first film is removed using the second film as a resist. For example, the first film is removed from a region overlapping with the space 551XY by a dry etching method. Specifically, the first film can be removed using an oxygen-containing gas. Accordingly, a groove-like structure is formed in the region overlapping with the space 551XY.

In a fifth step, a third film to be the film 529_2 later is formed over the second film by an ALD method, for example.

In a sixth step, the film 529_3 is formed with the use of a photosensitive polymer, for example. Accordingly, the groove-like structure formed in the region overlapping with the space 551XY is filled with the film 529_3.

In a seventh step, an opening overlapping with the electrode 551Y is formed in the second film and the third film by an etching method, whereby the film 529_2 and 30 the film 529_1 are formed.

In an eighth step, the layer 105Y is formed over the unit 103Y and the electrode 552Y is formed over the layer 105Y.

Note that this embodiment can be combined with any of the other embodiments and example in this specification as appropriate.

### Embodiment 7

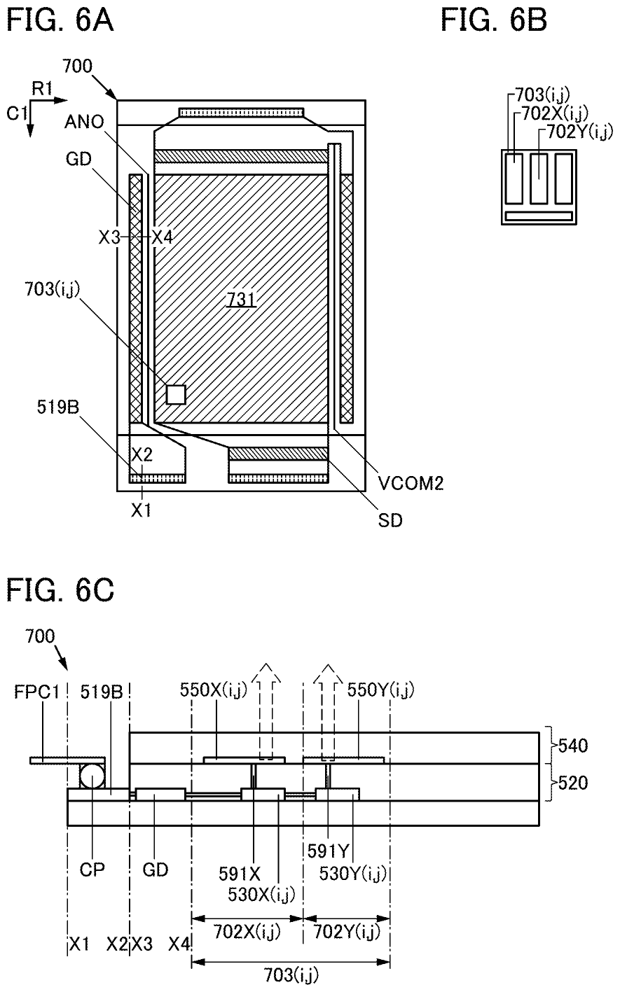

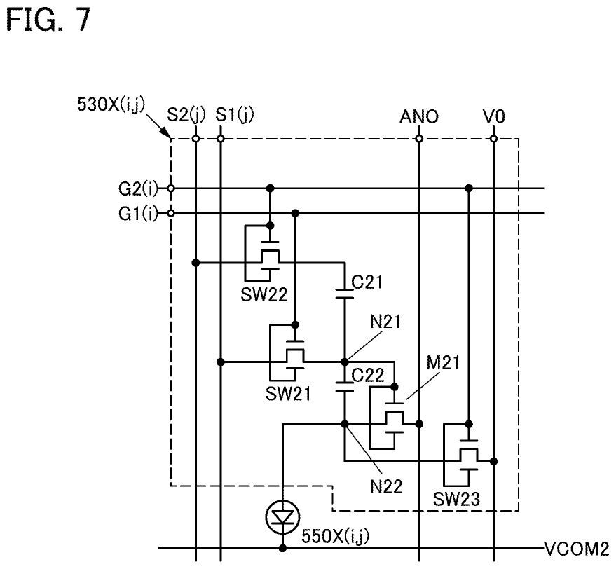

In this embodiment, a structure of a display apparatus of one embodiment of the present invention is described with reference to FIGS. 6A to 6C and FIG. 7.

FIG. 6A is a front view of the display apparatus of one embodiment of the present invention, and FIG. 6B is a front view illustrating part of FIG. 6A. FIG. 6C illustrates cross sections taken along cutting lines X1-X2 and X3-X4 in FIG. 6A and a cross section of a pixel set 703(i,j).

FIG. 7 is a circuit diagram illustrating the structure of the apparatus of one embodiment of the present invention.

In this specification, an integer variable of 1 or more may be used for reference numerals. For example, “(p)” where p is an integer variable of 1 or more may be used for part of a reference numeral that specifies any one of up to p components. For another example, “(m,n)” where each of m and n is an integer variable of 1 or more may be used for part of a reference numeral that specifies any one of up to m×n components.

### Structure Example 1 of Display Apparatus 700

The display apparatus 700 of one embodiment of the present invention includes a region 731 (see FIG. 6A). The region 731 includes the pixel set 703(i,j).

### Structure Example of Pixel Set 703(i,j)

The pixel set 703(i,j) includes a pixel 702X(i,j) and a pixel 702Y(i,j) (see FIGS. 6B and 6C).

The pixel 702X(i,j) includes a pixel circuit 530X(i,j) and the light-emitting device 550X(i,j). The light-emitting device 550X(i,j) is electrically connected to the pixel circuit 530X(i,j).

For example, the light-emitting device described in any one of Embodiments 1 to 5 can be used as the light-emitting device 550X(i,j).

The pixel 702Y(i,j) includes a pixel circuit 530Y(i,j) and the light-emitting device 550Y(i,j). The light-emitting device 550Y(i,j) is electrically connected to the pixel circuit 530Y(i,j). Note that the description of the structure of the light-emitting device 550X can be referred to for the light-emitting device 550Y(i,j). Specifically, the description of the light-emitting device 550X can be used for the description of the light-emitting device 550Y(i,j) by replacing “X” in the reference numerals of the components of the light-emitting device 550X with “Y”.

### Structure Example 2 of Display Apparatus 700

The display apparatus 700 of one embodiment of the present invention includes a functional layer 540 and the functional layer 520 (see FIG. 6C). The functional layer 540 overlaps with the functional layer 520.

The functional layer 540 includes the light-emitting device 550X(i,j).

The functional layer 520 includes the pixel circuit 530X(i,j) and a wiring (see FIG. 6C). The pixel circuit 530X(i,j) is electrically connected to the wiring. For example, a conductive film provided in an opening 591X or an opening 591Y in the functional layer 520 can be used for the wiring. The wiring electrically connects a terminal 519B to the pixel circuit 530X(i,j). Note that a conductive material CP electrically connects the terminal 519B to a flexible printed circuit board FPC1.

### Structure Example 3 of Display Apparatus 700

In addition, the display apparatus 700 of one embodiment of the present invention includes a driver circuit GD and a driver circuit SD (see FIG. 6A).

### Structure Example of Driver Circuit GD

The driver circuit GD supplies a first selection signal and a second selection signal.

### Structure Example of Driver Circuit SD

The driver circuit SD supplies a first control signal and a second control signal.

### Structure Example of Wiring

As the wiring, a conductive film G1(i), a conductive film G2(i), a conductive film S1(j), a conductive film S2(j), a conductive film ANO, a conductive film VCOM2, and a conductive film V0 are included (see FIG. 7).

The conductive film G1(i) is supplied with the first selection signal, and the conductive film G2(i) is supplied with the second selection signal.

The conductive film S1(j) is supplied with the first control signal, and the conductive film S2(j) is supplied with the second control signal.

### Structure Example 1 of Pixel Circuit 530X(i,j)

The pixel circuit 530X(i,j) is electrically connected to the conductive film G1(i) and the conductive film S1(j). The conductive film G1(i) supplies the first selection signal, and the conductive film S1(j) supplies the first control signal.

The pixel circuit 530X(i,j) drives the light-emitting device 550X(i,j) in response to the first selection signal and the first control signal. The light-emitting device 550X(i,j) emits light.

In the light-emitting device 550X(i,j), one of the electrodes is electrically connected to the pixel circuit 530X(i,j) and the other electrode is electrically connected to the conductive film VCOM2.

### Structure Example 2 of Pixel Circuit 530X(i,j)

The pixel circuit 530X(i,j) includes a switch SW21, a switch SW22, a transistor M21, a capacitor C21, and a node N21.

The transistor M21 includes a gate electrode electrically connected to the node N21, a first electrode electrically connected to the light-emitting device 550X(i,j), and a second electrode electrically connected to the conductive film ANO.

The switch SW21 includes a first terminal electrically connected to the node N21, a second terminal electrically connected to the conductive film S1(j), and a gate electrode having a function of controlling an on/off state of the switch SW21 according to the potential of the conductive film G1(i).

The switch SW22 includes a first terminal electrically connected to the conductive film S2(j), and a gate electrode having a function of controlling an on/off state of the switch SW22 according to the potential of the conductive film G2(i).

The capacitor C21 includes a conductive film electrically connected to the node N21 and a conductive film electrically connected to a second electrode of the switch SW22.

Accordingly, an image signal can be stored in the node N21. Alternatively, the potential of the node N21 can be changed using the switch SW22. Alternatively, the intensity of light emitted from the light-emitting device 550X(i,j) can be controlled with the potential of the node N21. As a result, a novel apparatus that is highly convenient, useful, or reliable can be provided.

### Structure Example 3 of Pixel Circuit 530X(i,j)

The pixel circuit 530X(i,j) includes a switch SW23, a node N22, and a capacitor C22.

The switch SW23 includes a first terminal electrically connected to the conductive film V0, a second terminal electrically connected to the node N22, and a gate electrode having a function of controlling an on/off state of the switch SW23 according to the potential of the conductive film G2(i).

The capacitor C22 includes a conductive film electrically connected to the node N21 and a conductive film electrically connected to the node N22.

The first electrode of the transistor M21 is electrically connected to the node N22.

This embodiment can be combined with any of the other embodiments and example in this specification as appropriate.

### Embodiment 8

In this embodiment, a display module of one embodiment of the present invention is described.

### <Display Module>

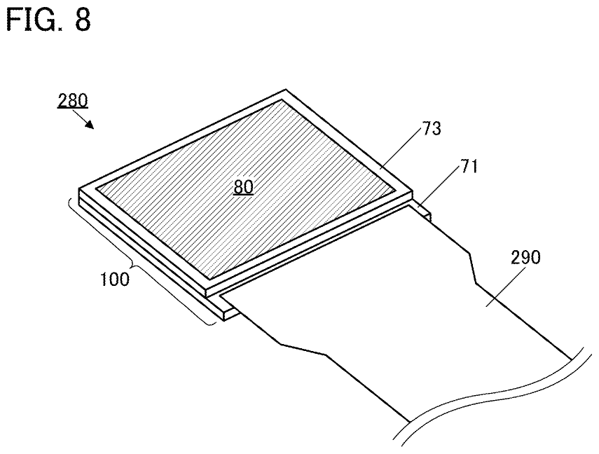

FIG. 8 is a perspective view illustrating a structure of a display module 280.

The display module 280 includes a display apparatus 100, and an FPC 290 or a connector. The FPC 290 is supplied with a data signal, a power supply potential, or the like from the outside and supplies the data signal, the power supply potential, or the like to the display apparatus 100. An IC may be mounted on the FPC 290. Note that a connector is a mechanical component for electrical connection through a conductor, and the conductor can electrically connect the display apparatus 100 to a component to be connected. For example, the FPC 290 can be used as the conductor. The connector can detach the display apparatus 100 from the connected component.

### <<Display Apparatus 100A>>

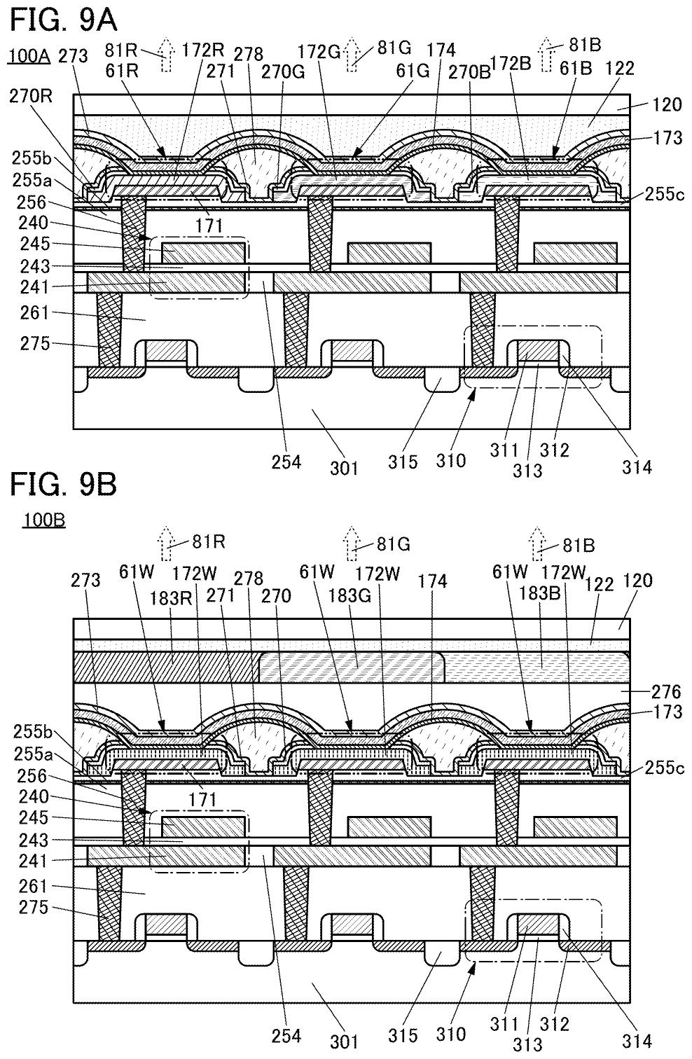

FIG. 9A is a cross-sectional view illustrating a structure of a display apparatus 100A. The display apparatus 100A can be used as the display apparatus 100 of the display module 280, for example. A substrate 301 corresponds to a substrate 71 in FIG. 8.

The display apparatus 100A includes the substrate 301, a transistor 310, an element isolation layer 315, an insulating layer 261, a capacitor 240, an insulating layer 255, a light-emitting device 61R, a light-emitting device 61G, and a light-emitting device 61B. The insulating layer 261 is provided over the substrate 301, and the transistor 310 is positioned between the substrate 301 and the insulating layer 261. An insulating layer 255a is provided over the insulating layer 261, the capacitor 240 is positioned between the insulating layer 261 and the insulating layer 255a, and the insulating layer 255a is positioned between the capacitors 240 and the light-emitting devices 61R, 61G, 61B.

### [Transistor 310]

The transistor 310 includes a conductive layer 311, a pair of low-resistance regions 312, an insulating layer 313, and an insulating layer 314, and its channel is formed in part of the substrate 301. The conductive layer 311 functions as a gate electrode. The insulating layer 313 is positioned between the substrate 301 and the conductive layer 311 and functions as a gate insulating layer. The substrate 301 includes the pair of low-resistance regions 312 doped with an impurity. Note that the low-resistance regions functions as a source and a drain. The side surface of the conductive layer 311 is covered with the insulating layer 314.

The element isolation layer 315 is embedded in the substrate 301, and positioned between two adjacent transistors 310.

### [Capacitor 240]

The capacitor 240 includes a conductive layer 241, a conductive layer 245, and an insulating layer 243, and the insulating layer 243 is positioned between the conductive layer 241 and the conductive layer 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is positioned over the insulating layer 261 and is embedded in an insulating layer 254. The conductive layer 241 is electrically connected to one of the source and the drain of the transistor 310 through a plug 275 embedded in the insulating layer 261. The insulating layer 243 covers the conductive layer 241. The conductive layer 245 overlaps with the conductive layer 241 with the insulating layer 243 therebetween.

### [Insulating Layer 255]

The insulating layer 255 includes the insulating layer 255a, an insulating layer 255b, and an insulating layer 255c, and the insulating layer 255b is positioned between the insulating layer 255a and the insulating layer 255c.

### [Light-Emitting Device 61R, Light-Emitting Device 61G, and Light-Emitting Device 61B]

The light-emitting devices 61R, 61G, and 61B are provided over the insulating layer 255c. For example, the light-emitting device described in any of Embodiments 1 to 6 can be used as any of the light-emitting devices 61R, 61G, and 61B.

The light-emitting device 61R includes a conductive layer 171 and an EL layer 172R, and the EL layer 172R covers the top and side surfaces of the conductive layer 171. A sacrificial layer 270R is positioned over the EL layer 172R. The light-emitting device 61G includes the conductive layer 171 and an EL layer 172G, and the EL layer 172G covers the top and side surfaces of the conductive layer 171. A sacrificial layer 270G is positioned over the EL layer 172G. The light-emitting device 61B includes the conductive layer 171 and an EL layer 172B, and the EL layer 172B covers the top and side surfaces of the conductive layer 171. A sacrificial layer 270B is positioned over the EL layer 172B.

The conductive layer 171 is electrically connected to one of the source and the drain of the transistor 310 through a plug 256 embedded in the insulating layers 243, 255a, 255b, and 255c, the conductive layer 241 embedded in the insulating layer 254, and the plug 275 embedded in the insulating layer 261. The top surface of the insulating layer 255c and the top surface of the plug 256 are level with or substantially level with each other. Any of a variety of conductive materials can be used for the plugs.

### [Protective Layer 271, Insulating Layer 278, Protective Layer 273, and Bonding Layer 122]

A protective layer 271 and an insulating layer 278 are positioned between adjacent light-emitting devices, e.g., between the light-emitting device 61R and the light-emitting device 61G, and the insulating layer 278 is provided over the protective layer 271. A protective layer 273 is provided over the light-emitting devices 61R, 61G, and 61B.

A bonding layer 122 attaches the protective layer 273 to a substrate 120.

### [Substrate 120]

The substrate 120 corresponds to a substrate 73 in FIG. 8. A light-blocking layer can be provided for the surface of the substrate 120 on the bonding layer 122 side, for example. A variety of optical members can be provided on the outer side of the substrate 120.

A film can be used as the substrate. In particular, a film with a low water absorption rate can be suitably used. For example, the water absorption rate is preferably 1% or lower, further preferably 0.1% or lower. Thus, a change in size of the film can be inhibited. Furthermore, generation of wrinkles or the like can be inhibited. Moreover, a change in shape of the display apparatus can be inhibited.

For example, a polarizing plate, a retardation plate, a light diffusion layer (e.g., a diffusion film), an anti-reflection layer, a light-condensing film, or the like can be used as the optical member.

It is possible that a highly optically isotropic material, in other words, a material with a low birefringence index is used for the substrate and a circular polarizing plate is provided to overlap with the display apparatus. For example, it is possible to use, for the substrate, a material that has an absolute value of a retardation (phase difference) of 30 nm or less, preferably 20 nm or less, further preferably 10 nm or less. For example, a triacetyl cellulose (TAC, also referred to as cellulose triacetate) film, a cycloolefin polymer (COP) film, a cycloolefin copolymer (COC) film, or an acrylic resin film can be used as a highly optically isotropic film.

Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 120. For example, a glass layer, a silica layer (SiOₓ layer), diamond like carbon (DLC), aluminum oxide (AlOₓ), a polyester-based material, a polycarbonate-based material, or the like can be used for the surface protective layer. Note that a material having a high visible light transmittance can be suitably used for the surface protective layer. In addition, a material having high hardness can be suitably used for the surface protective layer.

### Display Apparatus 100B>>

FIG. 9B is a cross-sectional view illustrating a structure of a display apparatus 100B. For example, the display apparatus 100B can be used as the display apparatus 100 of the display module 280 (see FIG. 8).

The display apparatus 100B includes the substrate 301, a light-emitting device 61W, the capacitor 240, and the transistor 310. The light-emitting device 61W can emit white light, for example.

The display apparatus 100B includes a coloring layer 183R, a coloring layer 183G, and a coloring layer 183B. The coloring layer 183R includes a region overlapping with one light-emitting device 61W, the coloring layer 183G includes a region overlapping with another light-emitting device 61W, and the coloring layer 183B includes a region overlapping with another light-emitting device 61W.

For example, the coloring layer 183R, the coloring layer 183G, and the coloring layer 183B can transmit red light, green light, and blue light, respectively.

### <Display Apparatus 100C>>

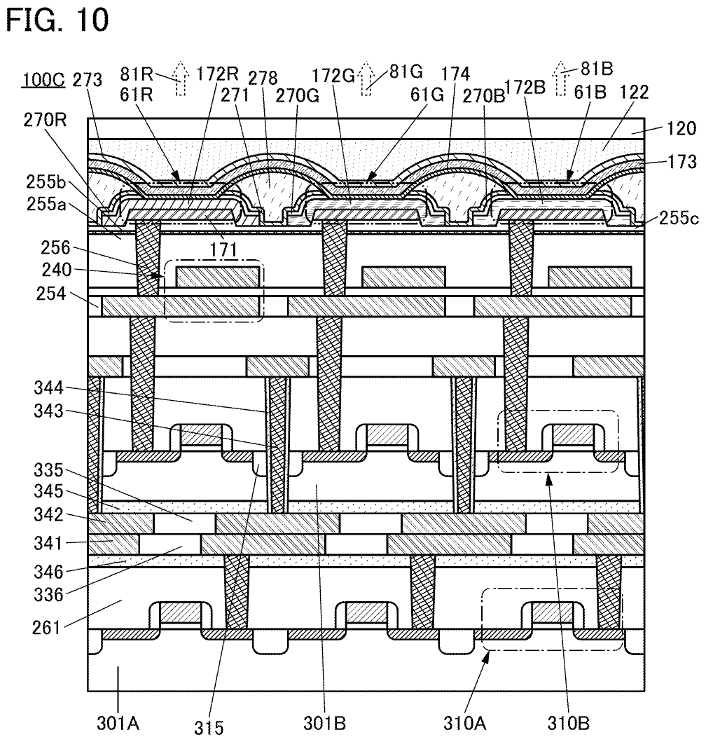

FIG. 10 is a cross-sectional view illustrating a structure of a display apparatus 100C. The display apparatus 100C can be used as the display apparatus 100 of the display module 280, for example (see FIG. 8). Note that in the following description of display apparatuses, the description of portions similar to those of the above-described display apparatuses may be omitted.

The display apparatus 100C includes a substrate 301B and a substrate 301A. The display apparatus 100C includes a transistor 310B, the capacitor 240, the light-emitting device 61, and a transistor 310A. A channel of the transistor 310A is formed in part of the substrate 301A and a channel of the transistor 310B is formed in part of the substrate 301B.

### [Insulating Layer 345 and Insulating Layer 346]

An insulating layer 345 is in contact with the bottom surface of the substrate 301B, and an insulating layer 346 is positioned over the insulating layer 261. For example, the inorganic insulating film that can be used as the protective layer 273 can be used as the insulating layers 345 and 346. The insulating layers 345 and 346 function as protective layers and can inhibit impurities from being diffused into the substrates 301B and 301A.

### [Plug 343]

A plug 343 penetrates the substrate 301B and the insulating layer 345. An insulating layer 344 covers the side surface of the plug 343. For example, the inorganic insulating film that can be used as the protective layer 273 can be used as the insulating layer 344. The insulating layer 344 functions as a protective layer and can inhibit impurities from being diffused into the substrate 301B.

### [Conductive Layer 342]

A conductive layer 342 is positioned between the insulating layer 345 and the insulating layer 346. The conductive layer 342 is embedded in an insulating layer 335, and a plane formed by the conductive layer 342 and the insulating layer 335 is preferably flat. Note that the conductive layer 342 is electrically connected to the plug 343.

### [Conductive Layer 341]

A conductive layer 341 is positioned between the insulating layer 346 and the insulating layer 335. It is preferable that the conductive layer 341 be embedded in an insulating layer 336 and a plane formed by the conductive layer 341 and the insulating layer 336 be flat. The conductive layer 341 is bonded to the conductive layer 342. Thus, the substrate 301A is electrically connected to the substrate 301B.

The conductive layers 341 and 342 are preferably formed using the same conductive material. For example, it is possible to use a metal film containing an element selected from Al, Cr, Cu, Ta, Ti, Mo, and W, or a metal nitride film containing any of the above elements as a component (e.g., a titanium nitride film, a molybdenum nitride film, or a tungsten nitride film). Copper is particularly preferably used for the conductive layers 341 and 342. In that case, it is possible to employ copper-to-copper (Cu-to-Cu) direct bonding (a technique for achieving electrical continuity by connecting copper (Cu) pads).

### <<Display Apparatus 100D>>

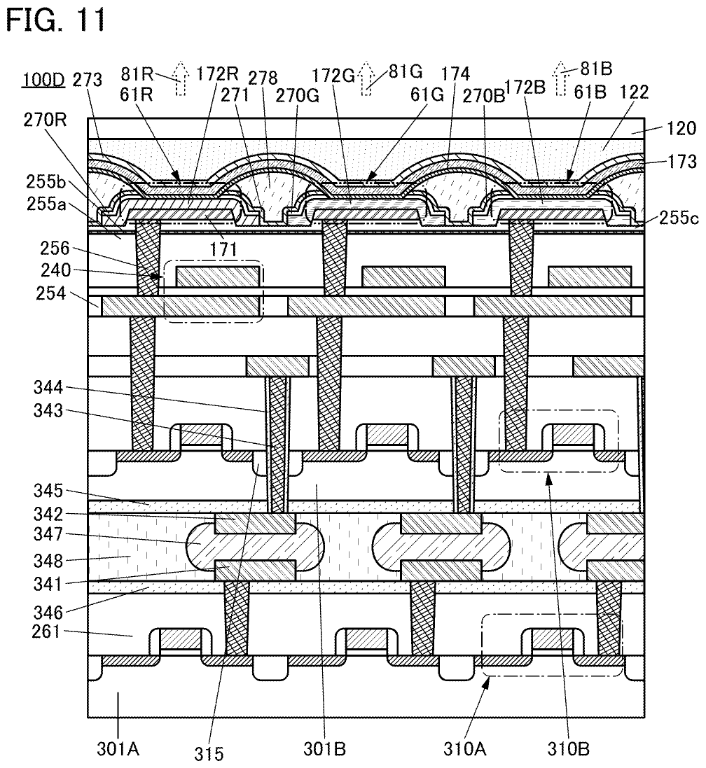

FIG. 11 is a cross-sectional view illustrating a structure of a display apparatus 100D. The display apparatus 100D can be used as the display apparatus 100 of the display module 280, for example (see FIG. 8).

The display apparatus 100D includes a bump 347, and the bump 347 bonds the conductive layer 341 to the conductive layer 342. The bump 347 electrically connects the conductive layer 341 to the conductive layer 342. The bump 347 can be formed using a conductive material containing gold (Au), nickel (Ni), indium (In), tin (Sn), or the like, for example. Solder can be used for the bump 347, for example.

The display apparatus 100D includes a bonding layer 348. The bonding layer 348 attaches the insulating layer 345 to the insulating layer 346.

### <<Display Apparatus 100E>>

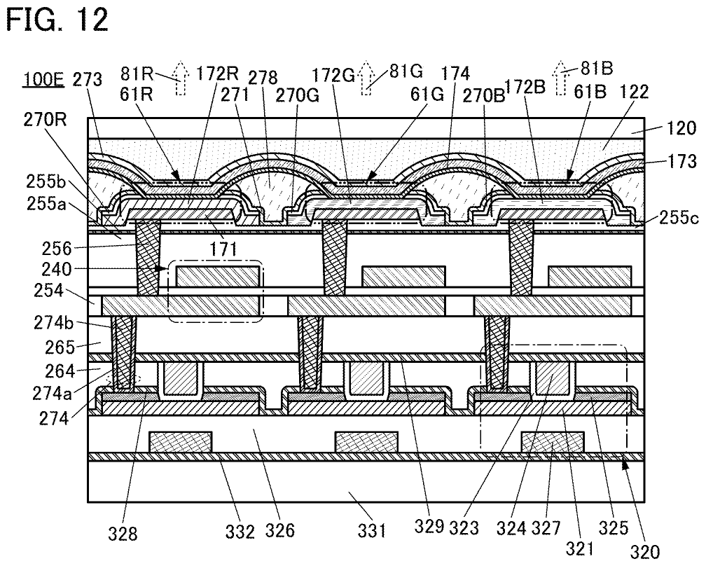

FIG. 12 is a cross-sectional view illustrating a structure of a display apparatus 100E. The display apparatus 100E can be used as the display apparatus 100 of the display module 280, for example (see FIG. 8). A substrate 331 corresponds to the substrate 71 in FIG. 8. An insulating substrate or a semiconductor substrate can be used as the substrate 331. The display apparatus 100E includes a transistor 320. Note that the display apparatus 100E is different from the display apparatus 100A in that the transistor is an OS transistor.

### [Insulating Layer 332]

An insulating layer 332 is provided over the substrate 331. For example, a film in which hydrogen or oxygen is less likely to be diffused than in a silicon oxide film can be used as the insulating layer 332. Specifically, an aluminum oxide film, a hafnium oxide film, a silicon nitride film, or the like can be used as the insulating layer 332. Thus, the insulating layer 332 can prevent impurities such as water and hydrogen from being diffused from the substrate 331 into the transistor 320. Furthermore, oxygen can be prevented from being released from a semiconductor layer 321 to the insulating layer 332 side.

### [Transistor 320]

The transistor 320 includes the semiconductor layer 321, an insulating layer 323, a conductive layer 324, a pair of conductive layers 325, an insulating layer 326, and a conductive layer 327.

The conductive layer 327 is provided over the insulating layer 332 and functions as a first gate electrode of the transistor 320. The insulating layer 326 covers the conductive layer 327. Part of the insulating layer 326 functions as a first gate insulating layer. The insulating layer 326 includes an oxide insulating film at least in a region in contact with the semiconductor layer 321. Specifically, a silicon oxide film or the like is preferably used. The insulating layer 326 has a flat top surface. The semiconductor layer 321 is provided over the insulating layer 326. A metal oxide film having semiconductor characteristics can be used as the semiconductor layer 321. The pair of conductive layers 325 is provided on and in contact with the semiconductor layer 321, and functions as a source electrode and a drain electrode.

### [Insulating Layer 328 and Insulating Layer 264]

An insulating layer 328 covers the top and side surfaces of the pair of conductive layers 325, the side surface of the semiconductor layer 321, and the like. An insulating layer 264 is provided over the insulating layer 328 and functions as an interlayer insulating layer. The insulating layers 328 and 264 have an opening reaching the semiconductor layer 321. For example, an insulating film similar to the insulating layer 332 can be used as the insulating layer 328. Thus, the insulating layer 328 can prevent impurities such as water and hydrogen from being diffused from the insulating layer 264 into the semiconductor layer 321. Furthermore, oxygen can be prevented from being released from the semiconductor layer 321.

### [Insulating Layer 323]

The insulating layer 323 is in contact with the side surfaces of the insulating layers 264 and 328 and the conductive layer 325 and the top surface of the semiconductor layer 321 inside the opening.

### [Conductive Layer 324]

Inside the opening, the conductive layer 324 is embedded and in contact with the insulating layer 323. The conductive layer 324 has a top surface subjected to planarization treatment, and is level with or substantially level with the top surface of the insulating layer 323 and the top surface of the insulating layer 264. The conductive layer 324 functions as a second gate electrode, and the insulating layer 323 functions as a second gate insulating layer.

### [Insulating Layer 329 and Insulating Layer 265]

An insulating layer 329 covers the conductive layer 324 and the insulating layers 323 and 264. An insulating layer 265 is provided over the insulating layer 329 and functions as an interlayer insulating layer. For example, an insulating film similar to the insulating layers 328 and 332 can be used as the insulating layer 329. Thus, impurities such as water and hydrogen can be prevented from being diffused from the insulating layer 265 into the transistor 320, for example.

### [Plug 274]

A plug 274 is embedded in the insulating layers 265, 329, 264, and 328 and is electrically connected to one of the pair of conductive layers 325. The plug 274 includes a conductive layer 274a and a conductive layer 274b. The conductive layer 274a is in contact with each of the side surfaces of openings in the insulating layers 265, 329, 264, and 328. In addition, the conductive layer 274a covers part of the top surface of the conductive layer 325. The conductive layer 274b is in contact with the top surface of the conductive layer 274a. For example, a conductive material in which hydrogen and oxygen are less likely to be diffused can be suitably used for the conductive layer 274a.

<<Display Apparatus 100f>>

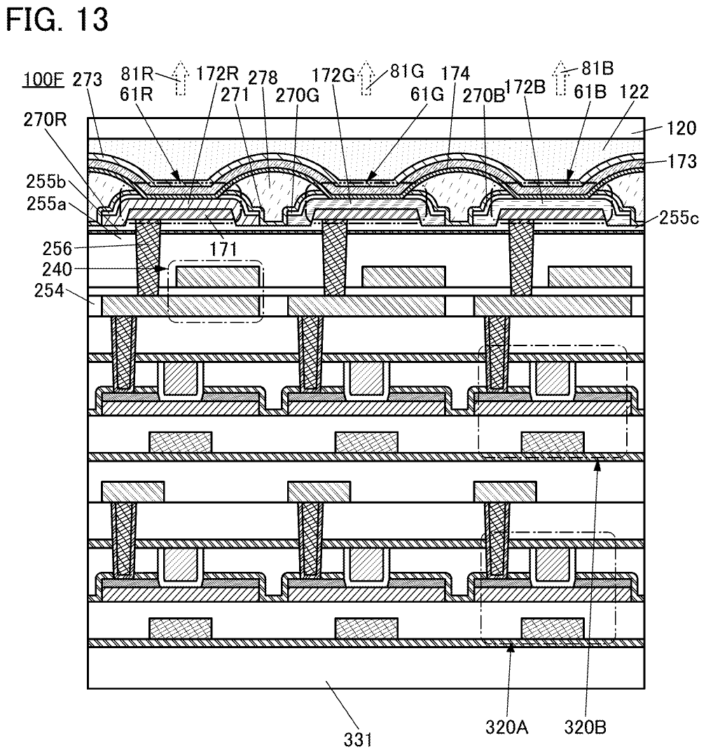

FIG. 13 is a cross-sectional view illustrating a structure of a display apparatus 100F. The display apparatus 100F has a structure in which a transistor 320A and a transistor 320B are stacked. Each of the transistors 320A and 320B includes an oxide semiconductor and a channel formed in the oxide semiconductor. Note that the structure of the display apparatus 100F is not limited to the stacked structure of two transistors, and may be a structure in which three or more transistors are stacked, for example.

The structures of the transistor 320A and the peripheral components are the same as those of the transistor 320 and the peripheral components of the display apparatus 100E. The structures of the transistor 320B and the peripheral components are the same as those of the transistor 320 and the peripheral components of the display apparatus 100E.

### <<Display Apparatus 100G>>

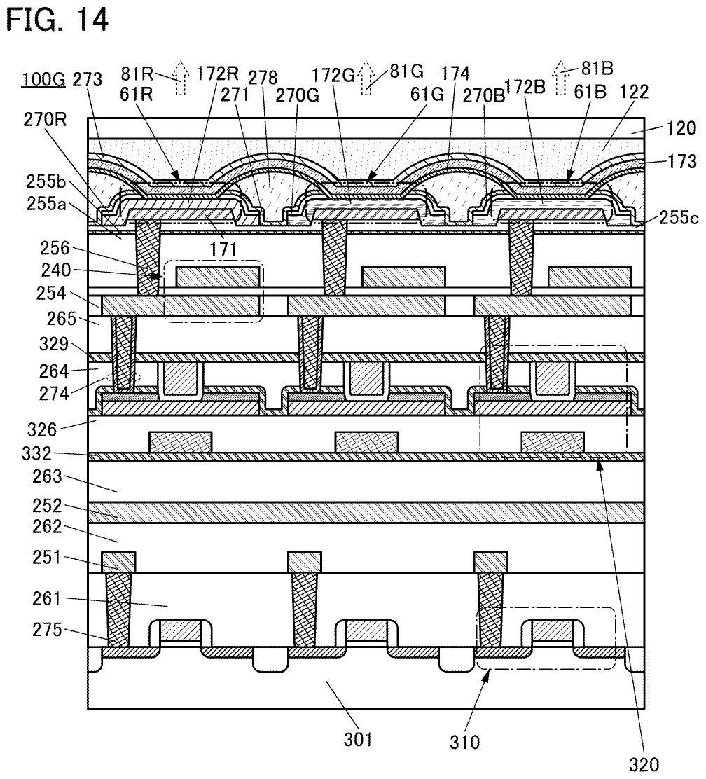

FIG. 14 is a cross-sectional view illustrating a structure of a display apparatus 100G. The display apparatus 100G has a structure in which the transistor 310 and the transistor 320 are stacked. The channel of the transistor 310 is formed in the substrate 301. The transistor 320 includes an oxide semiconductor and the channel formed in the oxide semiconductor.

The insulating layer 261 covers the transistor 310 and a conductive layer 251 is provided over the insulating layer 261. An insulating layer 262 covers the conductive layer 251 and a conductive layer 252 is provided over the insulating layer 262. An insulating layer 263 and the insulating layer 332 covers the conductive layer 252. The conductive layer 251 and the conductive layer 252 each function as a wiring.

The transistor 320 is provided over the insulating layer 332 and the insulating layer 265 covers the transistor 320. The capacitor 240 is provided over the insulating layer 265 and is electrically connected to the transistor 320 through the plug 274.

For example, the transistor 320 can be used as a transistor included in a pixel circuit. For another example, the transistor 310 can be used as a transistor included in a pixel circuit or for a driver circuit (e.g., a gate driver circuit or a source driver circuit) for driving the pixel circuit. The transistor 310 and the transistor 320 can be used for a variety of circuits such as an arithmetic circuit and a memory circuit. Thus, not only a pixel circuit but also a driver circuit can be provided directly under the light-emitting device, for example. The display apparatus can be downsized as compared to the case where a driver circuit is provided around a display region.

At least part of this embodiment can be implemented in combination with any of the other embodiments and example described in this specification, as appropriate.

### Embodiment 9

In this embodiment, a display apparatus of one embodiment of the present invention will be described.

### <Display Module>

FIG. 15 is a perspective view illustrating a structure of a display module.

The display module includes a display apparatus, an integrated circuit (IC), and one of an FPC and a connector. A display apparatus 100H is electrically connected to an IC 176 and an FPC 177. The FPC 177 is supplied with a signal and electric power from the outside and supplies the signal and the electric power to the display apparatus 100H. Note that a connector is a mechanical component for electrical connection through a conductor, and the conductor can electrically connect the display apparatus 100H to a component to be connected. For example, the FPC 177 can be used as the conductor. The connector can detach the display apparatus 100H from the connected component.

The display module includes the IC 176. For example, the IC 176 can be provided for a substrate 14b by a chip on glass (COG) method. Alternatively, the IC 176 can be provided for an FPC by a chip on film (COF) method, for example. Note that a gate driver circuit, a source driver circuit, or the like can be used as the IC 176.

### <<Display Apparatus 100H>>

The display apparatus 100H includes a display portion 37b, a connection portion 140, a circuit 164, a wiring 165, and the like.

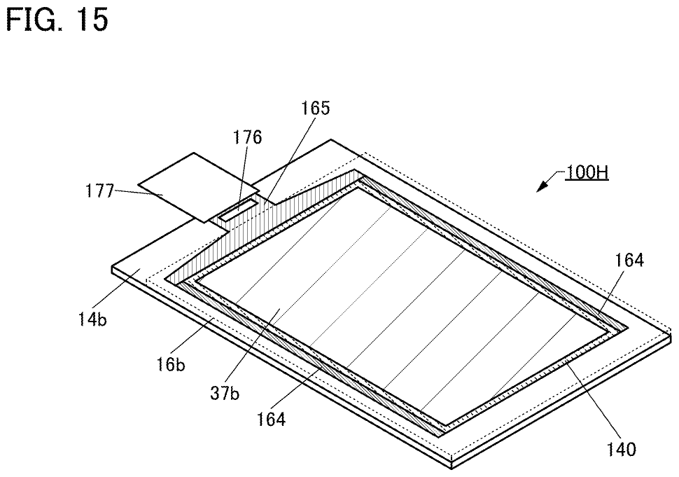

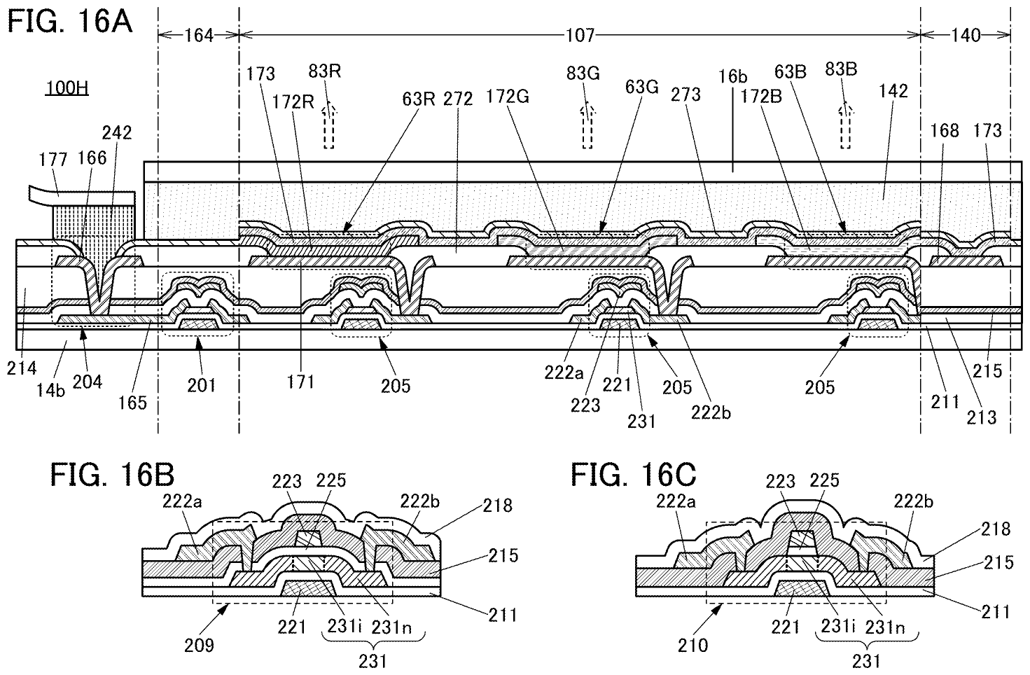

FIG. 16A is a cross-sectional view illustrating a structure of the display apparatus 100H. The display apparatus 100H includes a substrate 16b and the substrate 14b, which are bonded to each other. The display apparatus 100H includes one or more connection portions 140. The connection portion(s) can be provided outside the display portion 37b. For example, the connection portion can be provided along one side of the display portion 37b. Alternatively, the connection portion(s) can be provided along a plurality of sides, for example, the connection portion(s) can be provided to surround four sides. In the connection portion 140, a common electrode of a light-emitting device is electrically connected to a conductive layer, which supplies a predetermined potential to the common electrode.

The wiring 165 is supplied with a signal or electric power from the FPC 177 or the IC 176. The wiring 165 supplies a signal and electric power to the display portion 37b and the circuit 164.

For example, a gate driver circuit can be used as the circuit 164.

The display apparatus 100H includes the substrate 14b, the substrate 16b, a transistor 201, a transistor 205, a light-emitting device 63R, a light-emitting device 63G, a light-emitting device 63B, and the like (see FIG. 16A). For example, the light-emitting device 63R emits red light 83R, the light-emitting device 63G emits green light 83G, and the light-emitting device 63B emits blue light 83B. Note that a variety of optical members can be provided on the outer side of the substrate 16b. For example, a polarizing plate, a retardation plate, a light diffusion layer (e.g., a diffusion film), an anti-reflection layer, a light-condensing film, or the like can be provided.

For example, the light-emitting device described in any of Embodiments 1 to 6 can be used for each of the light-emitting devices 63R, 63G, and 63B.

The light-emitting device 63 includes the conductive layer 171, which functions as a pixel electrode. The conductive layer 171 includes a depression portion, which overlaps with an opening provided in an insulating layer 214, an insulating layer 215, and an insulating layer 213. The transistor 205 includes a conductive layer 222b, which is electrically connected to the conductive layer 171.

The display apparatus 100H includes an insulating layer 272. The insulating layer 272 covers an end portion of the conductive layer 171 to fill the depression portion of the conductive layer 171 (see FIG. 16A).

The display apparatus 100H includes the protective layer 273 and a bonding layer 142. The protective layer 273 covers the light-emitting devices 63R, 63G, and 63B. The protective layer 273 and the substrate 16b are attached to each other with the bonding layer 142. The bonding layer 142 fills a space between the substrate 16b and the protective layer 273. Note that the bonding layer 142 may be formed in a frame shape so as not to overlap with the light-emitting devices and a region surrounded by the bonding layer 142, the substrate 16b, and the protective layer 273 may be filled with a resin different from the material of the bonding layer 142. Alternatively, a hollow sealing structure may be employed, in which the region is filled with an inert gas (e.g., nitrogen or argon). For example, the material that can be used for the bonding layer 122 can be used for the bonding layer 142.

The display apparatus 100H includes the connection portion 140, which includes a conductive layer 168. Note that a power supply potential is supplied to the conductive layer 168. The light-emitting device 63 includes a conductive layer 173. The conductive layer 168 is electrically connected to the conductive layer 173, to which a power supply potential is supplied. Note that the conductive layer 173 functions as a common electrode. For example, the conductive layer 171 and the conductive layer 168 can be formed by processing one conductive film.

The display apparatus 100H has a top-emission structure. The light-emitting device emits light to the substrate 16b side. The conductive layer 171 contains a material reflecting visible light, and the conductive layer 173 transmits visible light.

### [Insulating Layer 211, Insulating Layer 213, Insulating Layer 215, and Insulating Layer 214]

An insulating layer 211, the insulating layer 213, the insulating layer 215, and the insulating layer 214 are provided in this order over the substrate 14b. Note that the number of insulating layers is not limited and each insulating layer may be a single layer or a stacked layer of two or more layers.

For example, an inorganic insulating film can be used as each of the insulating layers 211, 213, and 215. A silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

The insulating layers 215 and 214 cover the transistors. The insulating layer 214 functions as a planarization layer. For example, a material in which impurities such as water and hydrogen are less likely to be diffused is preferably used for the insulating layer 215 or the insulating layer 214. This can effectively inhibit impurities from being diffused to the transistors from the outside. Furthermore, the reliability of the display apparatus can be improved.

For example, an organic insulating layer can be favorably used as the insulating layer 214. Specifically, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used for the organic insulating layer. Alternatively, the insulating layer 214 can have a stacked layer structure of an organic insulating layer and an inorganic insulating layer. Thus, the outermost layer of the insulating layer 214 can be used as an etching protective layer. For example, in the case where a phenomenon of forming a depression portion in the insulating layer 214 should be avoided in processing the conductive layer 171 in a predetermined shape, the phenomenon can be inhibited.

### [Transistor 201 and Transistor 205]

The transistor 201 and the transistor 205 are formed over the substrate 14b. These transistors can be fabricated using the same materials in the same steps.

Each of the transistors 201 and 205 includes a conductive layer 221, the insulating layer 211, a conductive layer 222a, the conductive layer 222b, a semiconductor layer 231, the insulating layer 213, and a conductive layer 223. The insulating layer 211 is positioned between the conductive layer 221 and the semiconductor layer 231. The conductive layer 221 functions as a gate and the insulating layer 211 functions as a first gate insulating layer. The conductive layer 222a and the conductive layer 222b function as a source and a drain. The insulating layer 213 is positioned between the conductive layer 223 and the semiconductor layer 231. The conductive layer 223 functions as a gate and the insulating layer 213 functions as a second gate insulating layer. Here, a plurality of layers obtained by processing the same conductive film are shown with the same hatching pattern.

There is no particular limitation on the structure of the transistors included in the display apparatus of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

The structure in which the semiconductor layer where a channel is formed is provided between two gates is used for the transistors 201 and 205. The two gates may be connected to each other and supplied with the same signal to operate the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor layer of the transistors, and an amorphous semiconductor or a semiconductor having crystallinity (a microcrystalline semiconductor, a polycrystalline semiconductor, a single crystal semiconductor, or a semiconductor partly including crystal regions) may be used. It is preferable to use a semiconductor having crystallinity, in which case deterioration of the transistor characteristics can be suppressed.

The semiconductor layer of the transistor preferably contains a metal oxide. That is, an OS transistor is preferably used as the transistor included in the display apparatus of this embodiment.

### [Semiconductor Layer]

For example, indium oxide, gallium oxide, and zinc oxide can be used for the semiconductor layer. The metal oxide preferably contains two or three kinds selected from indium, an element M, and zinc. The element M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. Specifically, the element M is preferably one or more of aluminum, gallium, yttrium, and tin.

It is particularly preferable that an oxide containing indium (In), gallium (Ga), and zinc (Zn) (also referred to as IGZO) be used as the metal oxide used for the semiconductor layer. Alternatively, it is preferable to use an oxide containing indium, tin, and zinc (also referred to as ITZO (registered trademark)). It is preferable to use an oxide containing indium, gallium, tin, and zinc. It is preferable to use an oxide containing indium (In), aluminum (Al), and zinc (Zn) (also referred to as IAZO). It is preferable to use an oxide containing indium (In), aluminum (Al), gallium (Ga), and zinc (Zn) (also referred to as IAGZO).

When the metal oxide used for the semiconductor layer is an In-M-Zn oxide, the atomic ratio of In is preferably greater than or equal to the atomic ratio of M in the In-M-Zn oxide. Examples of the atomic ratio of the metal elements in such an In-M-Zn oxide are In:M:Zn=1:1:1, 1:1:1.2, 1:3:2, 1:3:4, 2:1:3, 3:1:2, 4:2:3, 4:2:4.1, 5:1:3, 5:1:6, 5:1:7, 5:1:8, 6:1:6, and 5:2:5 and a composition in the vicinity of any of the above atomic ratios. Note that the vicinity of the atomic ratio includes ±30% of an intended atomic ratio.

For example, when the atomic ratio is described as In:Ga:Zn=4:2:3 or a composition in the vicinity thereof, the case is included where the atomic ratio of Ga is greater than or equal to 1 and less than or equal to 3 and the atomic ratio of Zn is greater than or equal to 2 and less than or equal to 4 with the atomic ratio of In being 4. In addition, when the atomic ratio is described as In:Ga:Zn=5:1:6 or a composition in the vicinity thereof, the case is included where the atomic ratio of Ga is greater than 0.1 and less than or equal to 2 and the atomic ratio of Zn is greater than or equal to 5 and less than or equal to 7 with the atomic ratio of In being 5. Furthermore, when the atomic ratio is described as In:Ga:Zn=1:1:1 or a composition in the vicinity thereof, the case is included where the atomic ratio of Ga is greater than 0.1 and less than or equal to 2 and the atomic ratio of Zn is greater than 0.1 and less than or equal to 2 with the atomic ratio of In being 1.

The semiconductor layer may include two or more metal oxide layers having different compositions. For example, a stacked structure of a first metal oxide layer having In:M:Zn=1:3:4 [atomic ratio] or a composition in the vicinity thereof and a second metal oxide layer having In:M:Zn=1:1:1 [atomic ratio] or a composition in the vicinity thereof and being formed over the first metal oxide layer can be favorably employed. In particular, gallium or aluminum is preferably used as the element M.

Alternatively, a stacked structure of one selected from indium oxide, indium gallium oxide, and IGZO, and one selected from IAZO, IAGZO, and ITZO (registered trademark) may be employed, for example.

Examples of an oxide semiconductor having crystallinity include a c-axis-aligned crystalline oxide semiconductor (CAAC-OS) and a nanocrystalline oxide semiconductor (nc-OS).

Alternatively, a transistor using silicon in its channel formation region (a Si transistor) may be used. Examples of silicon include single crystal silicon, polycrystalline silicon, and amorphous silicon. In particular, a transistor containing low-temperature polysilicon (LTPS) in its semiconductor layer (also referred to as an LTPS transistor) can be used. The LTPS transistor has high field-effect mobility and excellent frequency characteristics.

With the use of Si transistors such as LTPS transistors, a circuit required to be driven at a high frequency (e.g., a data driver circuit) can be formed on the same substrate as the display portion. This allows simplification of an external circuit mounted on the display apparatus and a reduction in costs of parts and mounting costs.

An OS transistor has much higher field-effect mobility than a transistor containing amorphous silicon. In addition, the OS transistor has an extremely low leakage current between a source and a drain in an off state (hereinafter also referred to as off-state current), and charge accumulated in a capacitor that is connected in series to the transistor can be held for a long period. Furthermore, the power consumption of the display apparatus can be reduced with the OS transistor.

To increase the luminance of the light-emitting device included in the pixel circuit, the amount of current fed through the light-emitting device needs to be increased. To increase the current amount, the source-drain voltage of a driving transistor included in the pixel circuit needs to be increased. An OS transistor has a higher withstand voltage between a source and a drain than a Si transistor; hence, high voltage can be applied between the source and the drain of the OS transistor. Therefore, when an OS transistor is used as the driving transistor in the pixel circuit, the amount of current flowing through the light-emitting device can be increased, so that the luminance of the light-emitting device can be increased.

When transistors are driven in a saturation region, a change in source-drain current relative to a change in gate-source voltage can be smaller in an OS transistor than in a Si transistor. Accordingly, when an OS transistor is used as the driving transistor included in the pixel circuit, a current flowing between the source and the drain can be minutely determined by controlling the gate-source voltage. Thus, the amount of current flowing through the light-emitting device can be controlled. Consequently, the number of gray levels expressed by the pixel circuit can be increased.

Regarding saturation characteristics of current flowing when transistors are driven in the saturation region, even when the source-drain voltage of an OS transistor increases gradually, a more stable current (saturation current) can be fed through the OS transistor than through a Si transistor. Thus, by using an OS transistor as the driving transistor, a stable current can be fed through light-emitting devices even when the current-voltage characteristics of the light-emitting devices vary, for example. In other words, when the OS transistor is driven in the saturation region, the source-drain current hardly changes with an increase in the source-drain voltage. Hence, the luminance of the light-emitting device can be stable.

As described above, by using OS transistors as the driving transistors included in the pixel circuits, it is possible to inhibit black-level degradation, increase the luminance, increase the number of gray levels, and suppress variations in characteristics of light-emitting devices, for example.

The transistors included in the circuit 164 and the transistors included in the display portion 107 may have the same structure or different structures. One structure or two or more kinds of structures may be employed for a plurality of transistors included in the circuit 164. Similarly, one structure or two or more kinds of structures may be employed for a plurality of transistors included in the display portion 107.

All transistors included in the display portion 107 may be OS transistors, or all transistors included in the display portion 107 may be Si transistors. Alternatively, some of the transistors included in the display portion 107 may be OS transistors and the others may be Si transistors.

For example, when both an LTPS transistor and an OS transistor are used in the display portion 107, the display apparatus can have low power consumption and high driving capability. Note that a structure in which an LTPS transistor and an OS transistor are used in combination is referred to as LTPO in some cases. For example, it is preferable that an OS transistor be used as a transistor functioning as a switch for controlling electrical continuity between wirings and an LTPS transistor be used as a transistor for controlling current.

For example, one transistor included in the display portion 107 functions as a transistor for controlling a current flowing through the light-emitting device and can be referred to as a driving transistor. One of a source and a drain of the driving transistor is electrically connected to the pixel electrode of the light-emitting device. An LTPS transistor is preferably used as the driving transistor. In that case, the amount of current flowing through the light-emitting device can be increased.

Another transistor included in the display portion 107 functions as a switch for controlling selection or non-selection of a pixel and can be referred to as a selection transistor. A gate of the selection transistor is electrically connected to a gate line, and one of a source and a drain thereof is electrically connected to a signal line. An OS transistor is preferably used as the selection transistor. In that case, the gray level of the pixel can be maintained even with an extremely low frame frequency (e.g., 1 fps or less); thus, power consumption can be reduced by stopping the driver in displaying a still image.

As described above, the display apparatus of one embodiment of the present invention can have all of a high aperture ratio, high resolution, high display quality, and low power consumption.

Note that the display apparatus of one embodiment of the present invention has a structure including the OS transistor and the light-emitting device having an MML structure. This structure can significantly reduce a leakage current that would flow through a transistor and a leakage current that would flow between adjacent light-emitting devices. Displaying images on the display apparatus having this structure can bring one or more of image crispness, image sharpness, high color saturation, and a high contrast ratio to the viewer. When a leakage current that would flow through the transistor and a lateral leakage current that would flow between light-emitting devices are extremely low, display with little leakage of light at the time of black display (black-level degradation), for example, can be achieved.

In particular, current flowing between adjacent light-emitting devices having the MML structure can be extremely reduced.

### [Transistor 209 and Transistor 210]

FIGS. 16B and 16C are cross-sectional views each illustrating another example of a cross-sectional structure of a transistor that can be used for the display apparatus 100H.

A transistor 209 and a transistor 210 each include the conductive layer 221, the insulating layer 211, the semiconductor layer 231, the conductive layer 222a, the conductive layer 222b, an insulating layer 225, the conductive layer 223, and the insulating layer 215. The semiconductor layer 231 includes a channel formation region 231i and a pair of low-resistance regions 231n. The insulating layer 211 is positioned between the conductive layer 221 and the channel formation region 231i. The conductive layer 221 functions as a gate and the insulating layer 211 functions as a first gate insulating layer. The insulating layer 225 is positioned at least between the conductive layer 223 and the channel formation region 231i. The conductive layer 223 functions as a gate, and the insulating layer 225 functions as a second gate insulating layer. The conductive layer 222a is electrically connected to one of the pair of low-resistance regions 231n and the conductive layer 222b is electrically connected to the other of the pair of low-resistance regions 231n. The insulating layer 215 covers the conductive layer 223. An insulating layer 218 covers the transistor.

### Structure Example 1 of Insulating Layer 225

In the transistor 209, the insulating layer 225 covers the top and side surfaces of the semiconductor layer 231 (see FIG. 16B). The insulating layer 225 and the insulating layer 215 have openings, through which the conductive layers 222a and 222b are electrically connected to the low-resistance regions 231n. One of the conductive layers 222a and 222b functions as a source, and the other functions as a drain.

### Structure Example 2 of Insulating Layer 225

In the transistor 210, the insulating layer 225 overlaps with the channel formation region 231i of the semiconductor layer 231 and does not overlap with the low-resistance regions 231n (see FIG. 16C). For example, the insulating layer 225 can be processed in a predetermined shape using the conductive layer 223 as a mask. The insulating layer 215 covers the insulating layer 225 and the conductive layer 223. The insulating layer 215 includes openings, through which the conductive layers 222a and 222b are electrically connected to the low-resistance regions 231n.

### [Connection Portion 204]

A connection portion 204 is provided for the substrate 14b. The connection portion 204 includes a conductive layer 166, which is electrically connected to the wiring 165. Note that the connection portion 204 does not overlap with the substrate 16b, and the conductive layer 166 is exposed. Note that the conductive layer 166 and the conductive layer 171 can be formed by processing one conductive film. The conductive layer 166 is electrically connected to the FPC 177 through a connection layer 242. As the connection layer 242, for example, an anisotropic conductive film (ACF) or an anisotropic conductive paste (ACP) can be used.

### <<Display Apparatus 100I

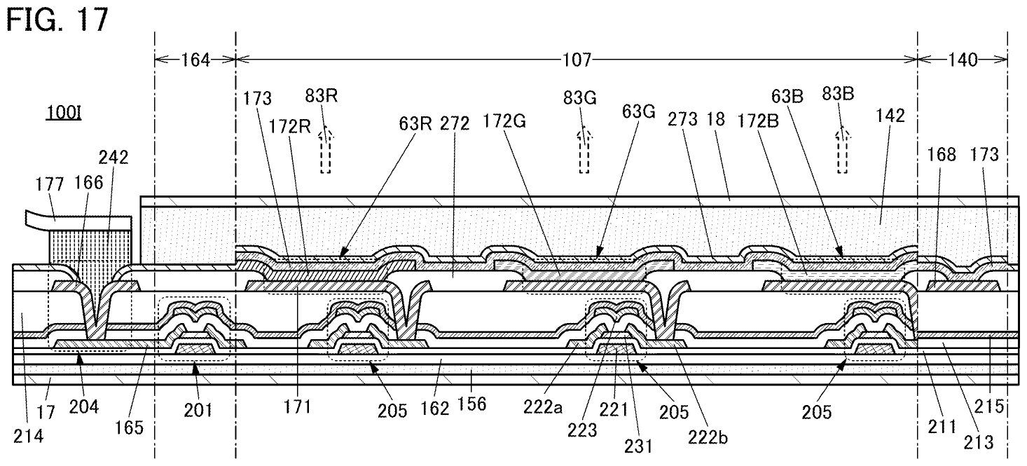

FIG. 17 is a cross-sectional view illustrating a structure of a display apparatus 100I. The display apparatus 100I is different from the display apparatus 100H in having flexibility. In other words, the display apparatus 100I is a flexible display. The display apparatus 100I includes a substrate 17 and a substrate 18 instead of the substrate 14b and the substrate 16b, respectively. The substrates 17 and 18 both have flexibility.

The display apparatus 100I includes a bonding layer 156 and an insulating layer 162. The insulating layer 162 and the substrate 17 are attached to each other with the bonding layer 156. For example, the material that can be used for the bonding layer 122 can be used for the bonding layer 156. For example, the material that can be used for the insulating layer 211, the insulating layer 213, or the insulating layer 215 can be used for the insulating layer 162. Note that the transistors 201 and 205 are provided over the insulating layer 162.

For example, the insulating layer 162 is formed over a formation substrate, and the transistors, the light-emitting devices 63, and the like are formed over the insulating layer 162. Then, the bonding layer 142 is formed over the light-emitting devices 63, and the formation substrate and the substrate 18 are attached to each other with the bonding layer 142. After that, the formation substrate is separated from the insulating layer 162 and the surface of the insulating layer 162 is exposed. Then, the bonding layer 156 is formed on the exposed surface of the insulating layer 162, and the insulating layer 162 and the substrate 17 are attached to each other with the bonding layer 156. In this manner, the components formed over the formation substrate can be transferred onto the substrate 17, whereby the display apparatus 100I can be manufactured.

### <<Display Apparatus 100J>>

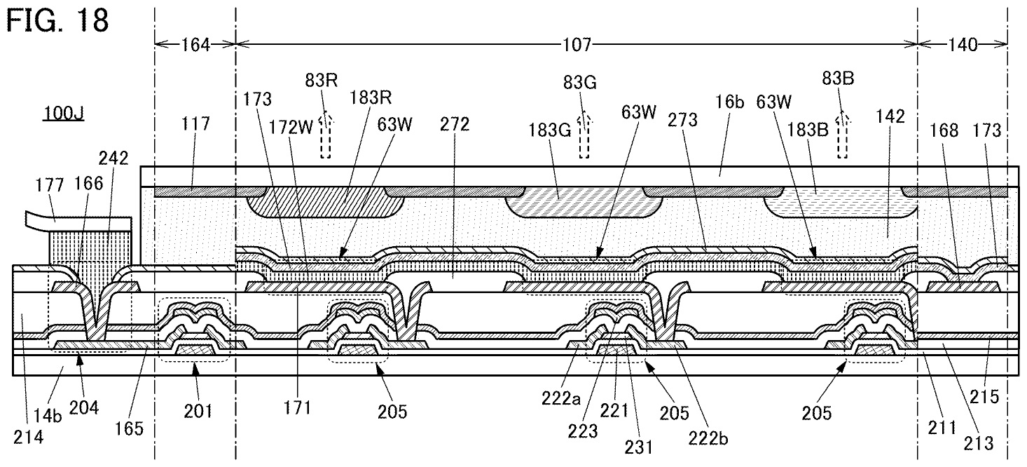

FIG. 18 is a cross-sectional view illustrating a structure of a display apparatus 100J. The display apparatus 100J is different from the display apparatus 100H in including light-emitting devices 63W, instead of the light-emitting devices 63R, 63G and 63B, and coloring layers 183R, 183G, and 183B.

The display apparatus 100J includes the coloring layers 183R, 183G, and 183B between the substrate 16b and the substrate 14b. The coloring layer 183R overlaps with one light-emitting device 63W, the coloring layer 183G overlaps with another light-emitting device 63W, and the coloring layer 183B overlaps with another light-emitting device 63W.

The display apparatus 100J includes a light-blocking layer 117. For example, the light-blocking layer 117 is provided between the coloring layers 183R and 183G, between the coloring layers 183G and 183B, and between the coloring layers 183B and 183R. The light-blocking layer 117 includes a region overlapping with the connection portion 140 and a region overlapping with the circuit 164.

The light-emitting device 63W can emit white light, for example. For example, the coloring layer 183R, the coloring layer 183G, and the coloring layer 183B can transmit red light, green light, and blue light, respectively. In this manner, the display apparatus 100J can emit the red light 83R, the green light 83G, and the blue light 83B, for example, to perform full color display.

At least part of this embodiment can be implemented in combination with any of the other embodiments and example described in this specification, as appropriate.

### Embodiment 10

In this embodiment, electronic devices of embodiments of the present invention will be described.

Electronic devices of this embodiment are each provided with the display apparatus of one embodiment of the present invention in a display portion. The display apparatus of one embodiment of the present invention is highly reliable and can be easily increased in resolution and definition. Thus, the display apparatus of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display apparatus of one embodiment of the present invention can have high definition, and thus can be favorably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, resolution of 4K, 8K, or higher is preferable. The pixel density (resolution) of the display apparatus of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. With such a display apparatus having one or both of high resolution and high definition, the electronic device can have higher realistic sensation, sense of depth, and the like in personal use such as portable use or home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic device in this embodiment can have a variety of functions. For example, the electronic device in this embodiment can have a function of displaying a variety of data (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

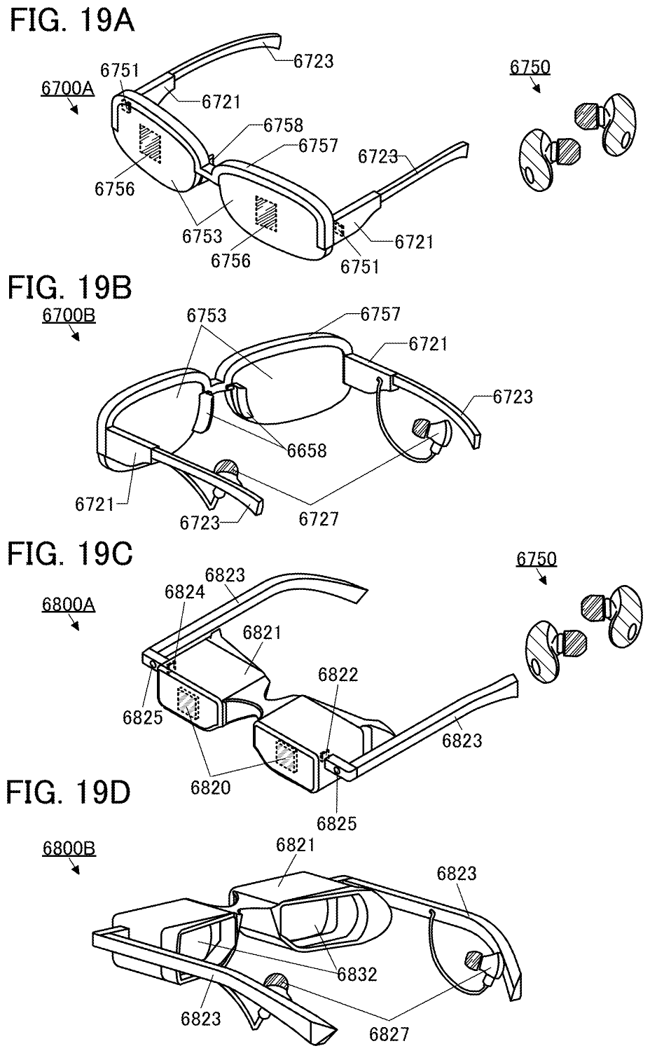

Examples of head-mounted wearable devices are described with reference to FIGS. 19A to 19D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 6700A illustrated in FIG. 19A and an electronic device 6700B illustrated in FIG. 19B each include a pair of display panels 6751, a pair of housings 6721, a communication portion (not illustrated), a pair of wearing portions 6723, a control portion (not illustrated), an image capturing portion (not illustrated), a pair of optical members 6753, a frame 6757, and a pair of nose pads 6758.

The display apparatus of one embodiment of the present invention can be used for the display panels 6751. Thus, a highly reliable electronic device is obtained.

The electronic devices 6700A and 6700B can each project images displayed on the display panels 6751 onto display regions 6756 of the optical members 6753. Since the optical members 6753 have a light-transmitting property, the user can see images displayed on the display regions, which are superimposed on transmission images seen through the optical members 6753. Accordingly, the electronic devices 6700A and 6700B are electronic devices capable of AR display.

In the electronic devices 6700A and 6700B, a camera capable of capturing images of the front side may be provided as the image capturing portion. Furthermore, when the electronic devices 6700A and 6700B are provided with an acceleration sensor such as a gyroscope sensor, the orientation of the user's head can be sensed and an image corresponding to the orientation can be displayed on the display regions 6756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic devices 6700A and 6700B are provided with a battery so that they can be charged wirelessly and/or by wire.

A touch sensor module may be provided in the housing 6721. The touch sensor module has a function of detecting a touch on the outer surface of the housing 6721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 6721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element (also referred to as a photoelectric conversion device) can be used as a light-receiving element. One or both of an inorganic semiconductor and an organic semiconductor can be used for an active layer of the photoelectric conversion element.

An electronic device 6800A illustrated in FIG. 19C and an electronic device 6800B illustrated in FIG. 19D each include a pair of display portions 6820, a housing 6821, a communication portion 6822, a pair of wearing portions 6823, a control portion 6824, a pair of image capturing portions 6825, and a pair of lenses 6832.

The display apparatus of one embodiment of the present invention can be used in the display portions 6820. Thus, a highly reliable electronic device is obtained.

The display portions 6820 are positioned inside the housing 6821 so as to be seen through the lenses 6832. When the pair of display portions 6820 display different images, three-dimensional display using parallax can be performed.

The electronic devices 6800A and 6800B can be regarded as electronic devices for VR. The user who wears the electronic device 6800A or the electronic device 6800B can see images displayed on the display portions 6820 through the lenses 6832.

The electronic devices 6800A and 6800B preferably include a mechanism for adjusting the lateral positions of the lenses 6832 and the display portions 6820 so that the lenses 6832 and the display portions 6820 are positioned optimally in accordance with the positions of the user's eyes. Moreover, the electronic devices 6800A and 6800B preferably include a mechanism for adjusting focus by changing the distance between the lenses 6832 and the display portions 6820.

The electronic device 6800A or the electronic device 6800B can be mounted on the user's head with the wearing portions 6823. FIG. 19C, for instance, shows an example where the wearing portion 6823 has a shape like a temple (also referred to as a joint or the like) of glasses; however, one embodiment of the present invention is not limited thereto. The wearing portion 6823 can have any shape with which the user can wear the electronic device, for example, a shape of a helmet or a band.

The image capturing portion 6825 has a function of obtaining information on the external environment. Data obtained by the image capturing portion 6825 can be output to the display portion 6820. An image sensor can be used for the image capturing portion 6825. Moreover, a plurality of cameras may be provided so as to support a plurality of fields of view, such as a telescope field of view and a wide field of view.

Although an example where the image capturing portions 6825 are provided is shown here, a range sensor (also referred to as a sensing portion) capable of measuring a distance between the user and an object just needs to be provided. In other words, the image capturing portion 6825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 6800A may include a vibration mechanism that functions as bone-conduction earphones. For example, at least one of the display portion 6820, the housing 6821, and the wearing portion 6823 can include the vibration mechanism. Thus, without additionally requiring an audio device such as headphones, earphones, or a speaker, the user can enjoy video and sound only by wearing the electronic device 6800A.

The electronic devices 6800A and 6800B may each include an input terminal. To the input terminal, a cable for supplying a video signal from a video output device or the like, power for charging a battery provided in the electronic device, and the like can be connected.

The electronic device of one embodiment of the present invention may have a function of performing wireless communication with earphones 6750. The earphones 6750 include a communication portion (not illustrated) and has a wireless communication function. The earphones 6750 can receive information (e.g., audio data) from the electronic device with the wireless communication function. For example, the electronic device 6700A in FIG. 19A has a function of transmitting information to the earphones 6750 with the wireless communication function. As another example, the electronic device 6800A in FIG. 19C has a function of transmitting information to the earphones 6750 with the wireless communication function.

The electronic device may include an earphone portion. The electronic device 6700B in FIG. 19B includes earphone portions 6727. For example, the earphone portion 6727 can be connected to the control portion by wire. Part of a wiring that connects the earphone portion 6727 and the control portion may be positioned inside the housing 6721 or the mounting portion 6723.

Similarly, the electronic device 6800B in FIG. 19D includes earphone portions 6827. For example, the earphone portion 6827 can be connected to the control portion 6824 by wire. Part of a wiring that connects the earphone portion 6827 and the control portion 6824 may be positioned inside the housing 6821 or the wearing portion 6823. Alternatively, the earphone portions 6827 and the wearing portions 6823 may include magnets. This is preferred because the earphone portions 6827 can be fixed to the wearing portions 6823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic devices 6700A and 6700B) and the goggles-type device (e.g., the electronic devices 6800A and 6800B) are preferable as the electronic device of one embodiment of the present invention.

The electronic device of one embodiment of the present invention can transmit information to earphones by wire or wirelessly.

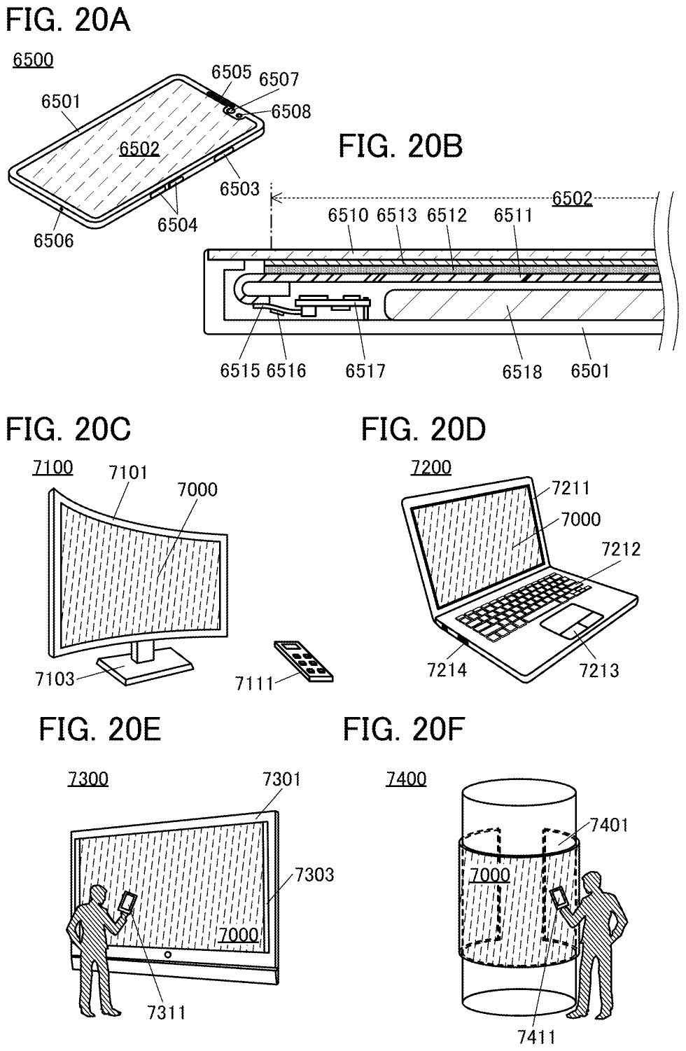

An electronic device 6500 illustrated in FIG. 20A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502. Thus, a highly reliable electronic device is obtained.

FIG. 20B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the region that is folded back. An IC 6516 is mounted on the FPC 6515. The FPC 6515 is connected to a terminal provided on the printed circuit board 6517.

The flexible display of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be achieved.

FIG. 20C illustrates an example of a television device. In a television device 7100, a display portion 7000 is incorporated in a housing 7101. Here, the housing 7101 is supported by a stand 7103.

The display apparatus of one embodiment of the present invention can be used in the display portion 7000. Thus, a highly reliable electronic device is obtained.

Operation of the television device 7100 illustrated in FIG. 20C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel of the remote controller 7111, channels and volume can be controlled and images displayed on the display portion 7000 can be controlled.

Note that the television device 7100 includes a receiver, a modem, and the like. A general television broadcast can be received with the receiver. When the television device is connected to a communication network with or without wires via the modem, one-way (from a transmitter to a receiver) or two-way (e.g., between a transmitter and a receiver or between receivers) information communication can be performed.

FIG. 20D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The display apparatus of one embodiment of the present invention can be used in the display portion 7000. Thus, a highly reliable electronic device is obtained.

FIGS. 20E and 20F illustrate examples of digital signage.

Digital signage 7300 illustrated in FIG. 20E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 20F shows digital signage 7400 attached to a cylindrical pillar 7401. The digital signage 7400 includes the display portion 7000 provided along a curved surface of the pillar 7401.

In FIGS. 20E and 20F, the display apparatus of one embodiment of the present invention can be used in the display portion 7000. Thus, a highly reliable electronic device is obtained.

A larger area of the display portion 7000 can increase the amount of information that can be provided at a time. The larger display portion 7000 attracts more attention, so that the effectiveness of the advertisement can be increased, for example.

The use of the touch panel in the display portion 7000 is preferable because in addition to display of still or moving images on the display portion 7000, intuitive operation by a user is possible. Moreover, for an application for providing information such as route information or traffic information, usability can be enhanced by intuitive operation.

As illustrated in FIGS. 20E and 20F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, a displayed image on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

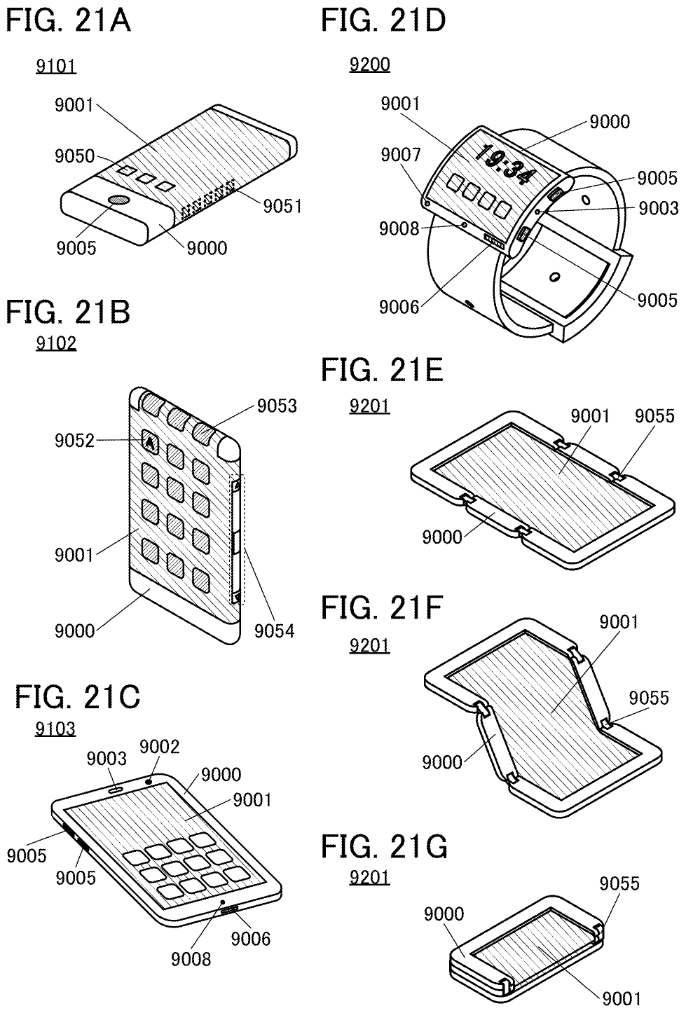

Electronic devices illustrated in FIGS. 21A to 21G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 9008, and the like.

The electronic devices illustrated in FIGS. 21A to 21G have a variety of functions. For example, the electronic devices can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of taking a still image or a moving image, a function of storing the taken image in a storage medium (an external storage medium or a storage medium incorporated in the camera), a function of displaying the taken image on the display portion, and the like.

The electronic devices in FIGS. 21A to 21G are described in detail below.

FIG. 21A is a perspective view of a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 21A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050, for example, may be displayed at the position where the information 9051 is displayed.

FIG. 21B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of user's clothes. Thus, the user can see the display without taking out the portable information terminal 9102 from the pocket and decide whether to answer the call, for example.

FIG. 21C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 21D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 21E to 21G are perspective views of a foldable portable information terminal 9201. FIG. 21E is a perspective view showing the portable information terminal 9201 that is opened. FIG. 21G is a perspective view showing the portable information terminal 9201 that is folded. FIG. 21F is a perspective view showing the portable information terminal 9201 that is shifted from one of the states in FIGS. 21E and 21G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with any of the other embodiments and example as appropriate. In this specification, in the case where a plurality of structure examples are shown in one embodiment, the structure examples can be combined as appropriate.

### Example

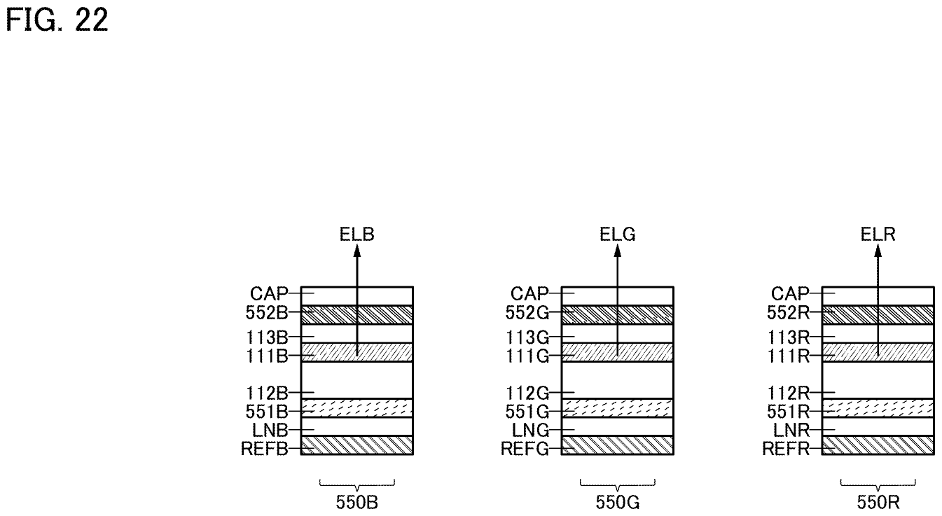

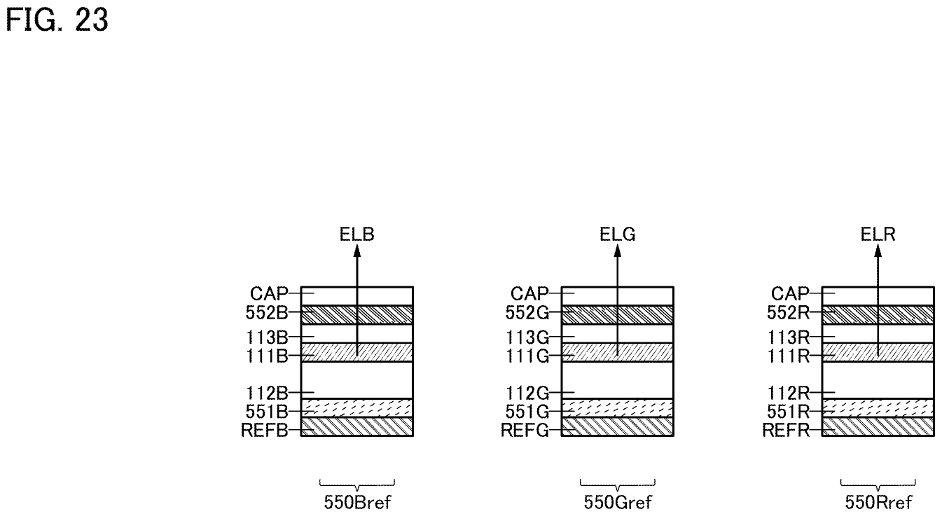

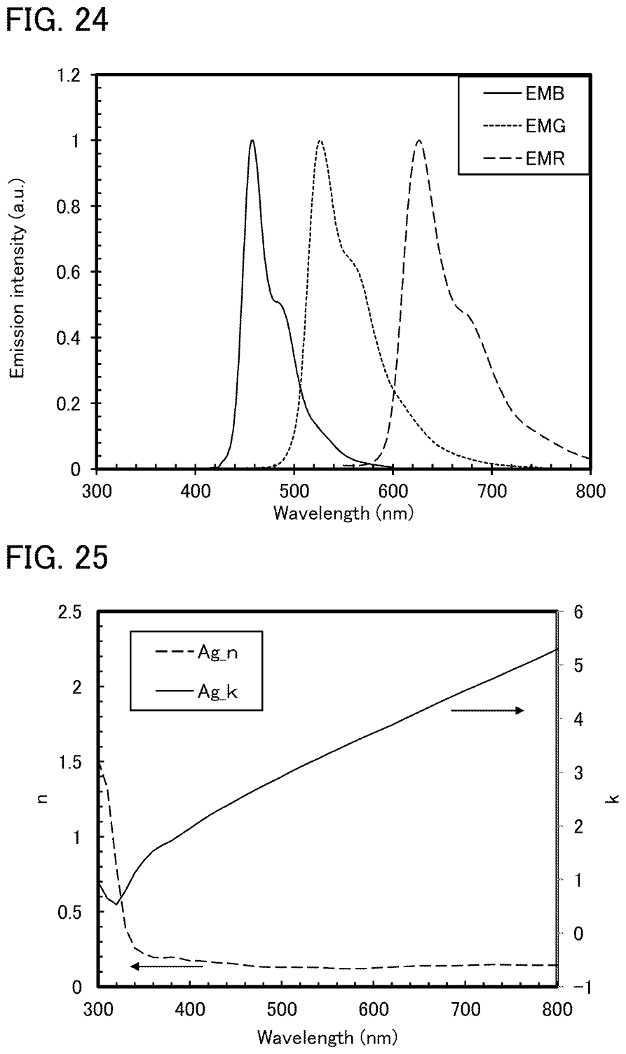

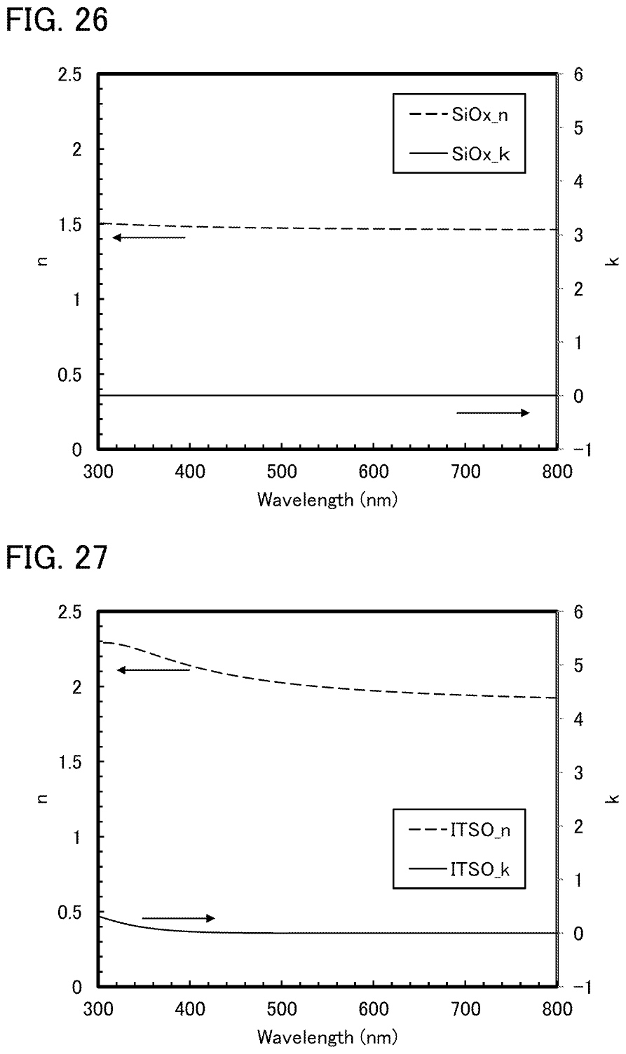

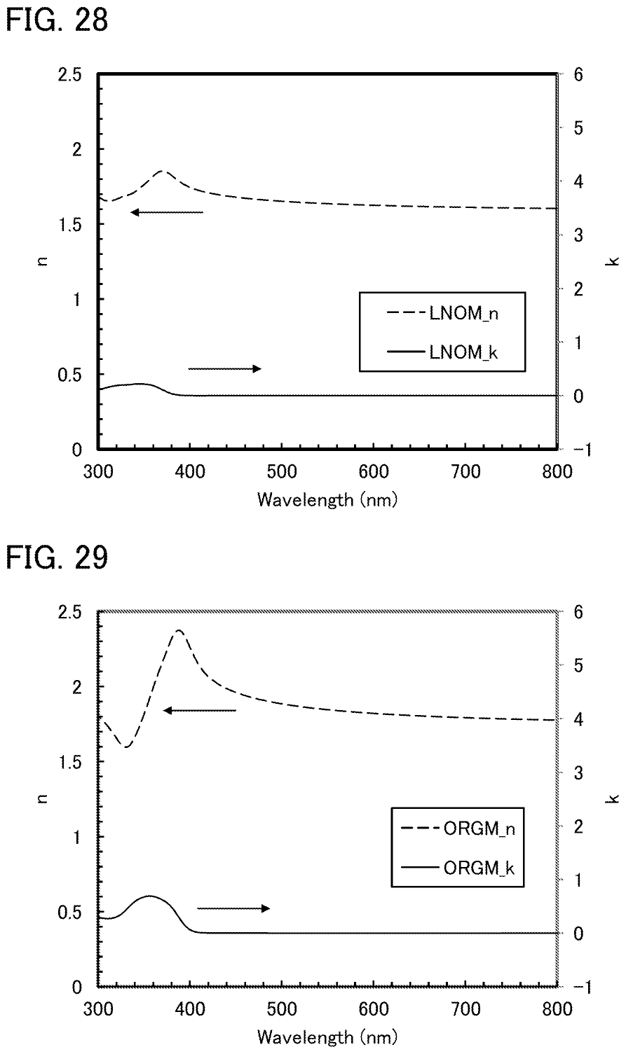

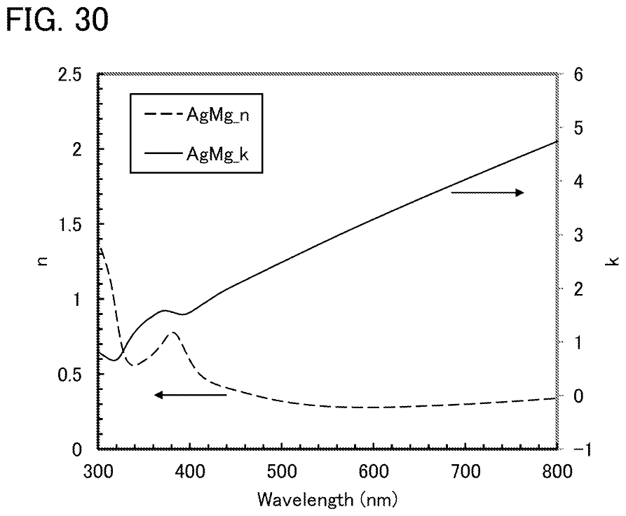

In this example, light-emitting devices of embodiments of the present invention are described with reference to FIG. 22, FIG. 23, FIG. 24, FIG. 25, FIG. 26, FIG. 27, FIG. 28, FIG. 29, and FIG. 30.

FIG. 22 illustrates structures of a light-emitting device 550B, a light-emitting device 550G, and a light-emitting device 550R of embodiments of the present invention.

FIG. 23 illustrates structures of a light-emitting device 550Bref, a light-emitting device 550Gref, and a light-emitting device 550Rref.

FIG. 24 shows emission spectra of a light-emitting material EMB, a light-emitting material EMG, and a light-emitting material EMR.

FIG. 25 shows wavelength dependence of the ordinary refractive index n and the extinction coefficient k of Ag.

FIG. 26 shows wavelength dependence of the ordinary refractive index n and the extinction coefficient k of SiOx.

FIG. 27 shows wavelength dependence of the ordinary refractive index n and the extinction coefficient k of ITSO.

FIG. 28 shows wavelength dependence of the ordinary refractive index n and the extinction coefficient k of LNOM.

FIG. 29 shows wavelength dependence of the ordinary refractive index n and the extinction coefficient k of ORGM.

FIG. 30 shows wavelength dependence of the ordinary refractive index n and the extinction coefficient k of Ag:Mg.

### <Light-Emitting Device 1B>

A light-emitting device 1i, which is described and used for calculation in this example, has a structure similar to that of the light-emitting device 550B (see FIG. 22).

The light-emitting device 1B includes a reflective film REFB, a layer LNB, an electrode 551B, a layer 112B, a layer 111B, and an electrode 552B.

The electrode 552B overlaps with the reflective film REFB, and the layer 111B is positioned between the electrode 552B and the reflective film REFB and contains the light-emitting material EMB. The light-emitting material EMB has an emission spectrum having a peak at the wavelength λX.

The layer 112B is positioned between the layer 111B and the reflective film REFB and contains the organic compound LNOM. The organic compound LNOM has an ordinary refractive index higher than or equal to 1.45 and lower than or equal to 1.75 at a wavelength in the range of 450 nm to 650 nm inclusive.

The electrode 551B is positioned between the layer 112B and the reflective film REFB. The electrode 551B has a property of transmitting light with a wavelength λB and contains an element with an atomic number of 21 to 83 at 5 atomic % or higher.

The layer LNB is positioned between the electrode 551B and the reflective film REFB. The layer LNB has a property of transmitting light with the wavelength λB and contains an element with an atomic number of 1 to 20 at 95 atomic % or higher. The reflective film REFB reflects light with the wavelength B.

### <<Structure of Light-Emitting Device 1B>>

Table 1 shows the structure of the light-emitting device 1B. Note that in the tables in this example, subscript and superscript characters are written in ordinary size for convenience. For example, a subscript character in an abbreviation or a superscript character in a unit are written in ordinary size in the tables. The corresponding description in the specification gives an accurate reading of such notations in the tables.

TABLE 1

| | Reference | | Composition | Thickness/ |
|---|---|---|---|---|
| Component | numeral | Material | ratio | nm |
| Layer | CAP | CAPM | | 70 |
| Electrode | 552B | Ag:Mg | 1:0.1 | 15 |
| Layer | 113B | ETM | | 34.6 |
| Layer | 111B | EMB | | 25 |
| Layer | 112B | LNOM | | 47.1 |
| Electrode | 551B | ITSO | | 48.3 |
| Layer | LNB | SiOx | | 62.8 |
| Reflective film | REFB | Ag | | 100 |

The reflective film REFB contains Ag and has a thickness of 100 nm. Note that FIG. 25 shows wavelength dependence of the ordinary refractive index n and the extinction coefficient k of Ag.

The layer LNB contains silicon oxide (abbreviation: SiOx) and has a thickness of 62.8 nm. Note that SiOx has a low ordinary refractive index, a low extinction coefficient, and a light-transmitting property. FIG. 26 shows wavelength dependence of the ordinary refractive index n and the extinction coefficient k of SiOx. SiOx has an ordinary refractive index of 1.48 at a wavelength of 460 nm.

The layer LNB has an optical length in the thickness direction of 92.9 nm obtained from the product of the thickness and the ordinary refractive index. Note that a value obtained by dividing the optical length 92.9 nm by the wavelength 460 nm is 0.202.

The electrode 551B contains indium oxide-tin oxide containing silicon or silicon oxide (abbreviation: ITSO) and has a thickness of 48.3 nm. The electrode 551B can be formed by a sputtering method using a target containing In₂O₃, SnO₂, and SiO₂ at a weight ratio of 85:10:5. Note that ITSO has a high ordinary refractive index, a low extinction coefficient, and a light-transmitting property. FIG. 27 shows wavelength dependence of the ordinary refractive index n and the extinction coefficient k of ITSO. ITSO has an ordinary refractive index of 2.06 at a wavelength of 460 nm.

The electrode 551B has an optical length in the thickness direction of 99.5 nm obtained from the product of the thickness and the ordinary refractive index. Note that a value obtained by dividing the optical length 99.5 nm by the wavelength 460 nm is 0.216.

The layer 112B contains the hole-transport organic compound LNOM and has a thickness of 47.1 nm. For example, N-(3,3″,5,5″-tetra-t-butyl-1,1′:3,1″-terphenyl-5′-yl)-N-(4-cyclohexylphenyl)-9,9-dimeth yl-9H-fluoren-2-amine (abbreviation: mmtBumTPchPAF) can be used as the organic compound LNOM. Note that mmtBumTPchPAF contains carbon atoms forming bonds by sp³ hybrid orbitals at 41% of the total carbon atoms in the molecule. The structural formula of mmtBumTPchPAF is shown below. FIG. 28 shows wavelength dependence of the ordinary refractive index n and the extinction coefficient k of the hole-transport organic compound LNOM. The organic compound LNOM has an ordinary refractive index of 1.67 at a wavelength of 460 nm.

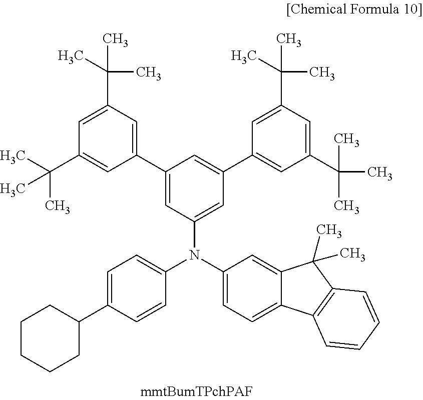 [SMILES: CC(C)(C)c1cc(-c2cc(-c3cc(C(C)(C)C)cc(C(C)(C)C)c3)cc(N(c3ccc(C4CCCCC4)cc3)c3ccc4c(c3)C(C)(C)c3ccccc3-4)c2)cc(C(C)(C)C)c1]

The 112B has an optical length in the thickness direction of 78.7 nm obtained from the product of the thickness and the ordinary refractive index. Note that a value obtained by dividing the optical length 78.7 nm by the wavelength 460 nm is 0.171.

The layer 111B contains the light-emitting material EMB and has a thickness of 25 nm. Note that an emission spectrum of the light-emitting material EMB has a peak at a wavelength of 458 nm (see FIG. 24). The ordinary refractive index n and the extinction coefficient k of the light-emitting material EMB are assumed to have the same wavelength dependence as the ordinary refractive index n and the extinction coefficient k of the organic material ORGM. FIG. 29 shows wavelength dependence of the ordinary refractive index n and the extinction coefficient k of the organic material ORGM. The organic material ORGM has an ordinary refractive index of 1.94 at a wavelength of 460 nm.

The layer 113B contains the electron-transport material ETM and has a thickness of 34.6 nm. The ordinary refractive index n and the extinction coefficient k of the electron-transport material ETM are assumed to have the same wavelength dependence as the ordinary refractive index n and the extinction coefficient k of the organic material ORGM.

The electrode 552B contains silver (Ag) and magnesium (Mg) at a volume ratio of Ag:Mg=1:0.1 and has a thickness of 15 nm. Note that FIG. 30 shows wavelength dependence of the ordinary refractive index n and the extinction coefficient k of Ag:Mg.

The layer CAP contains CAPM and has a thickness of 70 nm. The ordinary refractive index n and the extinction coefficient k of CAPM are assumed to have the same wavelength dependence as the ordinary refractive index n and the extinction coefficient k of the organic material ORGM.

### <<Simulation of Operation Characteristics of Light-Emitting Device 1B>>

Operation characteristics of the light-emitting device 1B were simulated. As software for the calculation, an organic device simulator (a semiconducting emissive thin film optics simulator: setfos, produced by Cybernet Systems Co., Ltd.) was used. Note that the light-emitting device 1B emits light ELB from the layer 111B in accordance with its operation.

Table 2 shows the calculated light extraction efficiency of the light-emitting device 1B. Table 2 also shows the light extraction efficiency of a comparative device having a structure to be described later (in reference example). Note that in the calculation of the light extraction efficiency of a light-emitting device, light emitted in the front direction of the light-emitting device is assumed to have Lambertian intensity distribution. Furthermore, the thicknesses of the layer LNB, the electrode 551B, the layer 112B, and the layer 113B of the light-emitting device 1B are optimized so that the light extraction efficiency is maximized.

TABLE 2

| | Light extraction efficiency (%) |
|---|---|
| Light-emitting device 1B | 36.7 |
| Comparative device 1B | 27.5 |

The simulation results show that the light-emitting device 1B has favorable characteristics. For example, the light-emitting device 1B emits blue light at high efficiency. Furthermore, it is confirmed that the light extraction efficiency of the light-emitting device 1B is higher than that of the comparative device 1B by 9.2 points, reducing power consumption.

Note that part of light emitted from the layer 1111B to the electrode 551B is reflected by the electrode 551B having a higher ordinary refractive index than the layer 112B, and the phase of the light is inverted owing to the reflection. In other words, the phase is shifted by an amount corresponding to half of 460 nm. Moreover, the light emitted from the layer 111B to the electrode 551B travels back and forth in the layer 112B in the thickness direction until the light is reflected by the electrode 551B to return to the layer 111B. The layer 112B of the comparative device 1B contains a hole-transport material HTM, and has an ordinary refractive index of 1.94 at a wavelength of 460 nm. The value obtained by dividing the product of the ordinary refractive index 1.94 and the thickness 124.1 nm by 460 nm is 0.52. Thus, the light emitted from the layer 111B to the electrode 551B returns to the layer 111B with a phase shift corresponding to the sum of 0.52 times, 0.5 times, and 0.52 times of 460 nm, i.e., 1.54 times of 460 nm. As a result, the light emitted from the layer 111B to the electrode 551B and light emitted from the layer 111B to the electrode 552B attenuate each other, resulting in a decrease in light extraction efficiency.

### <Light-Emitting Device 1G>

A light-emitting device 1G, which is described and used for calculation in this example, has a structure similar to that of the light-emitting device 550G (see FIG. 22).

### <<Structure of Light-Emitting Device 1G>>

Table 3 shows the structure of the light-emitting device 1G.

TABLE 3

| | Reference | | Composition | Thickness/ |
|---|---|---|---|---|
| Component | numeral | Material | ratio | nm |
| Layer | CAP | CAPM | | 70 |
| Electrode | 552G | Ag:Mg | 1:0.1 | 15 |
| Layer | 113G | ETM | | 41.47 |
| Layer | 111G | EMG | | 40 |
| Layer | 112G | LNOM | | 72.4 |
| Electrode | 551G | ITSO | | 48.3 |
| Layer | LNG | SiOx | | 62.8 |
| Reflective film | REFG | Ag | | 100 |

The reflective film REFG contains Ag and has a thickness of 100 nm.

The layer LNG contains SiOx and has a thickness of 62.8 nm.

The electrode 551G contains ITSO and has a thickness of 48.3 nm.

The layer 112G contains the hole-transport organic compound LNOM and has a thickness of 72.4 nm.

The layer 111G contains the light-emitting material EMG and has a thickness of 40 nm. Note that an emission spectrum of the light-emitting material EMG has a peak at a wavelength of 527 nm (see FIG. 24). The ordinary refractive index n and the extinction coefficient k of the light-emitting material EMG are assumed to have the same wavelength dependence as the ordinary refractive index n and the extinction coefficient k of the organic material ORGM.

The layer 113G contains the electron-transport material ETM and has a thickness of 41.47 nm.

The electrode 552G contains Ag and Mg at a volume ratio of Ag:Mg=1:0.1 and has a thickness of 15 nm.

The layer CAP contains CAPM and has a thickness of 70 nm.

### <<Simulation of Operation Characteristics of Light-Emitting Device 1G>>

Operation characteristics of the light-emitting device 1G were simulated using the above software. Note that the light-emitting device 1G emits light ELG from the layer 111G in accordance with its operation.

Table 4 shows the calculated light extraction efficiency of the light-emitting device 1G. Table 4 also shows the light extraction efficiency of a comparative device having a structure to be described later (in reference example). Note that in the calculation of the light extraction efficiency of a light-emitting device, light emitted in the front direction of the light-emitting device is assumed to have Lambertian intensity distribution. Furthermore, the thicknesses of the layer 112G and the layer 113G of the light-emitting device 1G are optimized so that the light extraction efficiency is maximized.

TABLE 4

| | Light extraction efficiency (%) |
|---|---|
| Light-emitting device 1G | 36.7 |
| Comparative device 1G | 32.8 |

The simulation results show that the light-emitting device 1G has favorable characteristics. For example, the light-emitting device 1G emits green light at high efficiency. Furthermore, it is confirmed that the light extraction efficiency of the light-emitting device 1G is higher than that of the comparative device 1G by 3.9 points, reducing power consumption.

The light-emitting device 1G has the same structure as the light-emitting device 1B. Specifically, the reflective film REFG and the reflective film REFB have the same structure, the layer LNG and the layer LNB have the same structure, and the electrode 551G and the electrode 551B have the same structure. Accordingly, the reflective film REFB and the reflective film REFG can be formed in the same step, the layer LNB and the layer LNG can be formed in the same step, and the electrode 551B and the electrode 551G can be formed in the same step. In addition, the manufacturing process can be simplified.

### <Light-Emitting Device 1R>

A light-emitting device 1R, which is described and used for calculation in this example, has a structure similar to that of the light-emitting device 550R (see FIG. 22).

### <<Structure of Light-Emitting Device 1R>>

Table 5 shows the structure of the light-emitting device 1R.

TABLE 5

| | Reference | | Composition | Thickness/ |
|---|---|---|---|---|
| Component | numeral | Material | ratio | nm |
| Layer | CAP | CAPM | | 70 |
| Electrode | 552R | Ag:Mg | 1:0.1 | 15 |
| Layer | 113R | ETM | | 58.35 |
| Layer | 111R | EMR | | 40 |
| Layer | 112R | LNOM | | 114.4 |
| Electrode | 551R | ITSO | | 48.3 |
| Layer | LNR | SiOx | | 62.8 |
| Reflective film | REFR | Ag | | 100 |

The reflective film REFR contains Ag and has a thickness of 100 nm.

The layer LNR contains SiOx and has a thickness of 62.8 nm.

The electrode 551R contains ITSO and has a thickness of 48.3 nm.

The layer 112R contains the hole-transport organic compound LNOM and has a thickness of 114.4 nm. The layer 111R contains the light-emitting material EMR and has a thickness of 40 nm. Note that an emission spectrum of the light-emitting material EMR has a peak at a wavelength of 627 nm (see FIG. 24). The ordinary refractive index n and the extinction coefficient k of the light-emitting material EMR are assumed to have the same wavelength dependence as the ordinary refractive index n and the extinction coefficient k of the organic material ORGM.

The layer 113R contains the electron-transport material ETM and has a thickness of 58.35 nm.

The electrode 552R contains Ag and Mg at a volume ratio of Ag:Mg=1:0.1 and has a thickness of 15 nm.

The layer CAP contains CAPM and has a thickness of 70 nm.

### <<Simulation of Operation Characteristics of Light-Emitting Device 1R>>

Operation characteristics of the light-emitting device 1R were simulated using the above software. Note that the light-emitting device 1R emits light ELR from the layer 111R in accordance with its operation.

Table 6 shows the calculated light extraction efficiency of the light-emitting device 1R. Table 6 also shows the light extraction efficiency of a comparative device having a structure to be described later (in reference example). Note that in the calculation of the light extraction efficiency of a light-emitting device, light emitted in the front direction of the light-emitting device is assumed to have Lambertian intensity distribution. Furthermore, the thicknesses of the layer 112R and the layer 113R of the light-emitting device 1R are optimized so that the light extraction efficiency is maximized.

TABLE 6

| | Light extraction efficiency (%) |
|---|---|
| Light-emitting device 1R | 38.3 |
| Comparative device 1R | 34.1 |

The simulation results show that the light-emitting device 1R has favorable characteristics. For example, the light-emitting device 1R emits red light at high efficiency. Furthermore, it is confirmed that the light extraction efficiency of the light-emitting device 1R is higher than that of the comparative device 1R by 4.2 points, reducing power consumption.

The light-emitting device 1R has the same structure as the light-emitting device 1B. Specifically, the reflective film REFR and the reflective film REFB have the same structure, the layer LNR and the layer LNB have the same structure, and the electrode 551R and the electrode 551B have the same structure. Accordingly, the reflective film REFB and the reflective film REFR can be formed in the same step, the layer LNB and the layer LNR can be formed in the same step, and the electrode 551B and the electrode 551R can be formed in the same step. In addition, the manufacturing process can be simplified.

### Reference Example

The comparative devices 1B, 1G, and 1R used for calculation in this example are described.

### <Comparative Device 1B>

The comparative device 1i, which is described and used for calculation in this example, has a structure similar to that of the light-emitting device 550Bref (see FIG. 23).

The comparative device 1B is different from the light-emitting device 1B in that the layer LNB is not included, the electrode 551B has a thickness of 10 nm instead of 48.3 nm, the layer 112B contains the hole-transport material HTM instead of the hole-transport organic compound LNOM and has a thickness of 124.1 nm instead of 47.1 nm, and the layer 113B has a thickness of 35.7 nm instead of 34.6 nm. Here, the above description is referred to for parts having the same structures as the above. Note that the ordinary refractive index n and the extinction coefficient k of the hole-transport material HTM are assumed to have the same wavelength dependence as the ordinary refractive index n and the extinction coefficient k of the organic material ORGM.

### <<Simulation of Operation Characteristics of Comparative Device 1B>>

Operation characteristics of the comparative device 1B were simulated using the above software. Note that the comparative device 1B emits the light ELB from the layer 111B in accordance with its operation. Table 2 shows the calculated light extraction efficiency of the comparative device 1B. Note that in the calculation of the light extraction efficiency of a comparative device, light emitted in the front direction of the comparative device is assumed to have Lambertian intensity distribution. Furthermore, the thicknesses of the layer 112B and the layer 113B of the comparative device 1B are optimized so that the light extraction efficiency is maximized.

### <Comparative Device 1G>

The comparative device 1G, which is described and used for calculation in this example, has a structure similar to that of the light-emitting device 550Gref (see FIG. 23).

The comparative device 1G is different from the light-emitting device 1G in that the layer LNG is not included, the electrode 551G has a thickness of 10 nm instead of 48.3 nm, the layer 112G contains the hole-transport material HTM instead of the hole-transport organic compound LNOM and has a thickness of 154.2 nm instead of 72.4 nm, and the layer 113G has a thickness of 42.5 nm instead of 41.47 nm. Here, the above description is referred to for parts having the same structures as the above. Note that the ordinary refractive index n and the extinction coefficient k of the hole-transport material HTM are assumed to have the same wavelength dependence as the ordinary refractive index n and the extinction coefficient k of the organic material ORGM.

### <<Simulation of Operation Characteristics of Comparative Device 1G>>

Operation characteristics of the comparative device 1G were simulated using the above software. Note that the comparative device 1G emits the light ELG from the layer 111G in accordance with its operation. Table 4 shows the calculated light extraction efficiency of the comparative device 1G. Note that in the calculation of the light extraction efficiency of a comparative device, light emitted in the front direction of the comparative device is assumed to have Lambertian intensity distribution. Furthermore, the thicknesses of the layer 112G and the layer 113G of the comparative device 1G are optimized so that the light extraction efficiency is maximized.

### <Comparative Device 1R>

The comparative device 1R, which is described and used for calculation in this example, has a structure similar to that of the light-emitting device 550Rref (see FIG. 23).

The comparative device 1R is different from the light-emitting device 1R in that the layer LNR is not included, the electrode 551R has a thickness of 10 nm instead of 48.3 nm, the layer 112R contains the hole-transport material HTM instead of the hole-transport organic compound LNOM and has a thickness of 199.0 nm instead of 114.4 nm, and the layer 113R has a thickness of 59.2 nm instead of 58.35 nm. Here, the above description is referred to for parts having the same structures as the above. Note that the ordinary refractive index n and the extinction coefficient k of the hole-transport material HTM are assumed to have the same wavelength dependence as the ordinary refractive index n and the extinction coefficient k of the organic material ORGM.

### <<Simulation of Operation Characteristics of Comparative Device 1R>>

Operation characteristics of the comparative device 1R were simulated using the above software. Note that the comparative device 1R emits the light ELR from the layer 111R in accordance with its operation. Table 6 shows the calculated light extraction efficiency of the comparative device 1R. Note that in the calculation of the light extraction efficiency of a comparative device, light emitted in the front direction of the comparative device is assumed to have Lambertian intensity distribution. Furthermore, the thicknesses of the layer 112R and the layer 113R of the comparative device 1R are optimized so that the light extraction efficiency is maximized.

This application is based on Japanese Patent Application Serial No. 2022-100505 filed with Japan Patent Office on Jun. 22, 2022, the entire contents of which are hereby incorporated by reference.

What is claimed is:

1. A light-emitting device comprising:
a first reflective film;
a first layer;
a second layer;
a third layer;
a fourth layer; and
a first electrode,
wherein the first electrode overlaps with the first reflective film,
wherein the fourth layer is positioned between the first electrode and the first reflective film,
wherein the fourth layer comprises a first light-emitting material,
wherein the first light-emitting material has an emission spectrum having a peak at a first wavelength,
wherein the third layer is positioned between the fourth layer and the first reflective film,
wherein the third layer comprises an organic compound,
wherein the organic compound has an ordinary refractive index higher than or equal to 1.45 and lower than or equal to 1.75 at a wavelength in a range of 450 nm to 650 nm inclusive,
wherein the second layer is positioned between the third layer and the first reflective film,
wherein the second layer has a property of transmitting light with the first wavelength,
wherein the second layer comprises a second electrode,
wherein the second layer comprises an element with an atomic number of 21 to 83 at 5 atomic % or higher,
wherein the first layer is positioned between the second layer and the first reflective film,
wherein the first layer has a property of transmitting light with the first wavelength,
wherein the first layer comprises an element with an atomic number of 1 to 20 at 95 atomic % or higher, and
wherein the first reflective film reflects light with the first wavelength.

2. The light-emitting device according to claim 1,
wherein the second layer has a higher ordinary refractive index than the third layer at the first wavelength, and
wherein a difference in ordinary refractive index at the first wavelength between the second layer and the third layer is larger than or equal to 0.2 and smaller than or equal to 1.5.

3. The light-emitting device according to claim 1,
wherein the first layer has a lower ordinary refractive index than the second layer at the first wavelength, and
wherein a difference in ordinary refractive index at the first wavelength between the first layer and the second layer is larger than or equal to 0.2 and smaller than or equal to 1.8.

4. The light-emitting device according to claim 1,
wherein the first layer has an ordinary refractive index higher than or equal to 1.20 and lower than or equal to 1.70 at the first wavelength, and
wherein the first layer has an insulating property.

5. A light-emitting device comprising:
a first reflective film;
a first layer;
a second layer;
a third layer;
a fourth layer; and
a first electrode,
wherein the first electrode overlaps with the first reflective film,
wherein the fourth layer is positioned between the first electrode and the first reflective film,
wherein the fourth layer comprises a first light-emitting material,
wherein the first light-emitting material has an emission spectrum having a peak at a first wavelength,
wherein the third layer is positioned between the fourth layer and the first reflective film,
wherein the third layer comprises an organic compound,
wherein the organic compound comprises carbon atoms forming bonds by sp³ hybrid orbitals at higher than or equal to 23% and lower than or equal to 55% of the total carbon atoms in a molecule,
wherein the second layer is positioned between the third layer and the first reflective film,
wherein the second layer has a property of transmitting light with the first wavelength,
wherein the second layer comprises a second electrode,
wherein the second layer comprises an element with an atomic number of 21 to 83 at 5 atomic % or higher,
wherein the first layer is positioned between the second layer and the first reflective film,
wherein the first layer has a property of transmitting light with the first wavelength,
wherein the first layer comprises an element with an atomic number of 1 to 20 at 95 atomic % or higher, and
wherein the first reflective film reflects light with the first wavelength.

6. The light-emitting device according to claim 5,
wherein the second layer comprises a metal oxide, and
wherein the metal oxide comprises indium, tin, zinc, gallium, or titanium.

7. The light-emitting device according to claim 5,
wherein the first layer comprises silicon oxide or aluminum oxide.

8. The light-emitting device according to claim 5,
wherein the first reflective film has conductivity, and
wherein the first reflective film is electrically connected to the second electrode.

9. The light-emitting device according to claim 5,
wherein the first reflective film comprises silver or aluminum.

10. The light-emitting device according to claim 5,
wherein the first electrode has a property of transmitting light with the first wavelength.

11. The light-emitting device according to claim 5,
wherein the first electrode comprises silver, magnesium, aluminum, indium, tin, zinc, gallium, or titanium.

12. A display apparatus comprising:
a first light-emitting device; and
a second light-emitting device,
wherein the first light-emitting device has the structure according to claim 1,
wherein the second light-emitting device is adjacent to the first light-emitting device,
wherein the second light-emitting device comprises a second reflective film, a fifth layer, a sixth layer, a seventh layer, an eighth layer, and a third electrode,
wherein the third electrode overlaps with the second reflective film,
wherein the eighth layer is positioned between the third electrode and the second reflective film,
wherein the eighth layer comprises a second light-emitting material,
wherein the second light-emitting material has an emission spectrum having a peak at a second wavelength,
wherein the second wavelength is longer than the first wavelength,
wherein the seventh layer is positioned between the eighth layer and the second reflective film,
wherein the seventh layer comprises the organic compound,
wherein the sixth layer comprises the same material as the second layer,
wherein the sixth layer is positioned between the third electrode and the second reflective film,
wherein the sixth layer has a property of transmitting light with the second wavelength,
wherein the sixth layer comprises a fourth electrode,
wherein the fifth layer comprises the same material as the first layer,
wherein the fifth layer is positioned between the sixth layer and the second reflective film,
wherein the fifth layer has a property of transmitting light with the second wavelength,
wherein the second reflective film is adjacent to the first reflective film, and
wherein the second reflective film reflects light with the second wavelength.

13. The display apparatus according to claim 12,
wherein the seventh layer is thicker than the third layer.

14. The display apparatus according to claim 12,
wherein a difference in thickness between the sixth layer and the second layer is larger than 0 and smaller than 5 nm.

15. The display apparatus according to claim 12,
wherein a difference in thickness between the fifth layer and the first layer is larger than 0 and smaller than 5 nm.

16. A display module comprising:
the display apparatus according to claim 12; and
at least one of a connector and an integrated circuit.

17. An electronic device comprising:
the display apparatus according to claim 12; and
at least one of a battery, a camera, a speaker, and a microphone.

18. A display apparatus comprising:
a first light-emitting device; and
a second light-emitting device,
wherein the first light-emitting device has the structure according to claim 5,
wherein the second light-emitting device is adjacent to the first light-emitting device,
wherein the second light-emitting device comprises a second reflective film, a fifth layer, a sixth layer, a seventh layer, an eighth layer, and a third electrode,
wherein the third electrode overlaps with the second reflective film,
wherein the eighth layer is positioned between the third electrode and the second reflective film,
wherein the eighth layer comprises a second light-emitting material,
wherein the second light-emitting material has an emission spectrum having a peak at a second wavelength,
wherein the second wavelength is longer than the first wavelength,
wherein the seventh layer is positioned between the eighth layer and the second reflective film,
wherein the seventh layer comprises the organic compound,
wherein the sixth layer comprises the same material as the second layer,
wherein the sixth layer is positioned between the third electrode and the second reflective film,
wherein the sixth layer has a property of transmitting light with the second wavelength,
wherein the sixth layer comprises a fourth electrode,
wherein the fifth layer comprises the same material as the first layer,
wherein the fifth layer is positioned between the sixth layer and the second reflective film,
wherein the fifth layer has a property of transmitting light with the second wavelength,
wherein the second reflective film is adjacent to the first reflective film, and
wherein the second reflective film reflects light with the second wavelength.

19. The display apparatus according to claim 18,
wherein the seventh layer is thicker than the third layer.

20. The display apparatus according to claim 18,
wherein a difference in thickness between the sixth layer and the second layer is larger than 0 and smaller than 5 nm.

21. The display apparatus according to claim 18,
wherein a difference in thickness between the fifth layer and the first layer is larger than 0 and smaller than 5 nm.

22. A display module comprising:
the display apparatus according to claim 18; and
at least one of a connector and an integrated circuit.

23. An electronic device comprising:
the display apparatus according to claim 18; and
at least one of a battery, a camera, a speaker, and a microphone.
